(19) United States
(12) Patent Application Publication
(10) Pub. No.: US 2026/0197113 A1
(43) Pub. Date: Jul. 9, 2026

(54) METHOD AND DEVICE FOR ENCODING AND DECODING DATA IN COMMUNICATION OR BROADCASTING SYSTEM

(71) Applicant: Samsung Electronics Co., Ltd., Suwon-si (KR)

(72) Inventors: Seho MYUNG, Suwon-si (KR); Euichang JUNG, Suwon-si (KR)

(21) Appl. No.: 19/555,628

(22) Filed: Mar. 3, 2026

Related U.S. Application Data
(63) Continuation of application No. PCT/KR2024/013250, filed on Sep. 3, 2024.

(30) Foreign Application Priority Data
Sep. 4, 2023 (KR) 10-2023-0117190
Oct. 12, 2023 (KR) 10-2023-0135521

(51) Int. Cl. H04L 1/00

(52) U.S. Cl. CPC H04L 1/0042

(57) ABSTRACT

Certain example embodiments may relate to a 5G and/or 6G communication system for supporting higher data transmission rates than 4G communication systems such as LTE. A method performed by a transmitter in a communication system, which method may include: determining the number of input bits; determining a base matrix on the basis of the number of input bits; determining a lifting size (Z) on the basis of at least one of the number of input bits or the base matrix; determining a parity check matrix on the basis of at least one of the base matrix or the lifting size (Z); and performing encoding on the basis of the parity check matrix and the input bits. The size of the parity check matrix is Z×(k+1) Z, the last column block of the parity check matrix corresponds to parity bits, a Z×kZ column block of the parity check matrix corresponds to information word bits, all of modulo-Z values of differences in cyclic shift values corresponding to circulant permutation matrices constituting a Z×Z circulant matrix are different, and all of the circulant matrices corresponding to the information word bits are composed of three or more circulant permutation matrices.

### CROSS-REFERENCE TO RELATED APPLICATIONS

This application is a continuation application of International Application No. PCT/KR2024/013250 designating the United States, filed on Sep. 3, 2024, in the Korean Intellectual Property Receiving Office and claiming priority to Korean Patent Application No. 10-2023-0117190, filed on Sep. 4, 2023, and Korean Patent Application No. 10-2023-0135521, filed on Oct. 12, 2023, the disclosures of which are all hereby incorporated by reference herein in their entireties.

### TECHNICAL FIELD

Certain example embodiments may relate to a method and/or device for encoding and/or decoding data in a communication and/or broadcasting system.

### BACKGROUND

Considering the development of wireless communication from generation to generation, the technologies have been developed mainly for services targeting humans, such as voice calls, multimedia services, and data services. Following the commercialization of 5G (5th-generation) communication systems, it is expected that the number of connected devices will exponentially grow. Increasingly, these will be connected to communication networks. Examples of connected things may include vehicles, robots, drones, home appliances, displays, smart sensors connected to various infrastructures, construction machines, and factory equipment. Mobile devices are expected to evolve in various form-factors, such as augmented reality glasses, virtual reality headsets, and hologram devices. In order to provide various services by connecting hundreds of billions of devices and things in the 6G (6th-generation) era, there have been ongoing efforts to develop improved 6G communication systems. For these reasons, 6G communication systems are referred to as beyond-5G systems.

6G communication systems, which are expected to be commercialized around 2030, will have a peak data rate of tera (1,000 giga)-level bps and a radio latency less than 100 sec, and thus will be 50 times as fast as 5G communication systems and have the 1/10 radio latency thereof.

In order to accomplish such a high data rate and an ultra-low latency, it has been considered to implement 6G communication systems in a terahertz band (for example, 95 GHz to 3 THz bands). It is expected that, due to severer path loss and atmospheric absorption in the terahertz bands than those in mmWave bands introduced in 5G, technologies capable of securing the signal transmission distance (that is, coverage) will become more crucial. It is necessary to develop, as major technologies for securing the coverage, radio frequency (RF) elements, antennas, novel waveforms having a better coverage than orthogonal frequency division multiplexing (OFDM), beamforming and massive multiple input multiple output (MIMO), full dimensional MIMO (FD-MIMO), array antennas, and multiantenna transmission technologies such as large-scale antennas. In addition, there has been ongoing discussion on new technologies for improving the coverage of terahertz-band signals, such as metamaterial-based lenses and antennas, orbital angular momentum (OAM), and reconfigurable intelligent surface (RIS).

Moreover, in order to improve the spectral efficiency and the overall network performances, the following technologies have been developed for 6G communication systems: a full-duplex technology for enabling an uplink transmission and a downlink transmission to simultaneously use the same frequency resource at the same time; a network technology for utilizing satellites, high-altitude platform stations (HAPS), and the like in an integrated manner; an improved network structure for supporting mobile base stations and the like and enabling network operation optimization and automation and the like; a dynamic spectrum sharing technology via collison avoidance based on a prediction of spectrum usage; an use of artificial intelligence (AI) in wireless communication for improvement of overall network operation by utilizing AI from a designing phase for developing 6G and internalizing end-to-end AI support functions; and a next-generation distributed computing technology for overcoming the limit of UE computing ability through reachable super-high-performance communication and computing resources (such as mobile edge computing (MEC), clouds, and the like) over the network. In addition, through designing new protocols to be used in 6G communication systems, developing mecahnisms for implementing a hardware-based security environment and safe use of data, and developing technologies for maintaining privacy, attempts to strengthen the connectivity between devices, optimize the network, promote softwarization of network entities, and increase the openness of wireless communications are continuing.

It is expected that research and development of 6G communication systems in hyper-connectivity, including person to machine (P2M) as well as machine to machine (M2M), will allow the next hyper-connected experience. Particularly, it is expected that services such as truly immersive extended reality (XR), high-fidelity mobile hologram, and digital replica could be provided through 6G communication systems. In addition, services such as remote surgery for security and reliability enhancement, industrial automation, and emergency response will be provided through the 6G communication system such that the technologies could be applied in various fields such as industry, medical care, automobiles, and home appliances.

### SUMMARY

Certain example embodiments may provide algebraic properties that the parity check matrix of an LDPC code should satisfy to reduce decoding latency and lower encoding complexity. Certain example embodiments may provide a method and device for efficient encoding and decoding by utilizing an LDPC code having the algebraic properties.

Certain example embodiments may provide algebraic properties that the parity check matrix of an LDPC code should satisfy to reduce the block error rate (BLER). Certain example embodiments may provide a method and device for efficient encoding and decoding by utilizing an LDPC code having the algebraic properties.

Certain example embodiments may provide combine the above algebraic properties so as to simultaneously reduce decoding latency, encoding complexity, and the BLER and provides algebraic properties that the parity check matrix of an LDPC code should satisfy. Certain example embodiments may provide a method and device for efficient encoding and decoding by utilizing an LDPC code having the combined algebraic properties.

A data transmission method of a base station or a terminal in a communication system may include: performing LDPC encoding of data based on a base matrix and/or a parity check matrix; applying appropriate rate matching to the encoded data; modulating the rate-matched encoded data; and transmitting a modulated signal through a transmitter, wherein the base matrix, parity check matrix, or its corresponding weight matrix satisfies specific algebraic conditions.

A data reception method of a base station or a terminal in a communication system according to an example embodiment may include: receiving a modulated signal through a receiver; performing demodulation to determine values for decoding based on the received signal; performing LDPC decoding based on the determined values, a base matrix, and/or a parity check matrix; appropriately applying rate dematching to the LDPC decoded result; and determining data from the rate-dematched result, wherein the base matrix, parity check matrix, or its corresponding weight matrix satisfies specific algebraic conditions.

Certain example embodiments may provide algebraic properties of a parity check matrix for reducing latency and BLER, to effectively support LDPC codes for variable lengths and variable rates.

### BRIEF DESCRIPTION OF DRAWINGS

FIG. 1 is a diagram illustrating an example format of a systematic LDPC codeword.

FIG. 2 is a diagram illustrating an example method of representing a graph for an LDPC code.

FIG. 3A is a diagram illustrating an example cycle characteristics of a QC-LDPC code.

FIG. 3B is a diagram illustrating an example cycle characteristics of a QC-LDPC code.

FIG. 4 is a diagram illustrating an example structure of a transport block according to an example embodiment.

FIG. 5 is a diagram illustrating an example LDPC encoding process according to an example embodiment.

FIG. 6 is a diagram illustrating an example LDPC decoding process according to an example embodiment.

FIG. 7 is a block diagram of a transmitter according to an example embodiment.

FIG. 8 is a block diagram of a receiver according to an example embodiment.

FIG. 9 is a diagram illustrating the structure of an LDPC decoder according to an example embodiment.

FIG. 10 is a diagram illustrating the structure of a parity check matrix of an example LDPC code.

FIG. 11A is a diagram illustrating the parity check matrix of an example LDPC code satisfying example characteristics.

FIG. 11B is a diagram illustrating the parity check matrix of an example LDPC code satisfying example characteristics.

FIG. 12A is a diagram illustrating cycle characteristics in a submatrix of the parity check matrix for an example LDPC code satisfying example characteristics.

FIG. 12B is a diagram illustrating example cycle characteristics in a submatrix of the parity check matrix for an example LDPC code satisfying example characteristics.

FIG. 12C is an example diagram illustrating cycle characteristics in a submatrix of the parity check matrix for an example LDPC code satisfying example characteristics.

FIG. 13 is a diagram illustrating the parity check matrix of an example LDPC code according to an example embodiment.

FIG. 14A is a diagram illustrating application of an example permutation rule to the parity check matrix according to an example embodiment.

FIG. 14B is a diagram illustrating application of an example permutation rule to the parity check matrix according to an example embodiment.

### DETAILED DESCRIPTION

Hereinafter, exemplary embodiments of the disclosure will be described in detail with reference to the accompanying drawings. In describing the disclosure, if a detailed description of a related well-known function or configuration is deemed to unnecessarily obscure the subject matter of the disclosure, such detailed description will be omitted. Additionally, the terms described below are defined based on their functions in this disclosure, and may vary depending on the intention or custom of the user or operator. Therefore, their definitions should be interpreted based on the overall content of this specification.

Those skilled in the art of this disclosure will understand that the subject matter of the disclosure can be applied to other systems with similar technical backgrounds with minor modifications not significantly departing from the scope of the disclosure. For reference, the term “communication system” generally includes the meaning of a broadcasting system, but in the disclosure, if a broadcasting service is the main service in the communication systems, it may be more clearly named as a broadcasting system.

The advantages and features of the disclosure, and methods for achieving them will become clear with reference to those embodiments described below in detail along with the accompanying drawings. However, the disclosure is not limited to those embodiments disclosed below and may be implemented in various different forms. These embodiments are provided only to ensure that the disclosure is complete and to fully inform those skilled in the art of the disclosure of the scope of the disclosure, and the disclosure is defined only by the scope of the claims. Identical reference symbols throughout the specification refer to the same components.

Low density parity check (LDPC) codes, first introduced by Gallager in the 1960s, have long been forgotten due to the degree of complexity that cannot be implemented at the technology level of that time. However, as turbo codes proposed by Berru, Glavieux, and Thitimajshima in 1993 have showed performance close to the Shannon's channel capacity, many studies on iterative decoding and graph-based channel coding have been conducted while many interpretations of the performance and properties of turbo codes have been made. This has led to a restudy of LDPC codes in the late 1990s, and it has been found that if decoding is performed by applying iterative decoding based on the sum-product algorithm on the Tanner graph corresponding to an LDPC code, the LDPC code also has performance approaching the Shannon's channel capacity.

The LDPC code is generally defined as a parity check matrix and may be represented using a bipartite graph commonly known as a Tanner graph. The LDPC code is generally a type of parity check code, and it is called “low density” parity check code because it has the characteristic of a very low ratio of 1's (e.g., density) in the parity check matrix for a very long length. Hence, the techniques proposed based on LDPC codes for convenience in this disclosure can be readily extended to general parity check matrix codes.

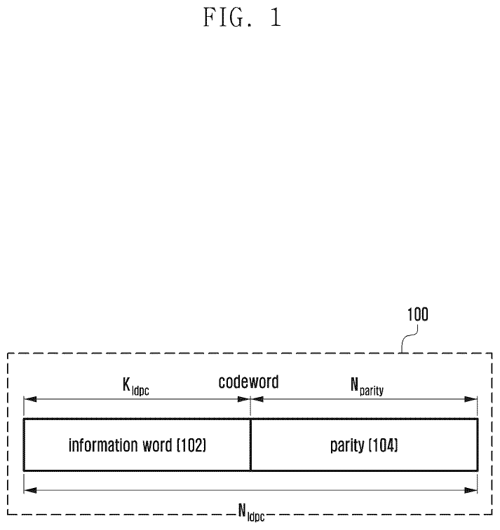

FIG. 1 is a diagram illustrating the format of a systematic LDPC codeword.

According to FIG. 1, the device performing LDPC encoding receives an information word 102 composed of K_{ldpc} bits or symbols and performs encoding to generate a codeword 100 composed of N_{ldpc} bits or symbols. For convenience of description below, it is assumed that an information word 102 containing K_{ldpc} bits is input and a codeword 100 composed of N_{ldpc} bits is generated. That is, when information word i=(i₀, i₁, i₂, . . . , i_{K}_{_{ldpc}}₋₁) 102 with K_{ldpc} input bits is LDPC encoded, codeword c=(C₀, C₁, C₂, . . . , C_{N}_{_{ldpc}}₋₁) 100 is generated. In other words, the information word and codeword are a bit sequence composed of multiple bits, and information bits and codeword bits represent the individual bits that make up the information word and codeword, respectively. Typically, if LDPC coded bits contain an information word, such as

$$\underline{c} = ( {c}_{0} , {c}_{1} , {c}_{2} , ... , {c}_{{N}_{ldpc} - 1} ) = ( \underline{i} , \underline{w} ) = ( {i}_{0} , {i}_{1} , {i}_{2} , ... , {i}_{{K}_{ldpc} - 1} , {w}_{0} , {w}_{1} , {w}_{2} , ... , {w}_{{N}_{ldpc} - {K}_{ldpc} - 1} )$$

it is called a systematic code. Here, w=[w₀ w₁ w₂ . . . w_{N}_{_{ldpc}}_{-K}_{_{ldpc}}₋₁] is parity bits 104, and the number of parity bits N_{parity} may be represented as N_{parity}=N_{ldpc}−K_{ldpc}.

The LDPC code is a type of linear block code and includes a process of determining a codeword that satisfies the condition in Equation 1 below.

$$H \cdot {\underline{c}}^{T} = [ \begin{matrix}{h}_{0} & {h}_{1} & {h}_{2} & ... & {h}_{{N}_{ldpc} - 1}\end{matrix} ] \cdot {\underline{c}}^{T} = {\sum }_{i = 0}^{{N}_{ldpc} - 1} {c}_{i} \cdot {h}_{i} = \underline{0} , \qquad [ Equation 1 ]$$

$$where \underline{c} = [ \begin{matrix}{c}_{0} & {c}_{1} & {c}_{2} & ... & {c}_{{N}_{ldpc} - 1}\end{matrix} ] .$$

In Equation 1, H represents the parity check matrix, c represents the codeword, cᵢ represents the i^{th} bit of the codeword, N_{ldpc} represents the LDPC codeword length, and hᵢ represents the i^{th} column of the parity check matrix H.

The parity check matrix H is composed of N_{ldpc} columns being equal to the number of bits in the LDPC codeword. Since Equation 1 may indicate that the sum of the products of the i^{th} column hᵢ of the parity check matrix and the i^{th} codeword bit cᵢ is ‘0’, this may indicate that the i^{th} column hᵢ is related to the i^{th} codeword bit cᵢ.

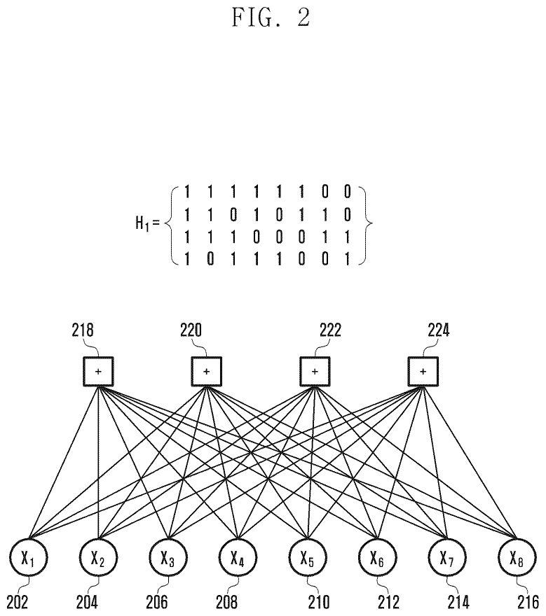

FIG. 2 is a diagram illustrating a method of representing a graph for an LDPC code.

A description will be given of a method for representing a graph of an LDPC code with reference to FIG. 2.

FIG. 2 illustrates an example of a parity check matrix H₁ of an LDPC code composed of four rows and eight columns, and its representation as a Tanner graph. With reference to FIG. 2, since the parity check matrix H₁ has 8 columns, a codeword of length 8 is generated, and the code generated through H₁ may indicate an LDPC code, and the columns correspond to 8 encoded bits.

With reference to FIG. 2, the Tanner graph of an LDPC code that encodes and decodes based on the parity check matrix H₁ is composed of eight variable nodes, namely x₁ 202, x₂204, x₃ 206, x₄ 208, x₅ 210, x₆ 212, x₇214 and x₈ 216, and four check nodes 218, 220, 222 and 224. Here, the i^{th} column and the j^{th} row of the parity check matrix H₁ of the LDPC code correspond respectively to the variable node xᵢ and the j^{th} check node. In addition, the value of 1, that is, a non-zero value, at the point where the i^{th} column and the j^{th} row of the parity check matrix H₁ of the LDPC code intersect may indicate that there is an edge connecting the variable node x₁ and the j^{th} check node on the Tanner graph, as shown in FIG. 2.

In the Tanner graph of an LDPC code, the degree of a variable node and a check node represents the number of edges connected to each node. This degree is equal to the number of non-zero entries in the corresponding column or row of the LDPC code's parity check matrix. For example, in FIG. 2, the degrees of variable nodes x₁ 202, x₂ 204, x₃ 206, x₄ 208, x₅ 210, x₆ 212, x₇ 214 and x₈ 216 are 4, 3, 3, 2, 2, 2, 2, respectively, and the degrees of check nodes 218, 220, 222 and 224 are 6, 5, 5, 5, respectively. Additionally, the numbers of non-zero entries in the columns of the parity check matrix H₁ of FIG. 2 corresponding to the variable nodes of FIG. 2 are equal respectively to 4, 3, 3, 3, 2, 2, 2, 2 being the degrees of the aforementioned variable nodes; and the numbers of non-zero entries in the rows of the parity check matrix H₁ of FIG. 2 corresponding to the check nodes of FIG. 2 are equal respectively to 6, 5, 5, 5 being the degrees of the aforementioned check nodes. For this reason, the degree of each variable node is also called the column degree or column weight, and the degree of each check node is also called the row degree or row weight.

LDPC-encoded codeword bits may be decoded using an iterative decoding algorithm based on the sum-product algorithm on the bipartite graph shown in FIG. 2. Here, the sum-product algorithm is a type of message passing algorithm, and the message passing algorithm indicates an algorithm that exchanges messages through edges on the bipartite graph and calculates and updates output messages from messages input to the variable nodes or check nodes.

Here, the value of the i^{th} encoding bit may be determined based on the message of the i^{th} variable node. The value of the i^{th} encoding bit may be determined using both hard and soft decision methods. Hence, performance of the i^{th} bit cᵢ of an LDPC codeword corresponds to performance of the i^{th} variable node of the Tanner graph, which may be determined depending on the positions and number of 1's in the i^{th} column of the parity check matrix. In other words, performance of N_{ldpc} codeword bits may be influenced by the positions and number of 1's in the parity-check matrix, and this may indicate that the performance of an LDPC code is significantly affected by the parity check matrix. Therefore, in order to design an LDPC code with excellent performance, a method for designing a good parity check matrix is needed.

Parity check matrices used in communications and broadcasting systems typically use quasi-cyclic LDPC codes (or QC-LDPC codes, hereinafter referred to as QC-LDPC codes), which utilize a quasi-cyclic parity check matrix for ease of implementation. Depending on the communication and broadcasting system, there are cases where a parity check matrix with a structure that is not a complete quasi-cyclic structure but is almost similar to a quasi-cyclic structure is used. Such LDPC codes may be not strictly classified algebraically as QC-LDPC codes, but for convenience, they are sometimes classified as QC-LDPC codes.

A typical QC-LDPC code is characterized by a parity check matrix composed of zero matrices or circulant permutation matrices (circular permutation matrices) in the form of small square matrices. Here, a permutation matrix refers to a matrix in which each row or column contains only a single 1, and all other entries are 0. Further, a circulant permutation matrix refers to a matrix in which entries of the identity matrix are circularly shifted to the right or left. Generally, the identity matrix itself is a circulant permutation matrix, because it may be considered that entries of the identity matrix have been circularly shifted zero times. Hence, circulant permutation matrices basically include identity matrices, but for convenience of explanation, an identity matrix and a circulant permutation matrix that is not an identity matrix may be used in a distinguished manner.

Next, a detailed description will be given of the QC-LDPC code.

First, a circulant permutation matrix P=(P_{i,j}) of size Z×Z is defined as shown in Equation 2. Here, P_{i,j} may indicate the entry of the i^{th} row and j^{th} column in the matrix

$$P . ( 0 \leq i , j < Z ) \qquad [ Equation 2 - 1 ]$$

$${P}_{i , j} = \{ \begin{matrix}1 & if i + 1 ≡ j ( mod Z ) \\ 0 & otherwise\end{matrix} .$$

For the permutation matrix P defined as above, Pⁱ(0≤i<Z) is a circulant permutation matrix, which is a Z×Z identity matrix with each element circularly shifted to the right i times. A circulant permutation matrix may also be defined as in Equation 2-2, in which case Pⁱ is a circulant permutation matrix being an identity matrix of size Z×Z with each element circularly shifted to the left by i times:

$${P}_{i , j} = \{ \begin{matrix}1 & if i ≡ j + 1 ( mod Z ) \\ 0 & otherwise\end{matrix} . \qquad [ Equation 2 - 2 ]$$

In the disclosure, for convenience, various embodiments are described using the circulant permutation matrix defined based on Equation 2-1. However, the circulant permutation matrices defined by Equation 2-1 and Equation 2-2 have the same basic algebraic properties, although their representations are different. Therefore, a circulant permutation matrix defined based on Equation 2-2 can be used in the embodiments of the disclosure, or various types of circulant permutation matrices having the same algebraic properties can be used.

The parity check matrix H of a simplest QC-LDPC code may be expressed as in Equation 3 below.

$$H = [ \begin{matrix}{P}^{{V}_{1 , 1}} & {P}^{{V}_{1 , 2}} & … & {P}^{{V}_{1 , {n}_{b}}} \\ {P}^{{V}_{2 , 1}} & {P}^{{V}_{2 , 2}} & … & {P}^{{V}_{2 , {n}_{b}}} \\ ⋮ & ⋮ & ⋱ & ⋮ \\ {P}^{{V}_{{m}_{b} , 1}} & {P}^{{V}_{{m}_{b} , 2}} & … & {P}^{{V}_{{m}_{b} , {n}_{b}}}\end{matrix} ] \qquad [ Equation 3 ]$$

For convenience, if P⁻¹ is defined as a 0-matrix of size Z×Z, each exponent V_{i,j} of the circulant permutation matrices or 0-matrices in Equation 3 above has one of the values {−1, 0, 1, 2, . . . , Z−1}. The identity matrix may be represented as P⁰ or I, and the 0-matrix may be represented as P⁻¹ or 0. Additionally, in the parity check matrix H of Equation 3, there are n_{b} column blocks and m_{b} row blocks, so the size of the parity check matrix H is n_{b}Z×m_{b}Z.

If the parity check matrix of Equation 3 above has full rank (or, complete rank), the length of information bits of the QC-LDPC code corresponding to the parity check matrix is (n_{b}−m_{b})Z. For convenience, the k_{b}−(n_{b}−m_{b}) column blocks corresponding to the information bits may be called information column blocks, and the number of information bits may be k_{b}Z; the m_{b} column blocks corresponding to the remaining parity bits may be called parity column blocks, and the number of parity bits is m_{b}Z. For reference, if the parity check matrix of Equation 3 above does not have full rank, the information bits is greater than (n_{b}−m_{b})Z, the number of information bits is greater than k_{b}Z, and the number of parity bits is less than m_{b}Z.

Typically, the binary matrix of size m_{b}×n_{b} obtained by replacing each circulant permutation matrix and 0-matrix in the parity check matrix of Equation 3 with 1 and 0, respectively, is called the mother matrix, base matrix, or base graph of the parity check matrix H and is denoted M(H) or H_{BG}. In addition, the integer matrix of size m_{b}×n_{b} obtained by selecting the exponent of each circulant permutation matrix or 0-matrix as in Equation 4 is called the exponent matrix V(H) of the parity check matrix H.

$$V ( H ) = [ \begin{matrix}{V}_{1 , 1} & {V}_{1 , 2} & … & {V}_{1 , {n}_{b}} \\ {V}_{2 , 1} & {V}_{2 , 2} & … & {V}_{2 , {n}_{b}} \\ ⋮ & ⋮ & ⋱ & ⋮ \\ {V}_{{m}_{b} , 1} & {V}_{{m}_{b} , 2} & … & {V}_{{m}_{b} , {n}_{b}}\end{matrix} ] \qquad [ Equation 4 ]$$

Definitely, such a matrix name is an example only, and the exponent matrix V(H) may be called by other names. For example, since the exponent of each circulant permutation matrix correspond to the value that circularly shifts the identity matrix, as in Equation 2-1 or Equation 2-2, each exponent may be called a shift value or circular shift value, and V(H) may also be called a circular shift value matrix or shift value matrix. Generally, the parity check matrix may be determined or identified when the exponent matrix or shift value matrix and the Z value corresponding to the size of the circulant permutation matrix or 0-matrix are given. For this reason, according to the mathematical definition, a parity check matrix may indicate a binary matrix H that satisfies the condition of Equation 1, but in some cases, for convenience, the exponent matrix or shift value matrix may be called a parity check matrix.

Since a single integer contained in the exponent matrix or shift value matrix corresponds to a circulant permutation matrix in the parity check matrix, the exponent matrix may be expressed as sequences of integers for convenience. In general, a parity check matrix may be expressed not only as an exponent matrix but also as various sequences that can represent algebraically identical properties. For convenience, in the disclosure, the parity check matrix is expressed as an exponent matrix or a sequence indicating the positions of 1's within the parity check matrix. However, there are various sequence notations that can distinguish the positions of 1's or 0's within the parity check matrix. Hence, without being limited to the method described herein, the parity check matrix may be expressed in various sequences or matrices that achieve the same algebraic effects. The above sequence may be called in various ways, such as LDPC sequence, LDPC code sequence, LDPC sequence, parity check matrix sequence, or (circular) shift value sequence, to distinguish it from other sequences.

Further, the transceiver may directly generate a parity check matrix to perform LDPC encoding and decoding. However, depending on implementation characteristics, LDPC encoding and decoding may also be performed based on an exponent matrix or a shift value matrix or sequence that achieves the same algebraic effects as the parity check matrix. Hence, for convenience, encoding and decoding using a parity check matrix are described in the disclosure, but in an actual transceiver, encoding and decoding may be carried out through various methods that can obtain the same effects as the parity check matrix.

For reference, the algebraically equivalent effect refers to the ability of two or more distinct representations to be logically or mathematically identical, or to be transformable between them. In particular, for codes that can be defined by matrices such as LDPC codes, this may mean that algebraic values that can be defined by a matrix, such as minimum distance, rank, or cycle characteristics on a Tanner graph are the same, or may mean that the basic structures or operations are the same in the encoding/decoding process. For example, if identical matrices are obtained through appropriate column and row permutations, the two matrices can be considered algebraically equivalent from a code perspective. Additionally, various transposes that do not change the actual properties of the code can provide algebraically equivalent effects.

As a concrete example, given the following matrix A, examples of various transforms that provide algebraically equivalent effects are shown as A1 to A8.

$$A = [ \begin{matrix}{P}^{{a}_{1 , 1}} & {P}^{{a}_{1 , 2}} & {P}^{{a}_{1 , 3}} & {P}^{{a}_{1 , 4}} \\ {P}^{{a}_{2 , 1}} & {P}^{{a}_{2 , 2}} & {P}^{{a}_{2 , 3}} & {P}^{{a}_{2 , 4}} \\ {P}^{{a}_{3 , 1}} & {P}^{{a}_{3 , 2}} & {P}^{{a}_{3 , 3}} & {P}^{{a}_{3 , 4}} \\ {P}^{{a}_{4 , 1}} & {P}^{{a}_{4 , 2}} & {P}^{{a}_{4 , 3}} & {P}^{{a}_{4 , 4}}\end{matrix} ]$$

$${A}_{1} = [ \begin{matrix}{P}^{{a}_{1 , 1}} & {P}^{{a}_{1 , 3}} & {P}^{{a}_{1 , 2}} & {P}^{{a}_{1 , 4}} \\ {P}^{{a}_{2 , 1}} & {P}^{{a}_{2 , 3}} & {P}^{{a}_{2 , 2}} & {P}^{{a}_{2 , 4}} \\ {P}^{{a}_{3 , 1}} & {P}^{{a}_{3 , 3}} & {P}^{{a}_{3 , 2}} & {P}^{{a}_{3 , 4}} \\ {P}^{{a}_{4 , 1}} & {P}^{{a}_{4 , 3}} & {P}^{{a}_{4 , 2}} & {P}^{{a}_{4 , 4}}\end{matrix} ] , {A}_{2} = [ \begin{matrix}{P}^{{a}_{3 , 1}} & {P}^{{a}_{3 , 3}} & {P}^{{a}_{3 , 2}} & {P}^{{a}_{3 , 4}} \\ {P}^{{a}_{2 , 1}} & {P}^{{a}_{2 , 3}} & {P}^{{a}_{2 , 2}} & {P}^{{a}_{2 , 4}} \\ {P}^{{a}_{1 , 1}} & {P}^{{a}_{1 , 3}} & {P}^{{a}_{1 , 2}} & {P}^{{a}_{1 , 4}} \\ {P}^{{a}_{4 , 1}} & {P}^{{a}_{4 , 3}} & {P}^{{a}_{4 , 2}} & {P}^{{a}_{4 , 4}}\end{matrix} ] ,$$

$${A}_{3} = [ \begin{matrix}{P}^{{a}_{1 , 1} + x} & {P}^{{a}_{1 , 2}} & {P}^{{a}_{1 , 3} + y} & {P}^{{a}_{1 , 4}} \\ {P}^{{a}_{2 , 1} + x} & {P}^{{a}_{2 , 2}} & {P}^{{a}_{2 , 3} + y} & {P}^{{a}_{2 , 4}} \\ {P}^{{a}_{3 , 1} + x} & {P}^{{a}_{3 , 2}} & {P}^{{a}_{3 , 3} + y} & {P}^{{a}_{3 , 4}} \\ {P}^{{a}_{4 , 1} + x} & {P}^{{a}_{4 , 2}} & {P}^{{a}_{4 , 3} + y} & {P}^{{a}_{4 , 4}}\end{matrix} ] ,$$

$${A}_{4} = [ \begin{matrix}{P}^{{a}_{1 , 1} + x} & {P}^{{a}_{1 , 2}} & {P}^{{a}_{1 , 3} + y} & {P}^{{a}_{1 , 4}} \\ {P}^{{a}_{2 , 1} + x + z} & {P}^{{a}_{2 , 2} + z} & {P}^{{a}_{2 , 3} + y + z} & {P}^{{a}_{2 , 4} + z} \\ {P}^{{a}_{3 , 1} + x} & {P}^{{a}_{3 , 2}} & {P}^{{a}_{3 , 3} + y} & {P}^{{a}_{3 , 4}} \\ {P}^{{a}_{4 , 1} + x + w} & {P}^{{a}_{4 , 2} + w} & {P}^{{a}_{4 , 3} + y + w} & {P}^{{a}_{4 , 4} + w}\end{matrix} ] ,$$

$${A}_{5} = [ \begin{matrix}{P}^{- {a}_{1 , 1}} & {P}^{- {a}_{2 , 1}} & {P}^{- {a}_{3 , 1}} & {P}^{- {a}_{4 , 1}} \\ {P}^{- {a}_{1 , 2}} & {P}^{- {a}_{2 , 2}} & {P}^{- {a}_{3 , 2}} & {P}^{- {a}_{4 , 2}} \\ {P}^{- {a}_{1 , 3}} & {P}^{- {a}_{2 , 3}} & {P}^{- {a}_{3 , 3}} & {P}^{- {a}_{4 , 3}} \\ {P}^{- {a}_{1 , 4}} & {P}^{- {a}_{2 , 4}} & {P}^{- {a}_{3 , 4}} & {P}^{- {a}_{4 , 4}}\end{matrix} ] ,$$

$${A}_{6} = [ \begin{matrix}{P}^{{a}_{1 , 1}} & {P}^{{a}_{2 , 1}} & {P}^{{a}_{3 , 1}} & {P}^{{a}_{4 , 1}} \\ {P}^{{a}_{1 , 2}} & {P}^{{a}_{2 , 2}} & {P}^{{a}_{3 , 2}} & {P}^{{a}_{4 , 2}} \\ {P}^{{a}_{1 , 3}} & {P}^{{a}_{2 , 3}} & {P}^{{a}_{3 , 3}} & {P}^{{a}_{4 , 3}} \\ {P}^{{a}_{1 , 4}} & {P}^{{a}_{2 , 4}} & {P}^{{a}_{3 , 4}} & {P}^{{a}_{4 , 4}}\end{matrix} ] ,$$

$${A}_{7} = [ \begin{matrix}{P}^{- {a}_{1 , 1}} & {P}^{- {a}_{1 , 2}} & {P}^{- {a}_{1 , 3}} & {P}^{- {a}_{1 , 4}} \\ {P}^{- {a}_{2 , 1}} & {P}^{- {a}_{2 , 2}} & {P}^{- {a}_{2 , 3}} & {P}^{- {a}_{2 , 4}} \\ {P}^{- {a}_{3 , 1}} & {P}^{- {a}_{3 , 2}} & {P}^{- {a}_{3 , 3}} & {P}^{- {a}_{3 , 4}} \\ {P}^{- {a}_{4 , 1}} & {P}^{- {a}_{4 , 2}} & {P}^{- {a}_{4 , 3}} & {P}^{- {a}_{4 , 4}}\end{matrix} ] ,$$

$${A}_{8} = [ \begin{matrix}{P}^{{ka}_{1 , 1}} & {P}^{{ka}_{1 , 2}} & {P}^{{ka}_{1 , 3}} & {P}^{{ka}_{1 , 4}} \\ {P}^{{ka}_{2 , 1}} & {P}^{{ka}_{2 , 2}} & {P}^{{ka}_{2 , 3}} & {P}^{{ka}_{2 , 4}} \\ {P}^{{ka}_{3 , 1}} & {P}^{{ka}_{3 , 2}} & {P}^{{ka}_{3 , 3}} & {P}^{{ka}_{3 , 4}} \\ {P}^{{ka}_{4 , 1}} & {P}^{{ka}_{4 , 2}} & {P}^{{ka}_{4 , 3}} & {P}^{{ka}_{4 , 4}}\end{matrix} ] ,$$

(where k is an integer relatively prime to Z)

A₁ is an example of a block-wise permutation of A obtained by permuting the second and third column blocks. A₂ is an example of a block-wise permutation obtained by permuting the first and third row blocks of A₁. A₃ is an example of applying circulant permutations only to the first and third column blocks of A. A₄ is an example of applying circulant permutations only to the second and fourth row blocks of A₃. A₅ is an example of applying a transpose to A. A₆ is an example of applying a block-wise transpose to A. A₇ is an example of applying a transform reversing the sign of each exponent (or circular shift value) to A (note that, when representing a Z×Z 0-matrix as P⁻¹ for convenience, using negative exponents (or shift values) can be confusing, and thus (−a_{i,j}) may be expressed as a positive value such as (Z−a_{i,j}). A₈ is an example of applying an affine transform with a constant term of 0 to A (the case with a non-zero constant term is also generally applicable). Note that the above examples, for convenience, describe the case where P^{a}_{i,j} has no entry that is a 0-matrix of size Z×Z. However, if a 0-matrix is included, the part corresponding to the 0-matrix is always a 0-matrix regardless of the transform. For example, if P^{a2,3} is a 0-matrix in A, then p^{a2,3} is also a 0-matrix in A₁, A₂ and A₆; P^{a2,3+y} and P^{a2,3+y+z} are a 0-matrix in A₃ and A₄; P^{-a2,3} is a 0-matrix in A₅ and A₇; P^{ka2,3} is a 0-matrix in A₈.

The above transforms are examples, and various other transforms may exist. Further, transforms may be applied independently, but can also be applied in appropriate repetition and combination. Here, the characteristics of individual transforms or a combination thereof may be converted back to the original matrix through an appropriate invertible transform process.

Various transforms or combinations of transforms described above are essentially symmetrical or reversible transforms that simply change the arrangement of bits (or variable nodes) or check nodes in the Tanner graph or maintain specific structures. Hence, in terms of code performance, while instantaneous performance may vary depending on the given channel conditions, they can provide the same performance on average. In this way, in the disclosure, all parity check matrices that can be obtained through transforms that produce the algebraically equivalent effect are considered to be the same parity check matrix.

So far, for convenience, only the case where a single circulant permutation matrix corresponds to one square block of size Z×Z has been described. However, the same invention can be applied to a case where multiple circulant permutation matrices are included in a single block. For example, when two circulant permutation matrices

$${P}^{{V}_{ij}^{( 1 )}} and {P}^{{V}_{ij}^{( 2 )}}$$

correspond to the position of the i^{th} row block and j^{th} column block as in Equation 5 below, it can be simply expressed in a sum form such as

$${P}^{{V}_{ij}^{( 1 )}} + {P}^{{V}_{ij}^{( 2 )}} ,$$

and its exponent matrix (or cyclic shift value matrix) can be expressed as in Equation 6. Referring to Equation 6, it can be seen that it is a matrix in which two integers correspond to the i^{th} row and j^{th} column corresponding to the row block and column block containing the sum of multiple circulant permutation matrices.

$$H = [ {P}^{{V}_{i , j}^{( 1 )}} + {P}^{{V}_{i , j}^{( 2 )}} ] \qquad [ Equation 5 ]$$

$$V ( H ) = [ ( {V}_{i , j}^{( 1 )} , {V}_{i , j}^{( 2 )} ) ] \qquad [ Equation 6 ]$$

As in the above embodiment, a QC-LDPC code typically has one or more circulant permutation matrices corresponding to a single row block and column block in the parity check matrix. For reference, a matrix of size Z×Z in which multiple circulant permutation matrices overlap in a single row block and column block is called a circulant matrix (or, circulant, circulant matrix, circular matrix). Generally, a circulant matrix may include any numbers not just binary numbers as entries. However, for convenience, as this disclosure discusses binary codes, the above circulant matrix refers to a binary circulant matrix. The algebraic structures and features proposed in this disclosure can be extended in a similar manner to non-binary codes, but details are omitted in this disclosure.

Meanwhile, the base matrix (mother matrix, base graph) for the parity check matrix and the exponent matrix (or circular shift value matrix) of Equations 5 and 6 may indicate a binary matrix obtained by replacing each circulant permutation matrix and 0-matrix with 1 and 0, respectively, similarly to the definition used in Equation 3, and the circulant matrix (e.g., the sum of multiple circulant permutation matrices) included in one block may also be replaced with 1.

A simple example of the relationship between the parity check matrix, the exponent matrix (or, circular shift value matrix), and the base matrix is shown in Equation 7 below.

$${H}_{1} = [ \begin{matrix}{P}^{159} & O & {P}^{0} & {P}^{0} & O & O \\ {P}^{117} & {P}^{109} & O & {P}^{0} & {P}^{0} & O \\ O & {P}^{225} & {P}^{1} & O & {P}^{0} & {P}^{0} \\ {P}^{84} & {P}^{211} & {P}^{0} & O & O & {P}^{0}\end{matrix} ] ( = [ \begin{matrix}{P}^{159} & O & I & I & O & O \\ {P}^{117} & {P}^{109} & O & I & I & O \\ O & {P}^{225} & {P}^{1} & O & I & I \\ {P}^{84} & {P}^{211} & I & O & O & I\end{matrix} ] ) , \qquad [ Equation 7 ]$$

$$M ( {H}_{1} ) = [ \begin{matrix}1 & 0 & 1 & 1 & 0 & 0 \\ 1 & 1 & 0 & 1 & 1 & 0 \\ 0 & 1 & 1 & 0 & 1 & 1 \\ 1 & 1 & 1 & 0 & 0 & 1\end{matrix} ] ,$$

$$V ( {H}_{1} ) = [ \begin{matrix}159 & - 1 & 0 & 0 & - 1 & - 1 \\ 117 & 109 & - 1 & 0 & 0 & - 1 \\ - 1 & 225 & 1 & - 1 & 0 & 0 \\ 84 & 211 & 0 & - 1 & - 1 & 0\end{matrix} ] .$$

In Equation 7, the exponent (or shift value) of a 0-matrix of size Z×Z is represented as −1, but this is an example only and it may be expressed in various ways. In addition, the matrix representation of Equation 7 may be expressed in various other ways. As a specific example, the parity check matrix representation of LDPC codes defined in 3GPP TS 38.212 belonging to the 3GPP 5G standards may be used. In 3GPP TS 38.212, the sizes of the parity check matrices of the LDPC codes corresponding to BG1 (Base Graph 1) and BG2 (Base Graph 2) are too large, so they are represented using a table. When the corresponding representation method is applied to the matrices of Equation 7, the result is as shown in Table 1 below.

H_{BG1} is a matrix of size 4×8, and H₁ is a matrix of size 4Z×8Z. Entries of the base matrix (or base graph) and parity check matrix not expressed in Table 1 below correspond to 0 or a 0-matrix of size Z×Z.

TABLE 1

| H_{BG1} | | |
|---|---|---|
| Row index i | Column index j | V_{i, j} |
| 0 | 0 | 159 |
| | 2 | 0 |
| | 3 | 0 |
| 1 | 0 | 117 |
| | 1 | 109 |
| | 3 | 0 |
| | 4 | 0 |
| 2 | 1 | 225 |
| | 2 | 1 |
| | 4 | 0 |
| | 5 | 0 |
| 3 | 0 | 84 |
| | 1 | 211 |
| | 2 | 0 |
| | 5 | 0 |

If the base matrix and exponent matrix in Equation 7 above are expressed using a sequence, they may be expressed in the following manner.
M(H₁):
023
0134
1245
0125
V(H₁):
159 0 0
117 109 00
225 1 0 0
84 211 00
When the exponent matrix V(H₁) is represented as a sequence as shown above, it can be conveniently named in various ways, such as shift sequence, shift value sequence, or LDPC sequence. In the above sequence representation, M(H₁) lists the positions of columns with a non-zero entry in a row-wise manner, and V(H₁) lists the exponents or shift values of each circulant permutation matrix other than a 0-matrix in a row-wise manner. From the above sequences, the exponent matrix (or shift value matrix) can be defined exactly, and if information about the Z value is obtained, the parity check matrix can also be defined exactly.

Another simple example of the relationship between the parity check matrix, the exponent matrix (or circular shift value matrix), and the base matrix is shown in Equation 8 below. The example of Equation 8 illustrates a case where the parity check matrix has at least one block of size Z×Z including a circulant matrix to which two or more circulant permutation matrices correspond.

$${H}_{2} = [ \begin{matrix}{P}^{117} + {P}^{159} & {P}^{109} & {P}^{0} & {P}^{0} \\ {P}^{84} & {P}^{211} + {P}^{225} & {P}^{1} + {P}^{3} & {P}^{0}\end{matrix} ] , \qquad [ Equation 8 ]$$

$$M ( {H}_{2} ) = [ \begin{matrix}1 & 1 & 1 & 1 \\ 1 & 1 & 1 & 1\end{matrix} ] ,$$

$$V ( {H}_{2} ) = [ \begin{matrix}117 , 159 & 109 & 0 & 0 \\ 84 & 211 , 235 & 1 , 3 & 0\end{matrix} ] ,$$

$$W ( {H}_{2} ) = [ \begin{matrix}2 & 1 & 1 & 1 \\ 1 & 2 & 2 & 1\end{matrix} ] .$$

For reference, W(H₂) in Equation 8 above is a weight matrix for the base matrix, exponent matrix, or parity-check matrix, and it represents the number of circulant permutation matrices corresponding to the i^{th} row and j^{th} column of the base matrix and exponent matrix, or the i^{th} row block and j^{th} column block of the parity check matrix. For example, W(H₂) is a matrix whose entry in the i^{th} row and j^{th} column represents the number of circulant permutation matrices that constitute a Z×Z circulant matrix corresponding to the i^{th} row block and j^{th} column block in the parity check matrix. That is, W(H₂) is a matrix whose entry represents 0 in correspondence to a 0-matrix and represents w in correspondence to w circulant permutation matrices. (Note that the 0-matrix can be viewed as a circulant matrix in a broad sense, but it is not a circulant ‘permutation’ matrix.)

If the base matrix or parity check matrix or circular shift value matrix (or exponent matrix) defined in Equation 8 is expressed according to the method of expressing parity check matrices of LDPC codes in 3GPP TS 38.212 as in Table 1, it can be expressed as in Table 2 below.

H_{BG2} is a matrix of size 2×4, and H₂ is a matrix of size 2Z×4Z. Entries of the base matrix (or base graph) and parity check matrix not expressed in Table 2 below correspond to 0 or a 0-matrix of size Z×Z.

TABLE 2

| H_{BG2} | | |
|---|---|---|
| Row index i | Column index j | V_{i, j} |
| 0 | 0 | 117, 159 |
| | 1 | 109 |
| | 2 | 0 |
| | 3 | 0 |
| 1 | 0 | 84 |
| | 1 | 211, 225 |
| | 2 | 1, 3 |
| | 3 | 0 |

If the base matrix and exponent matrix of Equation 8 above are expressed using a sequence, they may be expressed in the following manner.
M(H₂):
123
0 123
V(H₂):
(117, 159) 109 00
(211,225) (1,3)0

As another way of representation, they can be expressed only in the form of a sequence using a weight matrix as follows.
M(H₂):
0 123
0 123
W(H₂):
2 1 1 1
1 22 1
V(H₂):
117 159 109 0 0
84 211 225 1 3 0

In the above representation, M(H₂) lists the positions of columns with a non-zero entry in a row-wise manner, W(H₂) is a matrix defined based on the number of circulant permutation matrices that constitute the circulant matrices corresponding to the base matrix, exponent matrix, or parity check matrix, and V(H₂) lists the exponents or shift values of each circulant matrix other than a 0-matrix in a row-wise manner. From the above sequences, the exponent matrix can be defined exactly, and if information about the Z value is obtained, the parity check matrix can also be defined exactly.

Since the performance of an LDPC code depends on the parity check matrix, it is necessary to design a parity check matrix for an LDPC codes with superior performance. Further, an LDPC encoding or decoding method capable of supporting various input lengths and code rates is needed.

Lifting is not only used for the efficient design of QC-LDPC codes, but may also refer to a method for generating parity check matrices with various lengths or generating LDPC codewords by using a given base matrix and exponent matrix. That is, lifting may be applied to efficiently design a very large parity check matrix from a given small mother matrix by setting a Z value determining the size of a circulant permutation matrix or a 0-matrix according to a specific rule, or may mean a method of generating parity check matrices of various lengths or generating LDPC codewords by applying an appropriate Z value to a given exponent matrix or its corresponding sequence.

A brief description will be given of the existing lifting methods and characteristics of the QC-LDPC codes designed through lifting with reference to the following reference document Myung2006.

Reference [Myung2006]

S. Myung, K. Yang, and Y Kim, “Lifting Methods for Quasi-Cyclic LDPC Codes,” IEEE Communications Letters. vol. 10, pp. 489-491, June 2006.

First, for a given LDPC code C₀, let C₁, . . . , C_{S} be S QC-LDPC codes to be designed using lifting, and let Lₖ be the values corresponding to the sizes of the row and column blocks of the parity check matrices of the QC-LDPC codes. Here, C₀ corresponds to the smallest LDPC code whose parity check matrix is the mother matrix of the C₁, . . . , C_{S} codes, and the Z₀ value corresponding to the size of the row and column blocks is 1. Also, for convenience, the parity check matrix Hₖ of the code Cₖ has an exponent matrix

$$V ( {H}_{k} ) = ( {V}_{ij}^{( k )} )$$

of size m×n, and each exponent

$${V}_{i , j}^{( k )}$$

is selected as one of the values {−1, 0, 1, 2, . . . , Zₖ−1}.

The existing lifting method is composed of stages such as C₀->C₁-> . . . ->C_{S}, and has a characteristic of satisfying the condition Zₖ₊₁=qₖ₊₁Zₖ (qₖ₊₁ is a positive integer, k=0,1, . . . , S−1). Additionally, due to the characteristics of the lifting process, if only the parity check matrix H_{S} of Cₛ is stored, all the QC-LDPC codes C₀, C₁, . . . , C_{S} can be represented using Equation 9 or Equation 10 below according to the lifting method.

$$V ( {H}_{k} ) ≡ ⌊ \frac{{Z}_{k}}{{Z}_{S}} V ( {H}_{S} ) ⌋ \qquad [ Equation 9 ]$$

$$or ,$$

$$V ( {H}_{k} ) ≡ V ( {H}_{S} ) ( mod {Z}_{k} ) \qquad [ Equation 10 ]$$

In addition to designing larger QC-LDPC codes C₁, . . . , C_{S} from C₀ as described above, generating smaller codes Cᵢ(i=k−1, k−2, . . . 1, 0) from a larger code Cₖ using an appropriate method such as Equation 9 or Equation 10 may also be called lifting. For reference, 3GPP TS 38.212 allows generation of LDPC codes of various lengths by using the lifting method of Equation 10.

The lifting method of Equation 9 or 10 above ensures that the Zₖ values corresponding to the sizes of the row or column blocks in the parity check matrices of the QC-LDPC codes Ck are multiples of each other, and the exponent matrix is also selected in a specific manner. This existing lifting method helps to easily design QC-LDPC codes with improved error floor characteristics by improving the algebraic or graph characteristics of each parity check matrix designed through lifting.

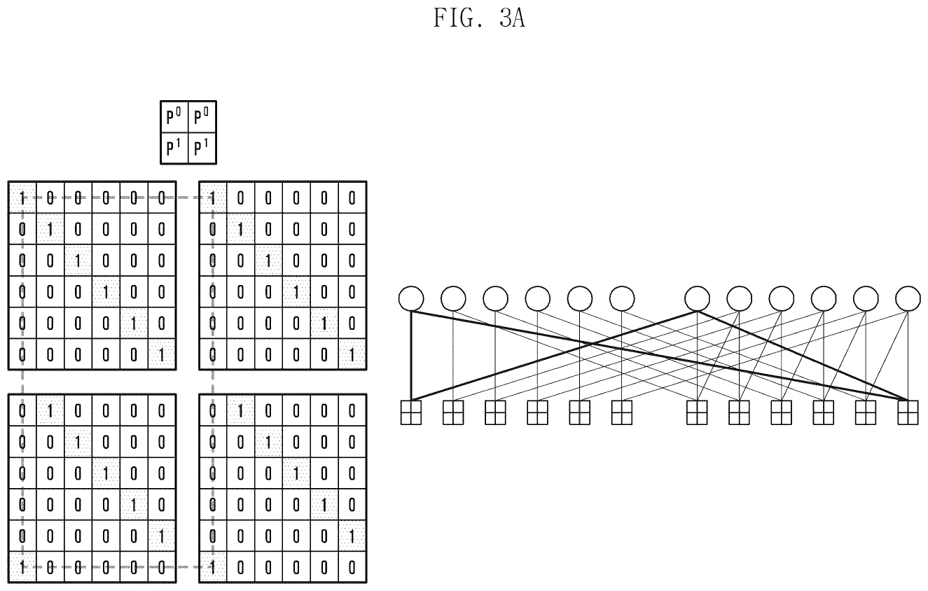

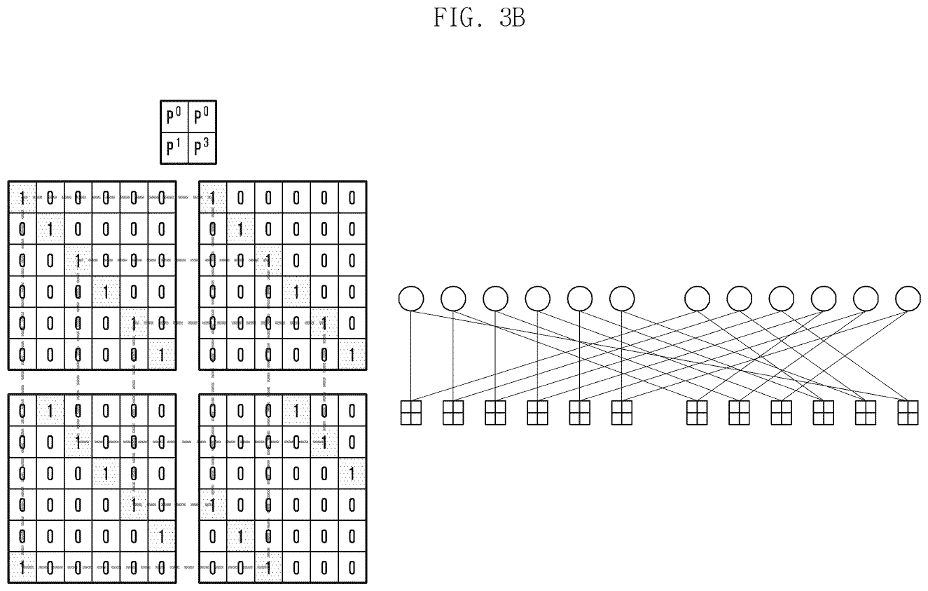

FIGS. 3A and 3B are schematic diagrams illustrating that the cycle characteristics may vary significantly depending on the exponent matrix of a QC-LDPC code.

FIG. 3A is a diagram illustrating the cycle characteristics of a QC-LDPC code.

The exponent matrix in FIG. 3A is

$${[ \begin{matrix}{P}^{0} & {P}^{0} \\ {P}^{1} & {P}^{1}\end{matrix} ]}_{( Z = 6 )} ,$$

in which case there may be many 4-cycles in the Tanner graph. Codes with many short cycles like this may experience severe decoding performance degradation.

FIG. 3B is a diagram illustrating the cycle characteristics of a QC-LDPC code.

The exponent matrix in FIG. 3B is

$${[ \begin{matrix}{P}^{0} & {P}^{0} \\ {P}^{1} & {P}^{3}\end{matrix} ]}_{( Z = 6 )} ,$$

in which case the length of the shortest cycle in the Tanner graph is 12. In this way, even a single change in the exponent of a circulant permutation matrix can significantly alter the cycle characteristics of the Tanner graph, the selection of the exponent matrix plays a crucial role in improving the performance of LDPC codes. The lifting method may be viewed as one of the design methods that takes these cycle characteristics into account.

In general, lifting may be viewed as utilizing the exponent matrix of Equation 4 for LDPC encoding and decoding by changing the values of its entries for various Z values. For example, when the exponent matrix of Equation 4 is V(H)=(V_{i,j}), and the exponent matrix transformed according to the Z value is V(H(Z))=(V_{i,j}(Z)), the following transform equation as in Equation 11 may generally be applied.

$${V}_{i , j} ( Z ) = \{ \begin{matrix}{V}_{i , j} & {V}_{i , j} < 0 \\ f ( {V}_{i , j} , Z ) & {V}_{i , j} \geq 0\end{matrix} or \qquad [ Equation 11 ]$$

$${V}_{i , j} ( Z ) = \{ \begin{matrix}{V}_{i , j} & {V}_{i , j} \leq 0 \\ f ( {V}_{i , j} , Z ) & {V}_{i , j} > 0\end{matrix}$$

In Equation 11, ƒ(x,Z) may be defined in various forms. For example, Equation 9 corresponds to

$$f ( x , Z ) = ⌊ \frac{Z}{{Z}_{max}} x ⌋ ( {Z}_{max} = {Z}_{S} ) ,$$

and Equation 10 may correspond to ƒ(x,Z)=mod(x,Z) (mod(a, b) means the modulo-b operation for a). In addition, ƒ(x, Z) may also be defined in various ways as shown in Equation 12 below.

$$f ( x , Z ) = mod ( x , {2}^{⌊ {log}_{2} Z} ) or \qquad [ Equation 12 ]$$

$$f ( x , Z ) = ⌊ \frac{x}{{2}^{D - ⌊ {log}_{2} Z ⌋}} ⌋ or$$

$$f ( x , Z ) = ⌊ \frac{Z}{D} x ⌋$$

In Equation 12, D means a constant that is a positive integer defined in advance.

For reference, in the transform equation of Equation 11, the reference value for applying the transform equation (or transform function) f (or, reference value of V_{i,j}, to distinguish between applications of V_{i,j} and ƒ(V_{i,j}, Z)) is conveniently represented as 0. However, this reference value may be set differently depending on the desired lifting size Z or the scheme of representing a 0-matrix of size Z×Z. For example, if a 0-matrix of size Z×Z is defined as a preset number or symbol other than a negative integer −1, the reference value for applying the transform equation f can be defined differently. Further, for representing the exponent matrix or LDPC sequence, if the exponent corresponding to a 0-matrix is initially excluded and not notated, the rule for values with an exponent less than 0 can be omitted in Equation 11. Since the transform equation f applies to a circulant permutation matrix or circulant matrix other than a 0-matrix, there are various ways to represent the method of omitting the transform for a 0-matrix of size Z×Z.

As an embodiment of the disclosure, a description will be given of a case where LDPC encoding and decoding are applied utilizing multiple exponent matrices or LDPC sequences based on a single fixed base matrix. That is, one base matrix is fixed, and the exponent matrix, (circular) shift value matrix, or LDPC sequence of an LDPC code defined based on the base matrix may be determined. Then, variable-length LDPC encoding and decoding are performed by applying lifting from the above matrix or sequence according to a lifting size included in each lifting size group. This method has the characteristic that the entries or numbers constituting the exponent matrix of the LDPC code or LDPC sequence may have different values, but the positions of those entries or numbers are exactly the same on the base matrix.

The LDPC codes defined in 3GPP 5G standard specification TS 38.212 are also designed in this way. Two base matrices H_{BG} are defined, and for each base matrix, eight exponent matrices (or circular shift value matrices)

$$V ( {H}_{{i}_{LS}} ) = ( {V}_{i , j}^{( {i}_{LS} )} ) ( {i}_{LS} = 0 , 1 , 2 , … , 7 )$$

are defined, which can be used for LDPC encoding. That is, according to the standard specification, the parity check matrices for various LDPC codes can be determined based on a total of two base matrices, 16 exponent matrices, and appropriate lifting sizes Z. However, in the TS 38.212 specification, the matrix corresponding to V(Hᵢ_{_{LS}}) is named a parity check matrix, and the matrix corresponding to a normal parity check matrix is named matrix H. V(Hᵢᵢ_{_{LS}}) is a matrix composed of integers, and a lifting size Z should be given to form a parity check matrix in the strict sense. However, as described above, for convenience, V(Hᵢᵢ_{_{LS}}) may also be called a parity check matrix.

For convenience of description, the following description uses the LDPC codes and their representations defined in 3GPP 5G standard specification TS 38.212 as much as possible, but conventional mathematical representations or other schemes may be used in some cases. First, the lifting sizes Z to be supported to determine the parity check matrix or matrix H of the LDPC code are shown in Table 3 below. (The set index i_{LS} for lifting size sets below is only an example and may be changed in a different order.)

TABLE 3

| Set index (i_{LS}) | Set of lifting sizes (Z) |
|---|---|
| 0 | {2, 4, 8, 16, 32, 64, 128, 256} |
| 1 | {3, 6, 12, 24, 48, 96, 192, 384} |
| 2 | {5, 10, 20, 40, 80, 160, 320} |
| 3 | {7, 14, 28, 56, 112, 224} |
| 4 | {9, 18, 36, 72, 144, 288} |
| 5 | {11, 22, 44, 88, 176, 352} |
| 6 | {13, 26, 52, 104, 208} |
| 7 | {15, 30, 60, 120, 240} |

In the disclosure, lifting sizes or block sizes are basically expressed in the same manner as in Table 3 above, but they can also be expressed in the same manner as in Table 4 below, and various other representations are also possible.

TABLE 4

| Set index (i_{LS}) | Set of lifting sizes (Z) |
|---|---|
| 0 | 2 × 2^{k}, k = 0, 1, 2, . . . , 7 |
| 1 | 3 × 2^{k}, k = 0, 1, 2, . . . , 7 |
| 2 | 5 × 2^{k}, k = 0, 1, 2, . . . , 6 |
| 3 | 7 × 2^{k}, k = 0, 1, 2, . . . , 5 |
| 4 | 9 × 2^{k}, k = 0, 1, 2, . . . , 5 |
| 5 | 11 × 2^{k}, k = 0, 1, 2, . . . , 5 |
| 6 | 13 × 2^{k}, k = 0, 1, 2, . . . , 4 |
| 7 | 15 × 2^{k}, k = 0, 1, 2, . . . , 4 |

In 3GPP 5G, lifting sizes or block sizes Z may be divided into multiple sets (or groups) as shown in Table 3 or Table 4. (in the following description, for convenience, they are referred to as lifting size sets (or groups) or block size sets (or groups))

In the 3GPP 5G standard, the parity check matrix or matrix H is determined based on the exponent matrix V(Hᵢ_{_{LS}}(Z))−V(Hᵢᵢ_{_{LS}}) (mod Z), which may be obtained using the lifting method of Equation 10. This may indicate that, when

$$V ( {H}_{{i}_{LS}} ) = ( {V}_{i , j}^{( {i}_{LS} )} ) and$$

$$V ( {H}_{{i}_{LS}} ( Z ) ) = ( {V}_{i , j}^{( {i}_{LS} )} ( Z ) ) ,$$

$${V}_{i , j}^{( {i}_{LS} )} ( Z ) = mod ( {V}_{i , j}^{( {i}_{LS} )} , Z )$$

for each i j. (For reference, in 3GPP 5G standard specification TS 38.212,

$${V}_{i , j}^{( {i}_{LS} )} ( Z )$$

is simply expressed as P_{i,j})

As described above in relation to Equation 11, it should be noted in the disclosure that no special transform is applied to the portion of the base matrix and the exponent matrix corresponding to a 0-matrix of size Z×Z. That is, also in V(Hᵢ_{_{LS}}(Z))≡V(Hᵢᵢ_{_{LS}}) (mod Z), unless otherwise specified, the portion corresponding to a 0-matrix does not undergo any special transform, and only the size of the 0-matrix may vary depending on the value of Z. As a specific example, in the representation used in the 3GPP 5G standard specification as in Table 1 and Table 2, the portion corresponding to a 0-matrix of size Z×Z is not initially notated. So, if a predefined transform such as modulo is appropriately performed only on V_{i,j}, included in Table 1 or Table 2, the part corresponding to the 0-matrix is naturally not transformed, which is equivalent to defining a 0-matrix with a different size. This representation is an example for convenience of description, and there may be various other representations.

For a given exponent matrix (or circular shift value matrix), the parity check matrix or matrix H can be transformed in various ways according to lifting sizes defined in Table 3, so the set of required lifting sizes can be defined differently depending upon the system. That is, Table 3 and Table 4 are only examples, and all lifting size (Z) values included in the lifting size (or block size) group (or set) of Table 3 and Table 4 may be utilized, some appropriate lifting sizes may be selected and utilized depending on the situation required by the system, and more diverse lifting size values may be added as needed.

For example, if the minimum transport block size (TBS) is 24, Z=2, 3, 4, 5, 6, 9, and 13 are virtually never used in the system. In this case, the lifting size set may be defined by excluding some Z values as shown in Table 5.

TABLE 5

| Set index (i_{LS}) | Set of lifting sizes (Z) |
|---|---|
| 0 | {8, 16, 32, 64, 128, 256} |
| 1 | {12, 24, 48, 96, 192, 384} |
| 2 | {10, 20, 40, 80, 160, 320} |
| 3 | {7, 14, 28, 56, 112, 224} |
| 4 | {18, 36, 72, 144, 288} |
| 5 | {11, 22, 44, 88, 176, 352} |
| 6 | {26, 52, 104, 208} |
| 7 | {15, 30, 60, 120, 240} |

In a communication system based on LDPC codes that applies Table 5 for the lifting size, as the minimum lifting size is 7, each column block that constitutes the parity check matrix of the LDPC code used for LDPC encoding and decoding may be composed of at least 7 columns.

If the minimum value of TBS is greater than or equal to 8 for future scalability, and additional values such as 8 or 16 are used, the lifting size set (or block size group) may be changed as in Table 6 below.

TABLE 6

| Set index (i_{LS}) | Set of lifting sizes (Z) |
|---|---|
| 0 | {4, 8, 16, 32, 64, 128, 256} |
| 1 | {6, 12, 24, 48, 96, 192, 384} |
| 2 | {(5,) 10, 20, 40, 80, 160, 320} |
| 3 | {7, 14, 28, 56, 112, 224} |
| 4 | {(9,) 18, 36, 72, 144, 288} |
| 5 | {11, 22, 44, 88, 176, 352} |
| 6 | {(13,) 26, 52, 104, 208} |
| 7 | {15, 30, 60, 120, 240} |

Table 6 is obtained by excluding only the cases where Z=2 or 3 from Table 3 or Table 4, this is because the minimum value of Z that can be determined when TBS is 8 or more is 4 or more.

As another example of setting the lifting size set, if the lifting sizes are classified into A sets Z₁, Z₂, Z₃, . . . , Z_{A}, this classification may be made basically in the following way. (k=1, 2, . . . )

$${Z}_{1} = \{ A , 2 A , … , {2}^{k} A \}$$

$${Z}_{2} = \{ ( A + 1 ) , 2 ( A + 1 ) , … , {2}^{k} ( A + 1 ) \}$$

$$…$$

$${Z}_{i} = \{ ( A + i - 1 ) , 2 ( A + i - 1 ) , … , {2}^{k} ( A + i - 1 ) \}$$

$$…$$

$${Z}_{A} = \{ 2 A - 1 , 2 ( 2 A - 1 ) , … , {2}^{k} ( 2 A - 1 ) \}$$

For example, the cases where A=4 and A=8 may be represented as in Table 7-1 and Table 7-2 below. (k=0, 1, 2, . . . )

TABLE 7-1
Set of lifting sizes (Z)

| | |
|---|---|
| 4, 8, 16, 32, . . . | (=4 × 2^{k}) |
| 5, 10, 20, 40, . . . | (=5 × 2^{k}) |
| 6, 12, 24, 48, . . . | (=6 × 2^{k}) |
| 7, 14, 28, 56, . . . | (=7 × 2^{k}) |

TABLE 7-2
Set of lifting sizes (Z)

| | |
|---|---|
| 8, 16, 32, 64, . . . | (=8 × 2^{k}) |
| 9, 18, 36, 72, . . . | (=9 × 2^{k}) |
| 10, 20, 40, 80, . . . | (=10 × 2^{k}) |
| 11, 22, 44, 88, . . . | (=11 × 2^{k}) |
| 12, 24, 48, 96, . . . | (=12 × 2^{k}) |
| 13, 26, 52, 108, . . . | (=13 × 2^{k}) |
| 14, 28, 56, 112, . . . | (=14 × 2^{k}) |
| 15, 30, 60, 120, . . . | (=15 × 2^{k}) |

Defining the lifting size set as shown in Table 7-1 and Table 7-2 has the advantage of allowing a relatively uniform distribution of Z values. The lifting size sets defined in Table 7-1 and Table 7-2 all contain the same number of Z values, but desired Z values may be added to or removed from each set as needed. For example, it is possible to define the lifting size sets of Table 3 to Table 6 based on the lifting size sets of Table 7-2 above.

In addition, by appropriately setting the k value range in Table 7-1 and Table 7-2, Z values suitable for the system may be set. For example, setting k=0, 1, . . . , 6 yields lifting size sets having seven distinct Z values each, and setting k=3, 4, . . . , 6 yields lifting size sets having four distinct Z values each. However, the above k values are an embodiment, and the example of k values does not limit the scope of the disclosure. Additionally, in some cases, it is also possible to add or exclude appropriate Z values to or from the above lifting size sets. For example, if the maximum Z value set in the system is Zmax, all values greater than Zmax may be removed (e.g., Zmax=768). In addition, if all Z values supported by the existing 3GPP 5G standard are included, at least some of values such as 2, 3, 4, 5, 6, and 7 may be further included. Definitely, even if 5G or 6G systems support additional values like TBS=8 and 16, Z values such as 2 and 3 are not used. Hence, only Z values such as 4, 6 and 7 or 4, 5, 6 and 7 may be included, and values that are not actually used in 5G may be excluded. Table 8 below shows specific examples of lifting size sets. (In Table 8, the numbers in (indicate values that may or may not be used as a lifting size.)

TABLE 8

| Set index (i_{LS}) | Set of lifting sizes (Z) |
|---|---|
| 0 | {(2, 4,) 8, 16, 32, 64, 128, 256, 512} |
| 1 | {(3, 6,) 12, 24, 48, 96, 192, 384, 768} |
| 2 | {(5,) 10, 20, 40, 80, 160, 320, 640} |
| 3 | {7, 14, 28, 56, 112, 224, 448(, 896)} |
| 4 | {(9,) 18, 36, 72, 144, 288, 576} |
| 5 | {11, 22, 44, 88, 176, 352, 704} |
| 6 | {(13,) 26, 52, 104, 208, 416(, 832)} |
| 7 | {15, 30, 60, 120, 240, 480(, 960)} |

Lifting size sets can be defined in various ways in addition to those described in Tables 3 to 8. However, they share the following common characteristics: multiple lifting size sets should not contain overlapping lifting sizes, and the lifting sizes within a lifting size set should be multiples or divisors of each other. Tables 3 to 8 are composed of consecutive multiples of 2^{k} (k=0, 1, 2, . . . ) for the smallest lifting size in each lifting size set, but in general, they may also be composed of non-consecutive multiples such as 2^{k} (k=0, 1, 3, 5, . . . ), and multiples of an integer other than 2 may also be included.

In new communication systems including 6G systems, to support backward compatibility with existing systems (e.g., 5G systems), the existing lifting size sets may be maintained (e.g., Table 3 or Table 4), and new lifting size sets may be added (e.g., Tables 5 to 8). Alternatively, when one lifting size set is defined, if the range of TBS values used is determined differently in advance based on system settings such as the application scenario or target BLER, the range of Z values used will also vary. For example, if a first minimum TBS value and a first maximum TBS value are set for a service applying first target BLER, and if a second minimum TBS value and/or a second maximum TBS value are set for a service applying second target BLER, the first minimum TBS value and the second minimum TBS value may be different, or the first maximum TBS value and the second maximum TBS value may be different (both the minimum values may be different and the maximum values may be different).

Additionally, the applicable service scenario or target BLER may be determined based on higher-layer signaling information. For example, the CQI table or MCS table can be typically determined in consideration of the target service scenarios or BLERs. (e.g., first CQI table and/or first MCS table for first target service or BLER, second CQI table and/or second MCS table for second target service or BLER, third CQI table and/or third MCS table for third target service or BLER, . . . )

As a result, this may indicate that the range of lifting sizes to be used or the set of lifting sizes to be used can be determined from higher-layer signaling information, and the corresponding intermediate operations can vary depending on the system. Further, the set of lifting sizes to be used can be indicated via physical layer signaling or higher-layer signaling. The parity check matrix can be determined based on the indicated set of lifting sizes and the determined lifting size Z value.

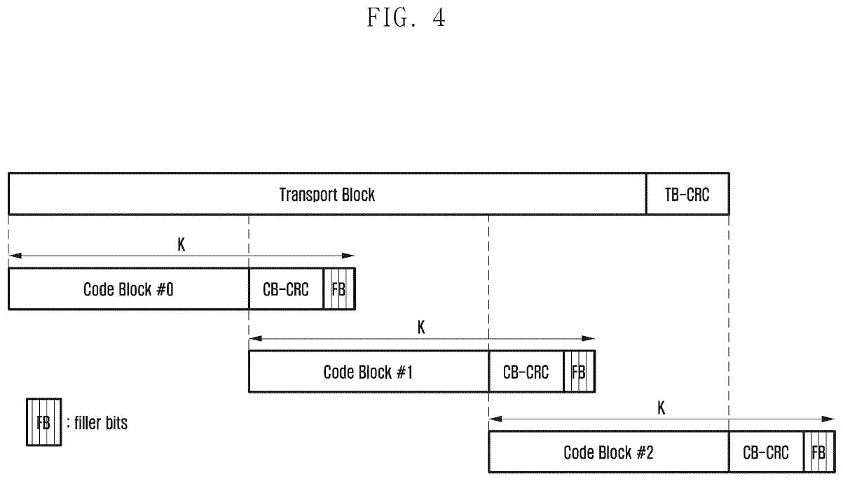

FIG. 4 is a diagram illustrating the structure of a transport block according to an embodiment of the disclosure.

With reference to FIG. 4, a transport block composed of A bits is appended with L bits of CRC bits (TB-CRC bits), and a single transport block can become a single code block. Additionally, if the value B=A+L exceeds a specific threshold, it may be divided into multiple code blocks through an appropriate segmentation process. Here, the sizes K of all code blocks are the same. To this end, specific bits called null bits or filler bits may be added to some code blocks. These null bits or filler bits typically correspond to a value of 0, but this limitation is not always required, and any preset specific bits may be configured as null or filler bits. This act of adding preset bits such as null bits or fillers is commonly called shortening because it reduces the size of the actual information bits, and if these values are 0, it may also be called zero-padding.

After the size of the transport block to be transmitted (transport block size, TBS) is determined, one of the two different base matrices of the LDPC code used for LDPC encoding or decoding may be determined based on the code rate indicated by the TBS size and MCS through a method such as “determining base matrix” below.

[Determining base matrix]

The LDPC base matrix for LDPC encoding and decoding of a transport block with TBS=A may be determined based on the TBS size and the code rate indicated by the MCS as follows:
If A≤292 (or 288), or A≤3824 and R≤0.67, or R≤0.25, LDPC encoding may be performed using LDPC base matrix 2.
Otherwise, LDPC encoding may be performed using LDPC base matrix 1. For reference, base matrix 1 M(H_{BG1}) and base matrix 2 M(H_{BG2}) defined in the 3GPP 5G standard are as follows.
M(HBG1):
0123 569101112131516181920212223
023457891112141516171921222324
0124567891013 1415171819202425
013467810111213 1416171820212225
0 1 26
01 3 12 16 21 22 27
0 6 10 11 13 17 18 20 28
0 1 4 7 8 14 29
01 3 12 16 19 21 22 24 30
0 1 10 11 13 17 18 20 31
124781432
0 1 12 16 21 22 23 33
0 1 10 11 13 18 34
03 7 20 23 35
0 12 15 16 17 21 36
0 1 10 13 18 25 37
13 11 20 22 38
0 14 16 17 21 39
1 12 13 18 1940
0 178 10 41
0 3 9 11 22 42
1 5 16 20 21 43
0 12 13 17 44
12 10 18 45
0 3 4 11 22 46
1 6 7 14 47
024 15 48
1 6 8 49
0 4 19 21 50
1 14 18 25 51
0 10 13 24 52
1 7 22 25 53
0 12 14 24 54
1 2 11 21 55
07 15 17 56
1 6 12 22 57
0 14 15 18 58
1 13 23 59
0 9 10 12 60
13 7 1961
0 8 17 62
13 9 18 63
0 4 24 64
1 16 18 25 65
0 7 9 22 66
1 6 10 67
M(HBC2):
0123691011
034567891112
0 13 4 8 10 12 13
124567891013
01 11 14
01 57 11 15
05791116
1 5 7 11 13 17
0 1 12 18
1 8 10 11 19
0 1 6 7 20
079 13 21
1 3 11 22
0 1 8 13 23
1 6 11 13 24
0101125
1 9 11 12 26
1 5 11 12 27
0 6 7 28
0 110 29
1 4 11 30
08 13 31
1 2 32
03 5 33
1 2 9 34
0 5 35
27 12 13 36
0637
1 2 5 38
0439
2 5 7 9 40
1 13 41
0 5 12 42
27 10 43
0 12 13 44
1 5 11 45
0 2 7 46
10 13 47
1 5 11 48
0 7 12 49
2 10 13 50
1 5 11 51

The sizes of base matrix 1 M(H_{BG1}) and base matrix 2 M(H_{BG2}) are 46×68 and 42×52, respectively, and the sizes of the parity check matrices determined from the above base matrices are 46Z×68Z and 42Z×52Z.

In addition, the number of CRC bits (L_{TB}) to be appended to the transport block may be determined based on the determined TBS as follows.

### [Determining Number of Transport Block CRC Bits]

The CRC bit size L_{T}B for a transport block with TBS=A may be set differently depending on the TBS value as follows.

$${L}_{TB} = 24 if A > 3824 , otherwise {L}_{TB} = 16.$$

Based on the TBS size A determined in this manner or the total number of bits (B=A+L) after adding the CRC to the transport block, appropriate code blocks may be determined from the transport block, and LDPC encoding and decoding may be performed for each code block. Here, the process of determining the code block size (CBS) is described in more detail as follows:

### [Determining CBS]

The input bit sequence for code block segmentation may be represented as b₀, b₁, . . . , b_{B-1} (B>0). If B is greater than the maximum code block size K_{cb}, segmentation of the input bit sequence is performed, and L=24 CRC bits are appended to each code block. For LDPC base matrix 1, the maximum code block size K_{cb} is 8448, and for LDPC base matrix 2, the maximum code block size K_{cb} is 3840.

The specific steps are described as follows.

Step 1: The number C of code blocks may be determined.

$$- If B \leq {K}_{cb} , L = 0 , C = 1 , and {B}^{′} = B$$

$$- Otherwise , L = 24 , C = ⌈ B / ( {K}_{cb} - L ) ⌉ , and$$

$${B}^{′} = B + C \times L .$$

Step 2: Let the bits output from the code block segmentation be cᵣ₀, cᵣ₁, . . . , cr_{(Kr-1)}, where r may represent the code block number (0≤r<C), and Kᵣ (=K) may represent the number of bits in the code block with code block number r. Here, K, the number of bits contained in each code block, may be calculated as follows:

$$- {K}^{′} = {B}^{′} / C ;$$

For LDPC base matrix 1, K_{b}=22.
For LDPC base matrix 2,
if B>640, K_{b}=10;
if 560<B≤640, K_{b}=9;
if 192<B≤560, K_{b}=8;
if B≤192, K_{b}=6.

Step 3: Among the Z values in Table 3, the minimum value Z, satisfying K_{b}·Z_{c}≥K′ may be determined. For LDPC base matrix 1, K=22Z_{c}, and for LDPC base matrix 2, K=10Z_{c}.

At step 2 of “determining CBS”, the K_{b} value corresponds to a column or column block corresponding to LDPC information bits in the base matrix (or base graph) or parity check matrix of the LDPC code, and may correspond to the maximum value of LDPC information bits without shortening or zero padding (=K_{b}Z_{c}). For example, although the number of columns (or column blocks) corresponding to information bits is 10 in the parity check matrix corresponding to LDPC base matrix 2 or base matrix 2, if K_{b}-6, LDPC encoding/decoding is substantially performed on maximum 6Z_{c} information bits, meaning that those information bits corresponding to at least (10−K_{b})Z_{c}=4Z_{c} columns in the parity check matrix are shortened or zero-padded. Here, shortening or zero padding may mean that the transmitter and receiver assign a pre-agreed bit value such as 0, or may mean not utilizing the corresponding portion of the parity check matrix.

The lifting size Z value for LDPC encoding and decoding may be determined based on the lifting size sets shown in Tables 3 to 8, or on lifting size sets with specific lifting size values added or removed. Z values are included in a specific set determined in advance based on index i_{LS}. When the Z value is determined at step 3 of “determining CBS”, the set or set index i_{LS} corresponding to the Z value is determined. Then, the parity check matrix of the LDPC code corresponding to the index or the sequence corresponding thereto may also be determined. The parity check matrix of the LDPC code or sequence corresponding thereto determined in this manner is transformed by applying a modulo operation based on the lifting size Z to the parity check matrix or sequence, thereby supporting encoding and decoding of LDPC codes of various lengths. Also in the 3GPP 5G standard, each number included in the parity check matrix or sequence of the LDPC code represents a value corresponding to a circulant permutation matrix.

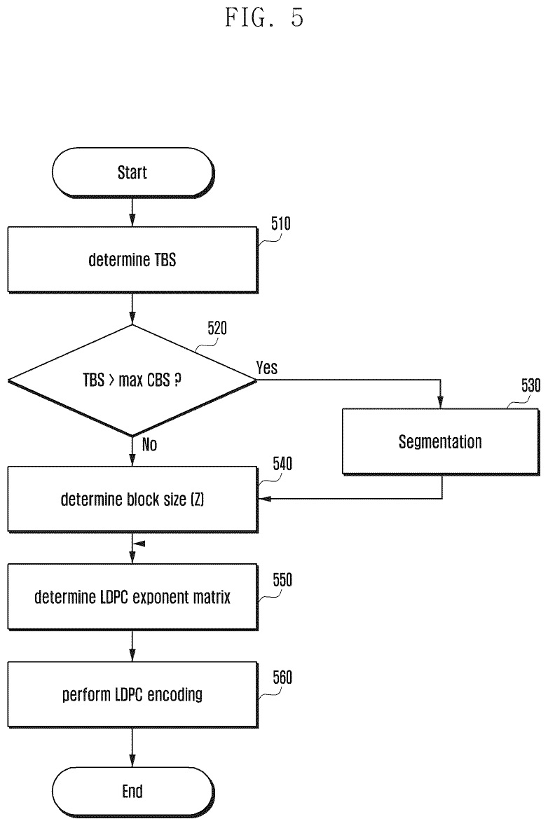

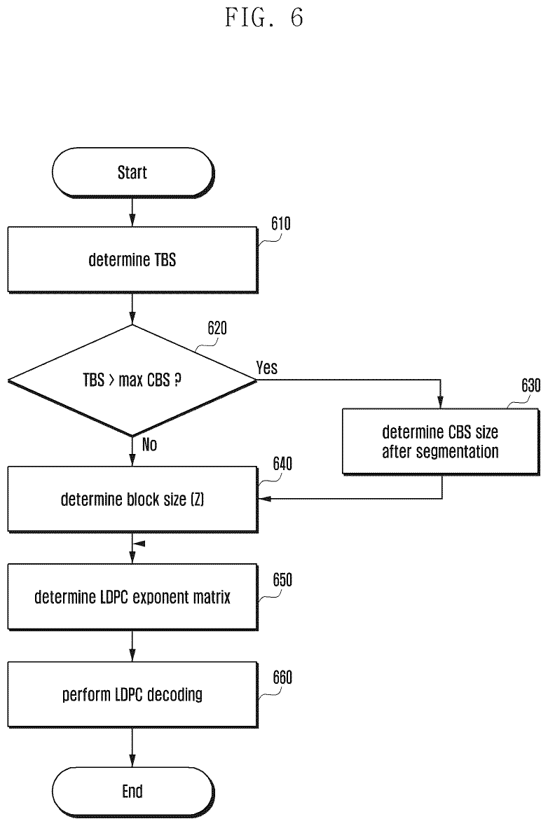

Flowcharts for embodiments of LDPC encoding and decoding processes based on the designed base matrix or exponent matrix are shown in FIGS. 5 and 6.

FIG. 5 is a diagram illustrating an embodiment of the LDPC encoding process.

First, the transmitter determines the transport block size (TBS) to be transmitted as shown at step 510 of FIG. 5. At step 520, the transmitter determines whether the TBS is greater than or less than or equal to the max CBS.

If the TBS is greater than the max CBS, at step 530, the transmitter may segment the transport block to determine the CBS. If the TBS is less than or equal to the max CBS, the transmitter skips the segmentation operation and determines the CBS to be the TBS.

At step 540, the transmitter determines the lifting size Z value to be applied to LDPC encoding based on the CBS.

Thereafter, at step 550, the transmitter determines a parity check matrix or sequence based on the TBS, CBS, or lifting size Z value. Alternatively, the transmitter may determine an LDPC exponent matrix or sequence that has an effect algebraically equivalent to the parity check matrix.

Thereafter, at step 560, the transmitter performs LDPC encoding based on the parity check matrix or sequence. Alternatively, the transmitter may perform LDPC encoding based on the exponent matrix or sequence at step 560. Further, the transmitter may perform LDPC encoding based on the lifting size and the exponent matrix or sequence at step 560.

For reference, at step 550, a process of transforming the determined LDPC exponent matrix or sequence may be performed based on the determined lifting size in some cases. It is evident that the LDPC exponent matrix or sequence, or parity check matrix for LDPC encoding may be determined in various ways, depending on the system, based on the TBS or CBS. For example, the transmitter may first determine the base matrix based on the TBS, and then determine the LDPC exponent matrix or sequence or parity check matrix based on the determined base matrix and the CBS. Various other methods can also be applied. For reference, additional operations may be included between step 520 and step 540 or between step 530 and step 540 depending on the system. For example, in the case of a 3GPP 5G system, when base matrix 2 (M(H_{BG2})) is used, a process of determining the K_{b} value, which may indicate the number of columns to be actually used in the base matrix or the number of column blocks to be used in the parity check matrix, may be included depending on the TBS size. (For reference, shortening is applied to the column blocks of the parity check matrix corresponding to the (10−K_{b}) columns of the base matrix.)

Likewise, the LDPC decoding process may be represented as in FIG. 6.

FIG. 6 is a diagram illustrating an embodiment of the LDPC decoding process.

After determining the TBS at step 610, at step 620, the receiver determines whether the TBS is greater than or less than or equal to the max CBS.

If the TBS is greater than the max CBS, at step 630, the receiver determines the value of the CBS after segmentation. If the TBS is determined to be less than or equal to the max CBS, the TBS is determined to be equal to the CBS.

At step 640, the receiver determines the lifting size Z value to be applied to LDPC decoding.

Thereafter, at step 650, the receiver determines the parity check matrix or sequence based on the TBS, CBS, or lifting size Z values. Alternatively, the transmitter may determine the exponent matrix or sequence that has an effect algebraically equivalent to the parity check matrix.

Thereafter, at step 660, the receiver may perform LDPC decoding based on the parity check matrix or sequence. Alternatively, the receiver may perform LDPC decoding by using an exponent matrix or sequence at step 660. For reference, in some cases, step 650 may include a process of transforming the determined LDPC exponent matrix or sequence based on the determined lifting size. It is evident that the LDPC exponent matrix or sequence, or parity check matrix for LDPC decoding may be determined in various ways, depending on the system, based on the TBS or CBS. For example, the receiver may first determine the base matrix based on the TBS, and then determine the LDPC exponent matrix or sequence, or parity check matrix based on the determined base matrix and CBS. Various other methods may also be applied.

According to the above embodiment, the process of determining the exponent matrix or sequence of the LDPC code at steps 550 and 650 of FIGS. 5 and 6 has been described for cases where the exponent matrix or sequence is determined based on one of the TBS, CBS, or lifting size Z, but various other methods may exist. Further, additional operations may be included between step 620 and step 640 or between step 630 and step 640 of FIG. 6 depending on the system. For example, in the case of a 3GPP 5G system, when using base matrix 2 (M(H_{BG2})), a process may be included to determine the K_{b} value, which indicates the number of columns to be actually used in the base matrix or the number of column blocks to be used in the parity check matrix, depending on the TBS size. For reference, the receiver may identify that the bits corresponding to the column blocks of the parity check matrix corresponding to the (10−K_{b}) columns of the base matrix have been shortened at the transmitter, so the receiver may additionally perform appropriate operations on the shortened bits before performing LDPC decoding.

In the embodiment of the LDPC encoding and decoding process based on the base matrix and exponent matrix (or LDPC sequence) of the LDPC code in FIGS. 5 and 6, LDPC encoding and decoding at various code rates and lengths may be supported by appropriately shortening or puncturing some of the information bits of the LDPC code and puncturing and repeating some of the codeword bits. For example, as in the 3GPP 5G standard technology, by applying shortening to some of the information bits in the LDPC encoding process of FIG. 5, puncturing the information bits corresponding to the first two columns of the base matrix, e.g., the first 2Z_{c} columns in the parity check matrix, puncturing some of the parity bits, or repeating some of the LDPC codeword, various information word lengths (or code block lengths) and various code rates can be supported.

When the given input bits or code block bits are represented as i₀, i₁, i₂, . . . , i_{K-1} and the encoding bits are represented as d₀, d₁, d₂, . . . , d_{N-1} (where N=66Z_{c} for base matrix 1 and N=50Z_{c} for base matrix 2), a part of the encoding process may be defined as in Table 9 below.

TABLE 9

```
for k = 2Z_{c} to K − 1
  if iₖ ≠ < NULL >
      d_{k-2Z}_{_{c}} = iₖ_{;}
  else
      iₖ = 0;
    d_{k-2Z}_{_{c}} = < NULL >;
  end if
end for
```

According to the above encoding process, the first 2Z_{c} bits i₀, i₁, i₂, . . . , i_{2Z}_{_{c}}₋₁ of the input bits or code block bits are not included in the encoding bits. That is, this may indicate that these 2Z_{c} bits are punctured at the transmitter and are not transmitted to the receiver. For reference, if some of the information bits are punctured, this may indicate the transmitter does not transmit a portion of the information word 102 in FIG. 1, and thus the receiver may perform decoding by treating the untransmitted information bits as erasures. In other words, the punctured bits are considered as if they were lost, and since they have an equal probability of being 0 or 1, the receiver can perform decoding by inserting the corresponding values.

The information bits punctured during the above encoding process may be not transmitted even in retransmissions. In the case where a circular buffer is used for rate matching, if rate matching and retransmission are performed without storing the punctured information bits in the circular buffer, the punctured information bits may never be transmitted.

On the other hand, some of the information bits may be punctured in the case of initial transmission, and all or some of the punctured information bits may be transmitted in the case of retransmission. All information bits are stored in the circular buffer, and in the case of initial transmission, the redundancy value (RV) may be appropriately set so that some of the information bits are punctured (e.g., RV0 value is set to exclude the information bits to be punctured). Even if some of the information bits are punctured in initial transmission, since their bit values are stored in the circular buffer, in the case of retransmission, some or all of the punctured information bits may be transmitted according to the circular buffer rate matching operation and selection of an appropriate RV value.

In Table 9, d₀, d₁, d₂, . . . , d_{N-1} are referred to as encoding bits for convenience, but the definition of encoding bits may change depending on the convenience of description. For example, a bit sequence after puncturing a portion of the information bits, such as d₀, d₁, d₂, . . . , d_{N-1} in Table 9, may be defined as encoding bits, but since the input bits or code block bits i₀, i₁, i₂, . . . , i_{K-1} are actually used to generate the parity bit vector w in the encoding process, with respect to before puncturing the information bits

$$( \underline{i} , \underline{w} ) = ( {i}_{0} , {i}_{1} , {i}_{2} , … , {i}_{{K}_{idpc} - 1} , {w}_{0} , {w}_{1} , {w}_{2} , … , {w}_{{N}_{idpc} - {K}_{idpc} - 1} )$$

may be defined as encoding bits. Additionally, the bit sequence e₀, e₁, e₂, . . . , e_{E-1}, to which rate matching is applied based on the amount of allocated resources, may be defined as encoding bits; and the bit sequence ƒ₀, ƒ₁, ƒ₂, . . . , ƒ_{E-1}, to which interleaving is applied to the rate-matched bit sequence, may be defined as encoding bits. In addition, the encoding bit sequence may be defined in various ways for convenience of description, but usually, the bit sequence d₀, d₁, d₂, . . . , d_{N-1} related to actual transmission in the system or (i, w) related to the encoding process may be defined as the encoding bits.

The LDPC decoding process of FIG. 6 may perform decoding by adding appropriate operations on the shortened information bits, punctured bits, or repeated bits in response to the transmitter operation. Typically, as the shortened information bits are 0, the receiver performs decoding by excluding the column corresponding to the shortened bits from the parity check matrix, or by setting the shortened bits to preset values in the system. (Since it's certain to be 0, the highest value is typically set in correspondence to the system-defined 0.) Punctured parity bits are considered erasures and have an equal probability of being 0 or 1, so the receiver may perform decoding by inserting corresponding values, or may perform decoding without using at least some of the rows corresponding to the punctured parity bits depending on the structure of the parity check matrix. In general, when puncturing a parity bit corresponding to a column with degree 1, the LDPC decoder may perform decoding without using some or all of the corresponding part in the parity check matrix, which has the advantage of reducing decoding complexity.

Furthermore, when supporting variable information word lengths or variable code rates by using LDPC code shortening or zero padding, code performance may be improved depending on the shortening order or method. When the shortening order is set, encoding performance may be improved by appropriately rearranging the order of some or all of the given base matrix. Also, performance may be improved by appropriately determining the lifting size or the number of column blocks to which shortening is applied for a specific information word length (or code block length CBS). Likewise, there are methods to improve LDPC code performance by adjusting the puncturing order of parity bits or the transmission order of the generated LDPC codeword. For example, compared with simple puncturing of parity bits to support variable code rates, appropriately puncturing a portion of the information bits and the parity bits may provide superior performance. In addition, when repeating some of the LDPC codeword to support lower code rates, the corresponding order may be appropriately determined in advance to improve LDPC encoding performance.

Typically, during the LDPC encoding process, the transmitter first determines the size of input bits (or code blocks) to which LDPC encoding will be applied, determines the lifting size Z for LDPC encoding based on this size, determines an appropriate LDPC exponent matrix or sequence based on the lifting size, and performs LDPC encoding based on the lifting size Z and the determined exponent matrix or LDPC sequence. Here, the LDPC exponent matrix or sequence may be applied to LDPC encoding without transform, and in some cases, the LDPC exponent matrix or sequence may be appropriately transformed according to the lifting size Z to perform LDPC encoding.

Similarly, during the LDPC decoding process, the receiver determines the size of input bits (or code blocks) for the transmitted LDPC codeword, determines the lifting size Z for LDPC decoding based on the determined size, determines an appropriate LDPC exponent matrix or sequence according to the lifting size, and performs LDPC decoding based on the lifting size Z and the determined exponent matrix or LDPC sequence. Here, the LDPC exponent matrix or sequence may be applied to LDPC decoding without transform, and in some cases, the LDPC exponent matrix or sequence may be appropriately transformed according to the lifting size Z to perform LDPC decoding.

In a parity check matrix, the submatrix corresponding to the parity bits often has a special structure for efficient encoding. In this case, lifting may change the encoding method or complexity. Hence, to maintain the same encoding method or complexity, lifting may be not applied to a portion of the exponent matrix corresponding to the submatrix of parity bits in the parity check matrix, or lifting different from that applied to the exponent matrix of the submatrix corresponding to the information bits may be applied. In other words, the lifting scheme applied to the sequence corresponding to the information bits within the exponent matrix and the lifting scheme applied to the sequence corresponding to the parity bits may be set differently, and in some cases, lifting may be not applied to a portion or all of the sequence corresponding to the parity bits, so that a fixed value may be used without transforming the sequence.

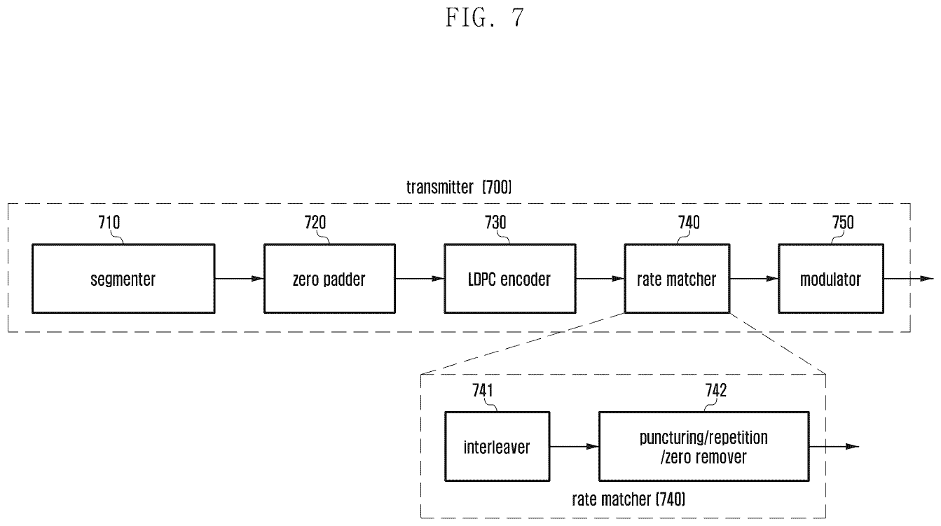

FIG. 7 is a block diagram of a transmitter according to an embodiment of the disclosure.

Specifically, as shown in FIG. 7, to process variable-length input bits, the transmitter 700 may include a segmenter 710, a zero padder 720, an LDPC encoder 730, a rate matcher 740, and a modulator 750. The rate matcher 740 may include an interleaver 741 and a puncturing/repetition/zero remover 742.

Here, the components illustrated in FIG. 7 are components that perform encoding and modulation for variable-length input bits, and this is only an example. In some cases, some of the components illustrated in FIG. 7 may be omitted or changed, and other components may be added.

Meanwhile, the transmitter 700 may determine necessary parameters (e.g., input bit length, ModCod (modulation and code rate), parameter for zero padding (or shortening), code rate/code length of LDPC code, parameter for interleaving, parameter for repetition and puncturing, and at least one modulation scheme), encode the input bits based on the determined parameters, and transmit them to the receiver 800.

As the number of input bits is variable, if the number of input bits is greater than a preset value, the input bits may be segmented into blocks with a length less than or equal to the preset value. Additionally, each of the segmented blocks may correspond to one LDPC coded block. However, if the number of input bits is less than or equal to the preset value, the input bits are not segmented and may correspond to one LDPC coded block.

Meanwhile, the transmitter 700 may store various parameters used for encoding, interleaving, and modulation. Here, the parameters used for encoding may include at least one of LDPC code rate, codeword length, or information about the parity check matrix. Additionally, the parameters used for interleaving may include information about the interleaving rule, and the parameters used for modulation may include information about the modulation scheme. In addition, information about puncturing may include the puncturing length. Further, information about repetitions may include the repetition length. Information about the parity check matrix may include the exponent values of the circulant matrix or values algebraically equivalent thereto when using the parity matrix proposed in the disclosure.

In this case, each component constituting the transmitter 700 may perform an operation using these parameters.

Meanwhile, although not shown, in some cases, the transmitter 700 may further include a controller (not shown) for controlling the operation of the transmitter 700.

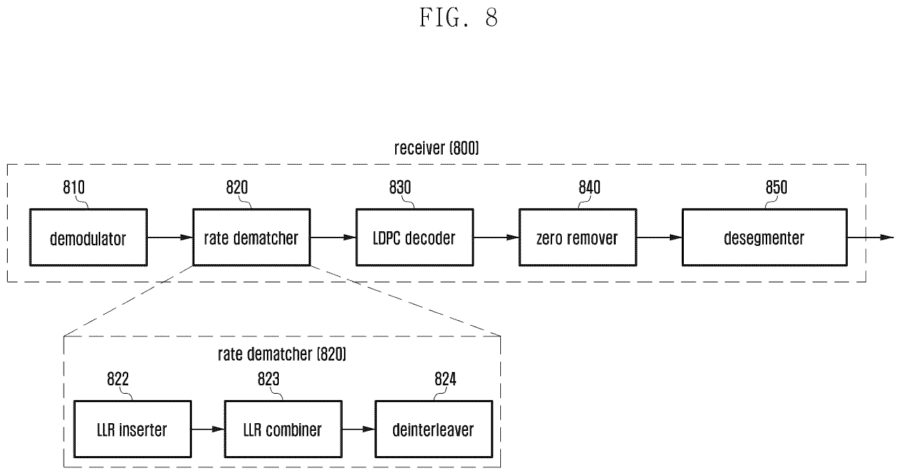

FIG. 8 is a block diagram of a receiver according to an embodiment of the disclosure.

Specifically, as shown in FIG. 8, to process variable length information, the receiver 800 may include a demodulator 810, a rate dematcher 820, an LDPC decoder 830, a zero remover 840, and a desegmenter 850. The rate dematcher 820 may include an LLR (log likelihood ratio) inserter 822, an LLR combiner 823, and a deinterleaver 824.

Here, the components illustrated in FIG. 8 are components that perform functions corresponding to those of the components illustrated in FIG. 8, and this is only an example. In some cases, some of the components illustrated in FIG. 8 may be omitted or changed, and other components may be added.

The parity check matrix in the present disclosure may be read from the memory, may be provided in advance to the transmitter or the receiver, or may be generated directly by the transmitter or the receiver. Additionally, the transmitter may store or generate a sequence or exponent matrix corresponding to the parity check matrix or values algebraically equivalent thereto, and apply it to encoding. Likewise, the receiver may store or generate a sequence or exponent matrix corresponding to the parity check matrix or values algebraically equivalent thereto, and apply it to decoding.

Next, a detailed description will be given of the receiver operation with reference to FIG. 8.

The demodulator 810 demodulates a signal received from the transmitter 700.

Specifically, the demodulator 810 is a component corresponding to the modulator 750 of the transmitter 700, and may demodulate a signal received from the transmitter 700 to generate values corresponding to bits transmitted from the transmitter 700.

To this end, the receiver 800 determines parameters necessary for demodulation and decoding (e.g., at least one of input bit length, ModCod (modulation and code rate), parameter for zero padding (or shortening), code rate/codeword length of the LDPC code, parameter for interleaving, parameter for repetition and puncturing, or modulation scheme). Based on the determined parameters, the demodulator 810 may demodulate the signal received from the transmitter 700 according to the mode, and perform a decoding process to generate values corresponding to the LDPC codeword bits.

Meanwhile, the values corresponding to the bits transmitted from the transmitter 700 may be a likelihood ratio (LR) value or a log likelihood ratio (LLR) value.

Specifically, the LR value represents the ratio of the probability of a bit transmitted from the transmitter 700 being 0 to the probability of being 1, and the LLR value may be represented as the logarithm of the ratio of the probability of a bit transmitted from the transmitter 700 being 0 to the probability of being 1. Alternatively, the LR or LLR value may be hard-decided based on the probability, probability ratio, or logarithm of the probability ratio, and represented as a bit value itself, or may be represented as a predefined representative value according to the interval within which the probability, probability ratio, or logarithm of the probability ratio falls. Examples of a method for determining a predefined representative value based on the interval within which the probability, probability ratio, or logarithm of the probability ratio falls include a method considering quantization. In addition, various other values corresponding to the probability, probability ratio, or logarithm of the probability ratio may be used.

In the disclosure, for convenience, operations based on LLR values are shown to explain the operation of the receiver and its method without being limited thereto.

The demodulator 810 includes a function for performing multiplexing on LLR values (not shown). Specifically, the multiplexer (not shown) is a component corresponding to the bit demultiplexer (not shown) of the transmitter 700 and may perform an operation corresponding to the bit demultiplexer (not shown).

To this end, the receiver 800 may store information regarding the parameters used by the transmitter 700 for demultiplexing and block interleaving. Hence, the multiplexer (not shown) may perform the inverse operation of the demultiplexing and block interleaving operation having been performed in the bit demultiplexer (not shown) on the LLR values corresponding to the cell word (information representing the received symbols for the LDPC codeword as a vector value), thereby multiplexing the LLR values corresponding to the cell word on a bit-by-bit basis.

The rate dematcher 820 may additionally insert LLR values into the LLR values output from the demodulator 810. In this case, the rate dematcher 820 may insert pre-agreed LLR values between the LLR values output from the demodulator 810.

Specifically, the rate dematcher 820 is a component corresponding to the rate matcher 740 of the transmitter 700, and may perform operations corresponding to the interleaver 741, and puncturing/repetition/zero remover 742.

First, the rate dematcher 820 performs deinterleaving in correspondence to the interleaver 741 of the transmitter. The LLR inserter 822 may insert an LLR value corresponding to zero bits at the positions, where zero bits have been padded in the LDPC codeword, in the output values of the deinterleaver 824. In this case, the LLR value corresponding to the padded zero bits, e.g., shortened zero bits, may be ∞ or −∞. However, ∞ or −∞ is a theoretical value, and in practice, it may be the maximum or minimum LLR value used by the receiver 800.

To this end, the receiver 800 may store information regarding the parameters used by the transmitter 700 to pad the zero bits. Hence, the rate dematcher 820 may identify the position where zero bits have been padded in the LDPC codeword and insert an LLR value corresponding to the shortened zero bits at the position.

Additionally, the LLR inserter 822 of the rate dematcher 820 may insert an LLR value corresponding to the punctured bits in the LDPC codeword at the position of the punctured bits. In this case, the LLR value corresponding to the punctured bits may be 0 or another preset value. Generally, puncturing parity bits with degree 1 has no effect on performance improvement in the LDPC decoding process, so some or all of the corresponding puncturing positions may be not used in LDPC decoding without LLR insertion. However, to increase the efficiency of the LDPC decoding process based on parallel processing, the LLR inserter 822 may insert a preset LLR value at a position corresponding to some or all of the punctured bits of degree 1 regardless of improvement in decoding performance.

To this end, the receiver 800 may store information about the parameters used for puncturing in the transmitter 700. Hence, the LLR inserter 822 may insert an LLR value (e.g., LLR=0) corresponding to the punctured LDPC information bits or parity bits at the position of the punctured bits. However, this process may be skipped at the position of some punctured parity bits.

The LLR combiner 823 can combine, e.g., add together, the LLR values output from the LLR inserter 822 and the demodulator 810. Specifically, the LLR combiner 823 is a component corresponding to the puncturing/repetition/zero remover 742 of the transmitter 700, and may perform an operation corresponding to the repetitioner 742. First, the LLR combiner 823 may combine the LLR value corresponding to the repeated bits with another LLR value. Here, the other LLR value may be an LLR value for those bits that have formed the basis for generating the repeated bits in the transmitter 700, e.g., the LDPC information bits or parity bits that have been selected for repetition.

That is, as described above, the transmitter 700 selects LDPC encoding bits, repeats them between LDPC information bits and LDPC parity bits, and transmits the result to the receiver 800. So, the LLR values for LDPC encoding bits may be composed of an LLR value for repeated LDPC encoding bits and an LLR value for non-repeated LDPC encoding bits. The LLR combiner 823 may combine LLR values for the same LDPC encoding bits.

To this end, the receiver 800 can store information about the parameters used for repetition in the transmitter 700. Hence, the LLR combiner 823 may identify the LLR value for the repeated LDPC encoding bits and combine it with the LLR value for the LDPC encoding bits that have formed the basis of the repetition.

Additionally, the LLR combiner 823 may combine the LLR value corresponding to the retransmission or IR (incremental redundancy) bits with another LLR value. Here, the other LLR value may be an LLR value for some or all of the LDPC codeword bits that have been the basis for generating the retransmission or IR bits in the transmitter 700.

As described above, when a NACK occurs for HARQ, the transmitter 700 may transmit some or all of the codeword bits to the receiver 800.

Hence, the LLR combiner 823 may combine the LLR value for the bits received through retransmission or IR with the LLR value for the LDPC codeword bits received through the previous frame.

To this end, the receiver 800 may store information about the parameters used by the transmitter 700 to generate the retransmission or IR bits. Hence, the LLR combiner 823 may identify the LLR value for the number of retransmission or IR bits and combine it with the LLR value for the LDPC encoding bits that have served as the basis for generating the retransmission bits.

The deinterleaver 824 may deinterleave the LLR values output from the LLR combiner 823.

Specifically, the deinterleaver 824 is a component corresponding to the interleaver 741 of the transmitter 700 and may perform an operation corresponding to the interleaver 741.

To this end, the receiver 800 may store information about the parameters utilized by the transmitter 700 for interleaving. Hence, the deinterleaver 824 may deinterleave the LLR values corresponding to the transmitted LDPC encoding bits by performing the inverse operation of the interleaving operation having been performed in the interleaver 741 on the LLR values corresponding to the transmitted LDPC encoding bits.

The LDPC decoder 830 may perform LDPC decoding based on the LLR values output from the rate dematcher 820.

Specifically, the LDPC decoder 830 is a component corresponding to the LDPC encoder 730 of the transmitter 700 and may perform an operation corresponding to the LDPC encoder 730.

To this end, the receiver 800 may store in advance information about the parameters used by the transmitter 700 to perform LDPC encoding according to the mode. Hence, the LDPC decoder 830 may perform LDPC decoding based on the LLR values output from the rate dematcher 820 according to the mode.

For example, the LDPC decoder 830 may perform LDPC decoding based on the LLR values output from the rate dematcher 820 according to an iterative decoding method based on a sum-product algorithm, and output error-corrected bits according to the LDPC decoding. The LDPC decoder 830 performs LDPC decoding on the LDPC codeword based on a parity check matrix or a corresponding exponent matrix or sequence. LDPC decoding may also be performed by using parity check matrices defined differently depending on the code rate (e.g., LDPC code rate). The LDPC decoder 830 may generate information bits by performing LDPC decoding by passing the LLR values corresponding to the LDPC codeword bits through an iterative decoding algorithm. Here, the LLR value is a channel value corresponding to the LDPC codeword bits, and may be represented in various ways.

The zero remover 840 may remove zero bits from the bits output from the LDPC decoder 830.

Specifically, the zero remover 840 is a component corresponding to the zero padder 720 of the transmitter 700 and may perform an operation corresponding to the zero padder 720.

To this end, the receiver 800 may store in advance information about the parameters utilized by the transmitter 700 to pad zero bits. Hence, the zero remover 840 may remove the zero bits padded in the zero padder 720 from the bits output from the LDPC decoder 830.

The desegmenter 850 is a component corresponding to the segmenter 710 of the transmitter 700 and may perform an operation corresponding to the segmenter 710.

To this end, the receiver 800 may store in advance information about the parameters used by the transmitter 700 for segmentation. Hence, the desegmenter 850 may restore the bits before segmentation by combining the bits output from the zero remover 840, e.g., segments for variable-length input bits.

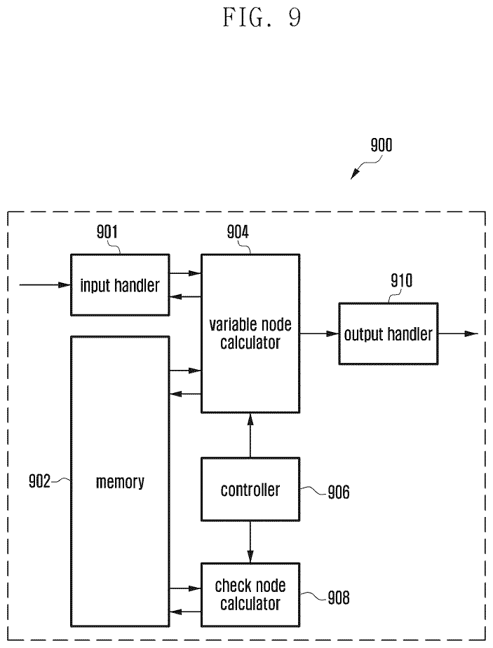

FIG. 9 is a diagram illustrating the structure of an LDPC decoder according to an embodiment of the disclosure.

Meanwhile, as described above, the LDPC decoder 830 may perform LDPC decoding by using an iterative decoding algorithm, and in this case, the LDPC decoder 830 may have a structure as shown in FIG. 9. 9. However, the detailed configuration illustrated in FIG. 9 is also an example.

According to FIG. 9, the decoder 900 includes an input handler 901, a memory 902, a variable node calculator 904, a controller 906, a check node calculator 908, and an output handler 910.

The input handler 901 stores the input values. Specifically, the input handler 901 may store the LLR values of a reception signal received through the channel.

The controller 904 determines the number of values input to the variable node calculator 904 and their address values in the memory 902, the number of values input to the check node calculator 908 and their address values in the memory 902 based on the block size (e.g., codeword length) of the reception signal received through the channel and the parity check matrix corresponding to the code rate.

The memory 902 stores input data and output data for the variable node calculator 904 and the check node calculator 908.

The variable node calculator 904 receives data from the memory 902 based on the address information and information about the number of input data received from the controller 906 and performs variable node operations. Thereafter, the variable node calculator 904 stores the variable node operation results in the memory 902 based on the address information and information about the number of output data received from the controller 906. In addition, the variable node calculator 904 outputs the variable node operation results to the output handler 910 based on the data received from the input handler 901 and the memory 902. Here, variable node operations have been described above with reference to FIG. 6.

The check node calculator 908 receives data from the memory 902 based on the address information and information about the number of input data received from the controller 906 and performs check node operations. Thereafter, the check node calculator 908 stores the check node operation results in the memory 902 based on the address information of output data and information about the number of output data received from the controller 906. Here, check node operations have been described above with reference to FIG. 6.

The output handler 910 performs a hard decision based on the data received from the variable node calculator 904 to determine whether the information bits of the transmitting side's codeword are 0 or 1, and outputs the hard decision result, and the output value of the output handler 910 becomes the final decoded value. In this case, a hard decision may be made based on the sum of all message values input to a single variable node (initial message value and all message values input from the check nodes) in FIG. 6.

Meanwhile, the memory 902 of the decoder 900 may store information about the code rate, codeword length, and parity check matrix of the LDPC code, and the LDPC decoder 810 may perform LDPC encoding by using this information. However, this is only an example, and the corresponding information may be provided from the transmitting side.

For reference, this disclosure focuses on LDPC codes as a forward error correction (FEC) technique for communication systems. However, FEC encoding and decoding in communication systems can generally be subdivided into concatenated codes, such as outer code and inner code. According to the definition of outer and inner codes, the transmitter performs inner encoding after outer encoding, and the receiver performs outer decoding after inner decoding.

In the case of external codes, algebraic codes that enable relatively simple error detection or correction, such as CRC (cyclic redundancy check) code, BCH (Bose-Chaudhuri-Hocquenghem) code, and RS (Reed-Solomon) code, are often used, but without being limited thereto, multiple codes may also be applied overlappingly.

In the case inner codes, encoding methods that are relatively complex but have high error-correcting capability such as LDPC, Turbo, and Polar codes are widely used, but without being limited thereto. (For example, tail-biting convolutional codes or other algebraic codes may be used, and multiple codes may also be applied overlappingly.) For reference, in the 3GPP 5G system, the outer code uses a CRC code, the inner code for the data channel uses an LDPC code, and the inner code for the control channel uses a Polar code.

Various broadcasting and communication systems utilize LDPC codes optimized for individual systems. This disclosure primarily describes a system utilizing LDPC codes defined based on parity check matrices with the same structure as the LDPC codes used in 3GPP 5G systems, but without being limited thereto. In addition, communication systems including 5G or 6G systems may apply rate matching at the transmitter and rate dematching at the receiver to support various code rates and various code lengths, but in systems that perform encoding/decoding based on fixed LDPC codes, such as some broadcasting systems, not only rate matching or rate dematching but also all or some of other operations may be omitted.

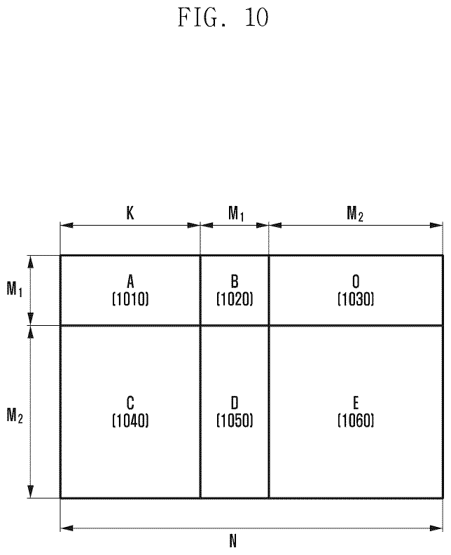

FIG. 10 illustrates the general structure of a parity check matrix of an LDPC code, which is an inner code applied to an FEC encoder (not shown) and an FEC decoder (not shown) to be described in the disclosure.

The parity check matrix illustrated in FIG. 10 has N columns and (M₁+M₂) rows (provided that M₁, M₂≥0, M₁+M₂>0). In general, when a parity check matrix has full rank, the number of columns corresponding to information bits in the parity check matrix is equal to the total number of columns minus the total number of rows. That is, if the parity check matrix in FIG. 10 has full rank of (M₁+M₂), the number of information bits K becomes N−(M₁+M₂). For convenience, this disclosure only describes the case where the parity check matrix in FIG. 10 has full rank, but the disclosure is not necessarily limited thereto.

First, the parity check matrix in FIG. 10 may be divided into a first part of the parity check matrix, composed of submatrices A 1010 and B 1020, and a second part of the parity check matrix, composed of submatrices C 1040, D 1050, and E 1060. (However, if either M₁ or M₂ is 0, the first and second parts may be not distinguished.) Submatrix O 1030 denotes a 0-matrix of size M₁×M₂. Since submatrix O 1030 is a 0-matrix of size M₁×M₂, even if it is included in the first part of the parity check matrix, it has no effect on the matrix operation. For this reason, in the disclosure, for convenience, the first part of the parity check matrix is defined as a matrix composed of submatrices A 1010 and B 1020 excluding the 0-matrix of size M₁×M₂, but if necessary, the first part of the parity check matrix may include the 0-matrix of size M₁×M₂.

If the parity check matrix in FIG. 10 is defined as a QC LDPC code with a lifting size or block size of Z, the parity check matrix in FIG. 10 may correspond to a base matrix or weight matrix having a size of m_{b}×n_{b} fork_{b}=K/Z, n_{b}=N/Z, m_{b} (M₁+M₂)/Z=m_{b1}+m_{b2} (m_{b1}=M₁/Z, m_{b2}=M₂/Z). Similarly, the first part of the parity check matrix composed of submatrices A 1010 and B 1020 corresponds to a submatrix of the base matrix or weight matrix of size

$$( \frac{{M}_{1}}{Z} ) \times ( \frac{K + {M}_{1}}{Z} ) or {m}_{b 1} \times ( {k}_{b} + {m}_{b 1} ) ,$$

and the second part of the parity check matrix composed of submatrices C 1040, D 1050 and E 1060 corresponds to a submatrix of the base matrix or weight matrix of size

$$( \frac{{M}_{2}}{Z} ) \times ( \frac{K + {M}_{1} + {M}_{2}}{Z} ) or$$

$${m}_{b 2} \times ( {k}_{b} + {m}_{b 1} + {m}_{b 2} ) = {m}_{b 2} \times {n}_{b} .$$

For convenience, let the parity check matrix of FIG. 10 be H, let the information bits (or information bit vector) corresponding to submatrix A 1010 or C 1040 be i=(i₀, i₁, i₂, . . . , i_{K-1}), let the first parity bits (or first parity bit vector) corresponding to submatrix B 1020 or D 1050 be w₁=(w_{1,0}, w_{1,1}, w_{1,2}, . . . , w_{1,M1-1}), let the second parity bits (or second parity bit vector) corresponding to submatrix E 1060 be w₂=(w_{2,0}, w_{2,1}, w_{2,2}, . . . , w_{2,M}_{₂}₋₁), then a mathematical relationship such as Equation 13 below may be obtained from Equation 1.

$$\begin{matrix}H \cdot {c}^{T} = H \cdot [ \begin{matrix}{\underline{i}}^{T} \\ {\underline{w}}_{1}^{T} \\ {\underline{w}}_{2}^{T}\end{matrix} ] \\ = [ \begin{matrix}A & B & O \\ C & D & E\end{matrix} ] \cdot [ \begin{matrix}{\underline{i}}^{T} \\ {\underline{w}}_{1}^{T} \\ {\underline{w}}_{2}^{T}\end{matrix} ] \\ = \{ \begin{matrix}A \cdot {\underline{i}}^{T} + B \cdot {\underline{w}}_{1}^{T} = 0 \\ C \cdot {i}^{T} + D \cdot {\underline{w}}_{i}^{T} + E \cdot {\underline{w}}_{2}^{T} = 0\end{matrix}\end{matrix} \qquad [ Equation 13 ]$$

With reference to Equation 13 above, the first parity vector w₁ may be obtained (or calculated or determined) based on the information bit vector i and the first part of the parity check matrix. Additionally, after obtaining the parity vector w₁, the parity vector w₂ may be obtained (or calculated or determined) based on the information bit vector i, the parity vector w₁, and the second part of the parity check matrix.

In the disclosure, for convenience, the first part of the parity check matrix, which is composed of A 1010 and B 1020, necessary for generating a first parity vector w₁ based on the information bit vector i, may be called a core part or core matrix, a kernel part or kernel matrix, or a precoding part or precoding matrix. In addition, the second part of the parity check matrix, which is composed of C 1040, D 1050 and E 1060, necessary for generating a second parity vector (w_2) based on the information word bit vector i and/or the first parity vector w₂ may be called an extension part or single parity-check extension part.

As a specific example, the core matrix parts of base matrix 1 M(H_{BG1}) and base matrix 2 M M(H_{BG2}) defined in the 3GPP 5G standard described above are as follows.

Core matrix of M(H_{BG1}):
0 12 3 5 6 9 10 11 12 13 15 16 18 19 20 21 22 23
023457891112141516171921222324
0124567891013 1415 171819202425
013467810111213 1416171820212225

Core matrix of M(H_{BG2}):
0 123 69 10 11
034567891112
0 13 4 8 10 12 13
124567891013

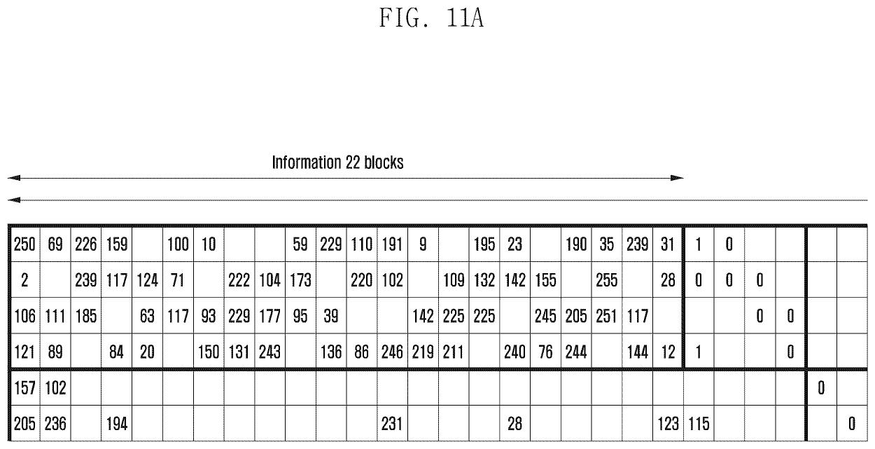

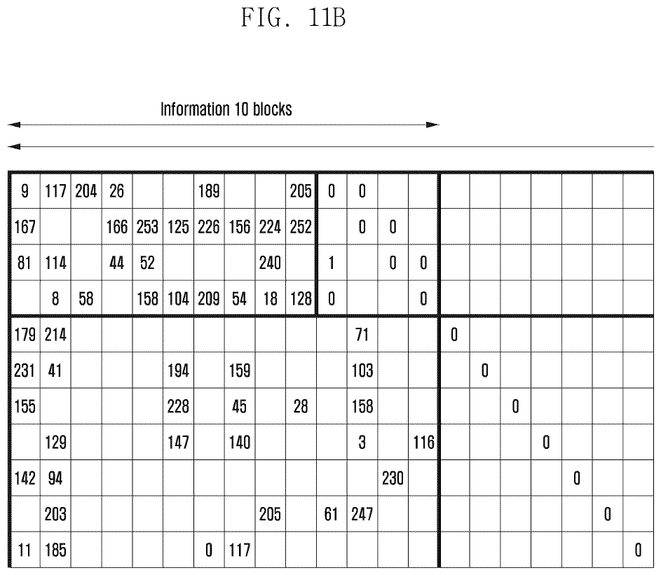

The core matrix of M(H_{BG1}) is of size 4×26, and the core matrix of M(H_{BG2}) is of size 4×14. Additionally, the core matrices for the parity check matrix are of size 4Z×26Z and of size 4Z×14Z, respectively. As a specific example, a portion of the exponent matrix of an LDPC code defined in 3GPP 5G specification TS 38.212 for lifting size set index i_{LS}=0 is shown in FIGS. 11A and 11B. The portion corresponding to the core matrix of the base matrix or parity check matrix in FIGS. 11A and 11B is as follows.

Core matrix of V(H₁), i_{LS}=0:
250 69 226 159 100 10 59 229 110 191 9 195 23 190 35 239 31 1 0
2 239 117 124 71 222 104 173 220 102 109 132 142 155 255 28 0 0 0
106 111 185 63 117 93 229 177 95 39 142 225 225 245 205 251 117 0 0
121 89 84 20 150 131 243 136 86 246 219 211 240 76 244 144 12 1 0

Core matrix of V(H₂), i_{LS}=0:
9 11720426 189 205 00
167 166 253 125 226 156 224 252 0 0
811144452240100
8 58 158 104 209 54 18 128 0 0

Meanwhile, in the disclosure, a parity check matrix based on the following conditions may be considered for the parity check matrix corresponding to FIG. 10.

In the following description, submatrix A 1010 and submatrix B 1020 may be referred to as a first submatrix and a second submatrix, respectively. Additionally, the circulant permutation matrix may refer to a circulant permutation matrix of size Z×Z determined based on the lifting size Z, and may be formed, for example, as in Equation 5 or Equation 6. Further, in the disclosure, a circulant matrix may refer to a matrix in which circulant permutation matrices overlap.

Condition 1(a): In the parity check matrix for the QC-LDPC code of FIG. 10, if submatrix B 1020 does not include a circulant matrix in which circulant permutation matrices of size Z×Z overlap, the weight of all column blocks of submatrix B 1020 is 2 or more, and at least one column block with an odd weight of 3 or more may be included in submatrix B 1020. In addition, the weight of all columns of the base matrix M(B) corresponding to submatrix B 1020 is 2 or more, and at least one column having an odd weight of 3 or more may be included in the basic matrix M(B).

Condition 1(b): In the parity check matrix for the QC-LDPC code of FIG. 10, if submatrix B 1020 includes at least one circulant matrix in which circulant permutation matrices of size Z×Z overlap, the weight of all column blocks of submatrix B 1020 is 2 or more, and at least one column block with an odd weight of 3 or more is included in submatrix B 1020. Additionally, in the weight matrix W(B) corresponding to submatrix B 1020, the sum of entries of all columns is 2 or more, and at least one column in which the sum of column entries is an odd number of 3 or more is included in the weight matrix W(B). (The weight of the column block containing a circulant matrix in which circulant permutation matrices of size Z×Z overlap may be 2 or 3 or more.)

Condition 2: All column weights and row weights of submatrix E 1060 of FIG. 10 are 1. Additionally, the column weights and row weights of the base matrix and the submatrix of the weight matrix corresponding to submatrix E 1060 are both 1. Hence, E 1060 and the submatrix of the base matrix and weight matrix corresponding to E 1060 are either identity matrices or matrices that can be transformed into identity matrices by applying appropriate column permutations or row permutations. (That is, E 1060 is either an identity matrix or a matrix with algebraic properties equivalent thereto.) If the parity check matrix of FIG. 10 is defined as a quasi-cyclic parity check matrix, the submatrix E may be divided into multiple identity matrices of size Z×Z.

FIGS. 11A and 11B illustrate an embodiment of a parity check matrix that satisfies at least one of condition 1(a), condition 1(b), or condition 2. As briefly explained above, FIG. 11A is an example of the case where K=22*Z, M₁=4*Z, M₂=2*Z in FIG. 10, and FIG. 11B is an example of the case where K=10*Z, M₁=4*Z, M₂=7*Z in FIG. 10. Note that the LDPC code corresponding to the parity check matrix of FIGS. 10, 11A, and 11B has a code rate of K/N, so as M₂ decreases, codewords with lower code rates may be generated. In other words, according to the disclosure, LDPC encoding and decoding may be performed based on a parity check matrix that can support a lower code rate by further expanding columns of degree 1 while including FIGS. 11A and 11B.

When using a lifting size set for LDPC encoding or decoding of a parity check matrix of a quasi-cyclic LDPC code, the number of columns constituting one column block of the parity check matrix is at least the minimum value of the lifting size. For example, when the values in Table 6 are used as a lifting size, the number of columns constituting one column block of the parity check matrix may be at least 4. Hence, in a communication system in which the lifting sizes of Table 6 are practically applied to the parity check matrix of an LDPC code having a structure as shown in FIG. 10, FIG. 11A, and FIG. 11B that satisfies at least one of condition 1(a), condition 1(b), or condition 2, it may indicate that the number of columns with degree 3 in submatrix B 1020 is at least 4 or more.

For reference, in a parity check matrix or base matrix or weight matrix, the core matrix may be defined in a form that satisfies at least one of condition 1(a), condition 1(b), or condition 2 by further adding one or two rows as follows. However, in the disclosure, for convenience, a parity check matrix [A (1010) B (1020)] including a submatrix B that satisfies only condition 1(a) or condition 1(b) is regarded as a core matrix (or kernel matrix or precoding matrix).

Core matrix of M(H_{BG1}):
0123569101112131516181920212223
023457891112141516171921222324
01245678910131415171819202425
0134678101112131416171820212225
0 1 26

Core matrix of M(H_{BG2}):
0 1 2 3 6 9 10 11
034567891112
0 13 4 8 10 12 13
124567891013
01 11 14

As an embodiment of the disclosure, a description will be given of a method for improving the performance of an LDPC code according to the weight matrix and a method for improving the decoding convergence speed.

First, the core matrix of base matrix 2 M(H_{BG2}) defined in “determining base matrix” is composed of four rows, which may also be expressed as a weight matrix as shown in Equation 14. Since the LDPC code defined by base matrix 1 M(H_{BG}1) or base matrix 2 M(H_{BG2}) is defined such that one circulant permutation matrix corresponds to one block of size Z×Z, the base matrix and the weight matrix are basically the same.

$$W ( {H}_{BG 2} ) = [ \begin{matrix}1 & 1 & 1 & 1 & 0 & 0 & 1 & 0 & 0 & 1 & 1 & 1 & 0 & 0 \\ 1 & 0 & 0 & 1 & 1 & 1 & 1 & 1 & 1 & 1 & 0 & 1 & 1 & 0 \\ 1 & 1 & 0 & 1 & 1 & 0 & 0 & 0 & 1 & 0 & 1 & 0 & 1 & 1 \\ 0 & 1 & 1 & 0 & 1 & 1 & 1 & 1 & 1 & 1 & 1 & 0 & 0 & 1\end{matrix} ] \qquad [ Equation 14 ]$$

The LDPC code, which is designed in this way so that at most one circulant permutation matrix corresponds to a single Z×Z block, has a structure suitable for performing layered decoding in a row-block wise manner. That is, the structure of the LDPC code is suitable for performing decoding through a Z-unit parallel processing processor.

As this layered decoding method typically performs parallel processing on a single row block as a basic unit, one iteration of decoding may be considered complete once decoding has been performed as many as the total number of row blocks. This may indicate that, if there are sufficient parallel processors, decoding throughput via layered decoding is inversely proportional to the number of row blocks. However, when supporting the same code length by using a parity check matrix with a smaller number of row blocks, as this may indicate that the lifting size Z value increases further, the number of parallel processing processors required to perform decoding simultaneously for one row block increases.

For example, the above weight matrix W(H_{BG2}) is composed of 4 rows and 14 columns, and the weights of columns are 3, 3, 2, 3, 3, 2, 3, 3, 2, 3, 3, 3, 2, 2, 2. Then, a weight matrix

$$W ( {H}_{BG 2}^{′} )$$

composed of 3 rows and 13 columns and having a weight distribution similar to W(H_{BG2}), and a weight matrix

$$W ( {H}_{BG 2}^{″} )$$

composed of 2 rows and 12 columns and having a weight distribution similar to W(H_{BG2}), may be composed as follows.

$$W ( {H}_{BG 2}^{′} ) = [ \begin{matrix}1 & 1 & 1 & 1 & 1 & 1 & 1 & 0 & 1 & 1 & 1 & 1 & 0 \\ 1 & 1 & 0 & 1 & 1 & 1 & 1 & 1 & 1 & 1 & 1 & 1 & 1 \\ 1 & 1 & 1 & 1 & 1 & 0 & 1 & 1 & 1 & 1 & 1 & 0 & 1\end{matrix} ] ,$$

$$W ( {H}_{BG 2}^{″} ) = [ \begin{matrix}2 & 1 & 1 & 2 & 1 & 1 & 2 & 1 & 1 & 2 & 1 & 1 \\ 1 & 2 & 1 & 1 & 2 & 1 & 1 & 1 & 2 & 1 & 2 & 1\end{matrix} ]$$

If LDPC codes with the same code length may be generated respectively using the weight matrices

$$W ( {H}_{BG 2} ) , W ( {H}_{BG 2}^{′} ) , W ( {H}_{BG 2}^{″} ) ,$$

and the lifting sizes corresponding respectively to the parity check matrices are Z₁, Z₂, Z₃, then

$${Z}_{3} = \frac{14}{12} {Z}_{1} and {Z}_{2} = \frac{13}{12} {Z}_{1} .$$

Additionally, if Z₁ parallel processing processors are available in the LDPC decoder, in terms of approximate decoding throughput,

$$W ( {H}_{BG 2}^{′} )$$

may be 1.5 times that of

$$W ( {H}_{BG 2} ) , and W ( {H}_{BG 2}^{″} )$$

may be twice that of W(H_{BG2}).

In this way, when sufficient parallel processing processors are available, reducing the number of row blocks may increase the decoding throughput in inverse proportion thereto. Hence, for a system requiring very high decoding throughput, it is advantageous to keep the number of rows of the base matrix or weight matrix, or in other words, the number of row blocks of the parity check matrix, small if more parallel processing processors can be applied.

While keeping the number of rows in the base or weight matrices—in other words, the number of row blocks in the parity check matrix—small may be beneficial in terms of decoding throughput, setting the number of row blocks too small may severely limit the LDPC code's algebraic properties, such as cycle characteristics or minimum distance characteristics, resulting in performance degradation. Therefore, the base matrix or weight matrix should be determined in simultaneous consideration of the target information processing capacity and target error correction capability of the system.

As an embodiment of the disclosure, a method for improving code performance while achieving high decoding throughput is proposed. In particular, the disclosure proposes algebraic properties that should be satisfied by the core matrix part of the base matrix or weight matrix, which is closely related to the maximum decoding throughput or peak data rate of the system. Definitely, if the parity check matrix does not include the second part of the parity check matrix composed of submatrices C 1040, D 1050 and E 1060 shown in FIG. 10, the core matrix may be identical to the base matrix or the weight matrix.

One of the conditions that the core matrix of the parity check matrix should satisfy is that when two columns with only one non-zero entry are selected from the weight matrix corresponding to the core matrix, it is not allowed for only one row to include non-zero entries such as

$$[ \begin{matrix}0 & 0 \\ ⋮ & ⋮ \\ {w}_{1} & {w}_{2} \\ ⋮ & ⋮ \\ 0 & 0\end{matrix} ] ( {w}_{1} , {w}_{2} \geq 1 ) .$$

Simple examples include

$$[ \begin{matrix}{w}_{1} & {w}_{2} \\ 0 & 0\end{matrix} ] , [ \begin{matrix}0 & 0 \\ {w}_{1} & {w}_{2}\end{matrix} ] , [ \begin{matrix}{w}_{1} & {w}_{2} \\ 0 & 0 \\ 0 & 0\end{matrix} ] , [ \begin{matrix}0 & 0 \\ {w}_{1} & {w}_{2} \\ 0 & 0\end{matrix} ] , … .$$

In a parity check matrix corresponding to a weight matrix containing this structure or its core matrix, the minimum distance is less than or equal to w₁+w₂, so the error floor phenomenon is highly likely to occur. Hence, in any two columns with only one non-zero entry, such as

$$[ \begin{matrix}{w}_{1} & 0 \\ 0 & {w}_{2}\end{matrix} ] , [ \begin{matrix}{w}_{1} & 0 \\ 0 & {w}_{2} \\ 0 & 0\end{matrix} ] , [ \begin{matrix}{w}_{1} & 0 \\ 0 & 0 \\ 0 & {w}_{2}\end{matrix} ] , … ,$$

the non-zero entries should be located in different rows.

This may indicate that, even for the base matrix, all non-zero entries in columns with weight 1 are located in different rows. The above explanation may be defined as conditions 3(a) and 3(b) below.

Condition 3(a): Every column of the basic matrix or weight matrix corresponding to the core matrix has a weight of 2 or more, or the number of columns with weight 1 is at most 1.

Condition 3(b): If there are two or more columns with weight 1 among the columns of the base matrix or weight matrix corresponding to the core matrix, the non-zero entries included in the columns with weight 1 are located in different rows.

Conditions 3(a) and 3(b) above mean that, if the number of column blocks containing only one circulant permutation matrix or circulant matrix in the core matrix is at most 1, or if two or more column blocks containing only one circulant permutation matrix or circulant matrix are included in the core matrix, the circulant permutation matrices of size Z×Z or circulant matrices should be included in different row blocks. In addition, conditions 3(a) and 3(b) above are a structure for preventing a serious error floor phenomenon, but if more excellent error floor characteristics are to be obtained, condition 4 below may be additionally added. As described above, the circulant permutation matrix and the circulant matrix may have a size of Z×Z.

Condition 4: The weight of the column corresponding to the information bit (or input bit or code block) in the parity check matrix corresponding to the core matrix is 3 or more.

Condition 4 above may be applied when trying to improve the error floor phenomenon although the encoding gain may be reduced by ensuring that no weight of the column corresponding to the information bit is 2, like the parity check matrix corresponding to base matrix 2 M(H_{BG2}) in Equation 14.

Condition 4 above may indicate that if, in the parity check matrix for a QC-LDPC code, submatrix A 1010 does not include a circulant matrix in which circulant permutation matrices of size Z×Z overlap, the weight of all column blocks of submatrix A 1010 is 3 or more, and the weight of all columns of the base matrix M(A) corresponding to submatrix A 1010 is 3 or more. Additionally, condition 4 above may indicate that if, in the parity check matrix for a QC-LDPC code, submatrix A 1010 includes at least one circulant matrix in which circulant permutation matrices of size Z×Z overlap, the weight of all column blocks of submatrix A 1010 is 3 or more, and the sum of entries of all columns of the weight matrix W(A) corresponding to submatrix A 1010 is 3 or more.

As another condition to be satisfied by the core matrix of a parity check matrix, it may be considered that the weight matrix corresponding to the core matrix does not include an entry with a value of 3 or more. Generally, when the core matrix of the weight matrix includes an entry with an integer value of 3 or more, this may indicate that there are three or more circulant permutation matrices corresponding to the corresponding position. If three or more circulant permutation matrices constituting a circulant matrix of size Z×Z overlap, the maximum cycle length is limited to 6 regardless of the Z value. Since the performance improvement effect of iterative decoding is reduced when the cycle length is short, a parity check matrix corresponding to a weight matrix or core matrix containing an entry with a value of 3 or more is appropriate for use when the code length is short or the code rate is relatively high. As this disclosure addresses the design of LDPC codes that support various code rates and code lengths, the core matrix of the weight matrix is restricted from including an entry with a value greater than or equal to 3. (Definitely, such an entry may be included in a portion corresponding to the single parity check extension part.) The above explanation may be defined as condition 5 below.

Condition 5: The weight matrix corresponding to the core matrix is composed of 0 and 1 only, or 0, 1 and 2 only.

As another condition that the core matrix should satisfy, submatrix B 1020 in FIG. 10 corresponding to the first parity vector wᵢ should have full rank to enable efficient encoding, and the following restrictive structure is desirable to prevent serious degradation of cycle characteristics.

Condition 6(a): If the weight matrix corresponding to the core matrix has four rows, then the submatrix corresponding to B 1020 in the weight matrix and base matrix is one of the following:

$$[ \begin{matrix}1 & 1 & 0 & 0 \\ 1 & 1 & 1 & 0 \\ 0 & 0 & 1 & 1 \\ 1 & 0 & 0 & 1\end{matrix} ] , [ \begin{matrix}1 & 1 & 0 & 0 \\ 0 & 1 & 1 & 0 \\ 1 & 0 & 1 & 1 \\ 1 & 0 & 0 & 1\end{matrix} ] , [ \begin{matrix}1 & 1 & 0 & 0 \\ 1 & 1 & 1 & 0 \\ 0 & 0 & 1 & 1 \\ 1 & 0 & 1 & 1\end{matrix} ] , [ \begin{matrix}1 & 1 & 0 & 0 \\ 0 & 1 & 1 & 0 \\ 1 & 1 & 1 & 1 \\ 1 & 0 & 1 & 1\end{matrix} ] ,$$

$$[ \begin{matrix}1 & 1 & 0 & 0 \\ 0 & 1 & 1 & 0 \\ 1 & 1 & 1 & 1 \\ 1 & 0 & 1 & 1\end{matrix} ] , [ \begin{matrix}1 & 1 & 0 & 0 \\ 0 & 1 & 1 & 0 \\ 1 & 0 & 1 & 1 \\ 1 & 1 & 1 & 1\end{matrix} ]$$

Condition 6(b): If the weight matrix corresponding to the core matrix has three rows, then the submatrix of the base matrix corresponding to submatrix B 1020 is

$$[ \begin{matrix}1 & 1 & 0 \\ 1 & 1 & 1 \\ 1 & 0 & 1\end{matrix} ] ,$$

and the weight matrix is one of the following:

$$[ \begin{matrix}1 & 1 & 0 \\ 1 & 1 & 1 \\ 1 & 0 & 1\end{matrix} ] , [ \begin{matrix}1 & 1 & 0 \\ 0 & 1 & 1 \\ 2 & 0 & 1\end{matrix} ] , [ \begin{matrix}2 & 1 & 0 \\ 0 & 1 & 1 \\ 1 & 0 & 1\end{matrix} ] , [ \begin{matrix}1 & 2 & 0 \\ 0 & 1 & 1 \\ 2 & 0 & 1\end{matrix} ] , [ \begin{matrix}1 & 2 & 0 \\ 0 & 1 & 2 \\ 2 & 0 & 1\end{matrix} ] .$$

Condition 6(c): If the weight matrix corresponding to the core matrix has two rows, the submatrix of the base matrix corresponding to submatrix B 1020 is

$$[ \begin{matrix}1 & 1 \\ 1 & 1\end{matrix} ] ,$$

and the weight matrix is one of the following:

$$[ \begin{matrix}1 & 1 \\ 2 & 1\end{matrix} ] , [ \begin{matrix}1 & 2 \\ 2 & 1\end{matrix} ] .$$

For reference, condition 6(a) above shows a case where the weight matrix and the base matrix are identical, and condition 6(b) shows a case where the weight matrix has the same form as the base matrix only if it is

$$[ \begin{matrix}1 & 1 & 0 \\ 1 & 1 & 1 \\ 1 & 0 & 1\end{matrix} ] .$$

In the base matrix or weight matrix shown in conditions 6(a), 6(b) and 6(c), 0 denotes a 0-matrix of size Z×Z, 1 denotes an identity matrix I=(P⁰) of size Z×Z or a circulant permutation matrix P^{v}(v>0). Additionally, 2 denotes a circulant matrix (P^{v1}+P^{v2}) of size Z×Z (v₁, v₂≥0, v₁≈v₂).

In general, it is possible to predict the upper bound on the cycle length from the base matrix or weight matrix, but it is not possible to identify the cycle characteristics of the parity check matrix corresponding to the base matrix or weight matrix. For example, if submatrix B 1020 is

$$[ \begin{matrix}I & I \\ {P}^{{v}_{1}} + {P}^{{v}_{2}} & I\end{matrix} ] or [ \begin{matrix}I & I & 0 \\ {P}^{{v}_{1}} & I & I \\ {P}^{{v}_{2}} & 0 & I\end{matrix} ] ,$$

in each case, regardless of the values of v1 and v2, the base matrix or weight matrix is the same as

$$[ \begin{matrix}1 & 1 \\ 2 & 1\end{matrix} ] or [ \begin{matrix}1 & 1 & 0 \\ 1 & 1 & 1 \\ 1 & 0 & 1\end{matrix} ] ,$$

but the cycle characteristics are very different. In the case of

$$[ \begin{matrix}I & I \\ {P}^{{v}_{1}} + {P}^{{v}_{2}} & I\end{matrix} ] ,$$

if at least one of v1 or v2 is 0 or

$${v}_{1} ≡ {v}_{2} ( mod \frac{Z}{2} ) ( or , {v}_{1} - {v}_{2} ≡ \frac{Z}{2} ( mod Z ) ) ,$$

a large number of 4-cycles are generated, so basically v1 and v2 are set to integers that satisfy v₁,

$${v}_{2} ( mod Z ) > 0 , {v}_{1} ≢ {v}_{2} ( mod \frac{Z}{2} ) ( or , {v}_{1} - {v}_{2} ≢ \frac{Z}{2} ( mod Z ) ) .$$

Similarity, in the case of

$$[ \begin{matrix}I & I & 0 \\ {P}^{{v}_{1}} & I & I \\ {P}^{{v}_{2}} & 0 & I\end{matrix} ] ,$$

a large number of 4-cycles are generated when v1=0, so basically v1 is set to an integer satisfying v₁(mod Z)>1, and v2 is set to an integer satisfying v₂(mod Z)>0. The above is a way to eliminate 4-cycles, and the values of v1 and v2 may be restricted in various ways to obtain longer cycles.

If the communication system applies puncturing of information bits as described in Table 9, the following condition that the core matrix should satisfy may be added.

Condition 7: In an LDPC encoding system where puncturing of information bits is applied, a submatrix of the core matrix composed only of columns corresponding to the punctured information bits includes at least one row with a row weight of 1.

Since punctured bits at the receiver are considered lost during the reception process, the probability of a punctured bit being 0 or 1 is determined to be equal. This typically may mean 1 when performing decoding using LR values, and may mean 0 when performing decoding using LLR values. However, it can be determined in other forms based on the values used in the decoding process. When performing LDPC decoding based on a parity check matrix that does not satisfy condition 7, the punctured information bits may be not decoded unless an ML (maximum likelihood) decoding scheme or pseudo-ML decoding scheme is used. Since ML or pseudo-ML decoding schemes are not commonly used due to their complexity, the parity check matrix may be determined so as to satisfy condition 7 to ensure successful decoding.

If the LDPC code is a QC-LDPC code, the parity check matrix may be represented based on the lifting size Z value and the base matrix and/or weight matrix and/or exponent matrix, so this may be expressed as condition 8 below.

Condition 8: In a QC-LDPC encoding system where information bits are punctured in units of lifting size Z or its multiples, there is at least one row with weight 1 in a submatrix of the base matrix composed of only a columns in correspondence to a submatrix of the core matrix composed of only a*Z columns corresponding to the punctured a*Z (a: integer greater than or equal to 1) information bits. In addition, a submatrix of the weight matrix composed of only a columns in correspondence to a submatrix of the core matrix composed of only a*Z columns has at least one row with a weight of 1 and an entry of 1.

For example, in a QC-LDPC encoding system where puncturing of information bits of 2Z bits is always applied, condition 8 implies that a=2.

Meanwhile, in the disclosure, at least one of the above conditions may be used to construct a parity check matrix. That is, the parity check matrix may be determined to satisfy one of the above conditions or a combination of at least two of the above conditions.

As an embodiment of the disclosure, a method for improving the error floor performance of an LDPC code is proposed. In general, the error floor phenomenon in an LDPC code is significantly affected by the cycle characteristics of the corresponding Tanner graph. However, since the cycle characteristics on the Tanner graph of a QC LDPC code are determined by the relationship between the base matrix and the exponent or circular shift value of the circulant permutation matrix, the circular shift value as well as the position of the circulant permutation matrix constituting the parity check matrix should be appropriately selected.

The disclosure proposes an algebraic property that submatrix B 1020 corresponding to first parity bits (or, first parity bit vector) w₁=(w_{1,0}, w_{1,1}, w_{1,2}, . . . , w_{1M}_{₁}₋₁) in the first part of a parity check matrix composed of submatrices A 1010 and B 1020 in FIG. 10 should satisfy.

The size of submatrix B 1020 is M₁×M₁ (or, m_{b1}Z×m_{b1}Z), and submatrix B 1020 corresponds to the base matrix or weight matrix of size

$$( \frac{{M}_{1}}{Z} ) \times ( \frac{{M}_{1}}{Z} ) ( or , {m}_{b 1} \times {m}_{b 1} ) .$$

Additionally, the first column block of submatrix B 1020 is composed of three circulant permutation matrices. Here, the circulant permutation matrices may include an identity matrix. That is, in the disclosure, a circulant permutation matrix is defined as a matrix obtained by circularly shifting each entry of the identity matrix by i. If the value of i is 0, the circulant permutation matrix may become an identity matrix. This may be applied throughout the detailed description of the disclosure. Additionally, the remaining column blocks of submatrix B 1020 are composed of two circulant permutation matrices or identity matrices. In the disclosure, for convenience, the remaining column blocks are expressed only when the identity matrices are configured in a dual diagonal structure, but in general, there is no need to be so limited.

Specific examples of submatrix B 1020 are illustrated in Equation 15. Submatrix B 1020 may be determined based on at least one of the matrices included in Equation 15 below. However, embodiments of the disclosure are not limited thereto, and various matrices satisfying the above characteristics (the first column block is composed of three circulant permutation matrices, and the remaining column blocks are composed of two circulant permutation matrices or identity matrices) may be considered.

$${B}_{1} = [ \begin{matrix}{P}^{a} & I & O \\ {P}^{b} & I & I \\ {P}^{c} & O & I\end{matrix} ] , {B}_{2 , 1} = [ \begin{matrix}{P}^{a} & I & O & O \\ {P}^{b} & I & I & O \\ O & O & I & I \\ {P}^{c} & O & O & I\end{matrix} ] , \qquad [ Equation 15 ]$$

$${B}_{2 , 2} = [ \begin{matrix}{P}^{a} & I & O & O \\ O & I & I & O \\ {P}^{b} & O & I & I \\ {P}^{c} & O & O & I\end{matrix} ] , {B}_{3} = [ \begin{matrix}{P}^{a} & I & O & O & O \\ O & I & I & O & O \\ {P}^{b} & O & I & I & O \\ O & O & O & I & I \\ {P}^{c} & O & O & O & I\end{matrix} ]$$

$$M ( {B}_{1} ) = [ \begin{matrix}1 & 1 & 0 \\ 1 & 1 & 1 \\ 1 & 0 & 1\end{matrix} ] , M ( {B}_{2 , 1} ) = [ \begin{matrix}1 & 1 & 0 & 0 \\ 1 & 1 & 1 & 0 \\ 0 & 0 & 1 & 1 \\ 1 & 0 & 0 & 1\end{matrix} ] ,$$

$$M ( {B}_{2 , 2} ) = [ \begin{matrix}1 & 1 & 0 & 0 \\ 0 & 1 & 1 & 0 \\ 1 & 0 & 1 & 1 \\ 1 & 0 & 0 & 1\end{matrix} ] , M ( {B}_{3} ) = [ \begin{matrix}1 & 1 & 0 & 0 & 0 \\ 0 & 1 & 1 & 0 & 0 \\ 1 & 0 & 1 & 1 & 0 \\ 0 & 0 & 0 & 1 & 1 \\ 1 & 0 & 0 & 0 & 1\end{matrix} ] ,$$

$$V ( {B}_{2 , 1} ) = [ \begin{matrix}a & 0 & - 1 & - 1 \\ b & 0 & 0 & - 1 \\ - 1 & - 1 & 0 & 0 \\ c & - 1 & - 1 & 0\end{matrix} ] , V ( {B}_{3} ) = [ \begin{matrix}a & 0 & - 1 & - 1 & - 1 \\ - 1 & 0 & 0 & - 1 & - 1 \\ b & - 1 & 0 & 0 & - 1 \\ - 1 & - 1 & - 1 & 0 & 0 \\ c & - 1 & - 1 & - 1 & 0\end{matrix} ]$$

In Equation 15, B₁, B₂,1, B_{2,2} and B₃ have the first column block composed of three different circulant permutation matrices P^{a}, P^{b} P^{c} Additionally, Equation 15 only shows the cases where the m_{b1} value is 3, 4, and 5 for convenience, submatrix B 1020 may be similarly defined for larger integers. In addition, matrices that can be transformed into the form of submatrix B 1020 above through an appropriate invertible transform process may be considered as algebraically equivalent matrices.

This disclosure proposes a method for improving cycle characteristics not only for B₁, B_{2,1}, B_{2,2}, B₃ of Equation 15, but also for larger submatrix B 1020 in a similar form. For convenience, the method for analyzing the cycle characteristics of QC LDPC codes and details on some algebraic properties are omitted herein, but reference may be made to reference document Myung2005.

[Myung2005]

S. Myung, K. Yang, and J. Kim, “Quasi-Cyclic LDPC Codes for Fast Encoding,” IEEE Transactions on Information Theory, vol. 51, No. 8, pp. 2894-2901, Aug. 2005.

As in Equation 15, when the remaining column blocks excluding the first column block in submatrix B 1020 have a dual diagonal structure composed of identity matrices, in the related art, at least two of the exponents (or circular shift values) a, b, c of the circulant permutation matrices of the first column block are set to the same value for encoding convenience. In this case, matrix φ of size Z×Z used in the encoding process becomes an identity matrix I or a simple circulant permutation matrices P^{x}. The inverse matrix φ⁻¹ of φ is simplified to an identity matrix I or P^{-x}, which simplifies the encoding process. (Refer to Myung2005 for detailed description of encoding process of QC LDPC codes) As a specific example, when a=c, φ becomes P^{b}, and φ⁻¹ becomes P^{-b}, enabling efficient encoding. Similarly, when a=b, φ becomes P^{c}, and φ⁻¹ becomes P^{-c}, enabling efficient encoding.

However, when a=c≠b, there are always Z cycles of length 2m_{b1} in the Tanner graph due to the structure shown in Equation 16 below. In other words, if the value of m_{b1} is fixed, there is always a cycle of length 2m_{b1} regardless of the values of lifting size Z and exponent a(=c). (Refer to Myung2005 for detailed information on cycle characteristics of QC LDPC codes)

$$[ \begin{matrix}{P}^{a} & I & * & * & * \\ * & I & I & * & * \\ * & * & ⋱ & ⋱ & * \\ * & * & * & I & I \\ {P}^{a} & * & * & * & I\end{matrix} ] \qquad [ Equation 16 ]$$

Further, in the case of a=b, there is always a cycle shorter than 2m_{b1} regardless of lifting size Z and the value of exponent a(=b) due to the structure shown in Equation 17 below.

$$[ \begin{matrix}{P}^{a} & I & * \\ {P}^{b} & I & * \\ * & * & *\end{matrix} ] , [ \begin{matrix}{P}^{a} & I & * & * \\ * & I & I & * \\ {P}^{b} & * & I & * \\ * & * & * & *\end{matrix} ] \qquad [ Equation 17 ]$$

If the value of m_{b1} is appropriately large, the cycle characteristics of the Tanner graph corresponding to structures shown in Equations 16 and 17 may not significantly affect the performance of the LDPC code. However, when the m_{b1} value is relatively small, the BLER may increase due to the error floor phenomenon, which becomes a problem that cannot be ignored as the target BLER of the system is low.

To address this issue, the disclosure proposes a method for improving cycle characteristics by restricting exponents (or circular shift values) a, b, c of the circulant permutation matrices constituting the first column block of submatrix B 1020, which has a structure as shown in Equation 15, to satisfy specific algebraic conditions. In addition, a description is given of the above method which is characterized by a reasonable increase in computational complexity related to the φ−1 matrix required in the LDPC encoding process while improving cycle characteristics.

If the lifting size Z for the parity check matrix of a QC LDPC code is Z=p·2^{L} (p is an odd integer, L is an integer greater than or equal to 0), then exponents (or circular shift values) a, b, c of the circulant permutation matrices constituting the first column block of submatrix B 1020 are different integers and satisfy at least some or all of the following conditions:

Exponent condition 1a: At least one of the differences between two exponents (circular shift values) has a greatest common divisor of 1 with the lifting size Z, or is the smallest divisor of Z greater than 1. (That is, it is coprime to Z, or has the smallest divisor of Z greater than 1 as its greatest common divisor)

Exponent condition 1b: Two of the differences between two exponents have a common divisor of 1 with the lifting size Z, or are the smallest divisors of Z greater than 1.

Exponent condition 2a: At least one of the differences between two exponents is

$$\frac{Z}{{2}^{i}}$$

$$( 0 \leq i \leq L ) .$$

Exponent condition 2b: At least one of the differences between two exponents is

$$\frac{Z}{{2}^{i}} ( 1 \leq i < L )$$

when p is 1 and L>1, and is

$$\frac{Z}{{2}^{i}} ( 1 \leq i \leq L )$$

when p is an odd number greater than or equal to 3 and L>0.

For reference, the difference between exponents used in the above exponent conditions may indicate|a−b|, |b−c|, or |c−a|.

According to exponent condition 1a, if the difference between two exponents is relatively prime to Z, the cycle length determined by the circulant permutation matrices associated with the two exponents is maximized. For example, if the value of |a−b| is relatively prime to Z, the length of the cycle on the Tanner graph determined by

$$[ \begin{matrix}{P}^{a} & I & * \\ {P}^{b} & I & * \\ * & * & *\end{matrix} ]$$

in Equation 17 becomes 4Z. If the greatest common divisor of |a−b| and Z is D, the cycle length becomes 4Z/D. Consequently, as the value of Z increases, the cycle length also increases.

As another example, if the value of |a−c| is relatively prime to Z, the cycle length determined by the structure of Equation 16 becomes 2m_{b1}Z. If the greatest common divisor of |a−c| and Z is D, the cycle length becomes 2m_{b1}Z/D. As a result, it can be seen that the cycle length is not fixed regardless of the Z value, but rather increases as the Z value increases. Considering only the cycle characteristics, it is desirable for the difference between exponents to be relatively prime to Z. However, depending on the situation, the exponents may be selected so that the greatest common divisor D is small (e.g., the smallest divisor of Z greater than 1) according to other conditions. For example, if the difference between exponents cannot satisfy the property of being relatively prime to Z, it is desirable to select exponents that make the greatest common divisor D small.

Exponent condition 1b above further restricts the exponent condition compared to exponent condition 1a, thereby further improving the cycle characteristics. For example, when the values of |a−b| and |b−c| are relatively prime to Z, not only is the cycle property related to exponents a, b such as

$$[ \begin{matrix}{P}^{a} & I & * \\ {P}^{b} & I & * \\ * & * & *\end{matrix} ]$$

improved, but the cycle property related to exponents b, c such as

$$[ \begin{matrix}* & * & * \\ {P}^{b} & * & I \\ {P}^{c} & * & I\end{matrix} ]$$

is also improved. (The same holds true for Equation 15 and other forms of submatrix B extended based on Equation 15.)

In Equation 15 and other extended forms of submatrix B based on Equation 15, when a, b, c are all different, the φ matrix required for the encoding process is defined as φ=P^{a}+P^{b}+P^{c}. For this φ matrix, not only is it difficult to obtain φ⁻¹, but the density of weights in the φ⁻¹ matrix also often exhibits a high density characteristic rather than a low density characteristic. That is, the low-density φ matrix does not guarantee the low-density characteristic of the φ⁻¹ matrix. Since the high density characteristic of the φ⁻¹ matrix increases the encoding complexity, it is desirable that the density of the φ⁻¹ matrix be as low as possible, and it is desirable that the φ⁻¹ matrix have a simple structure.

Exponent conditions 2a and 2b are conditions for simplifying the φ⁻¹ matrix as much as possible for efficient LDPC encoding. For example, in exponent condition 2a above, if

$$\vert a - c \vert = \frac{Z}{{2}^{i}} ,$$

$${ϕ}^{{2}^{i}} = {P}^{{2}^{i} a} + {P}^{{2}^{i} b} + {P}^{{2}^{i} c} = {P}^{{2}^{i} a} ( I + {P}^{{2}^{i} ( c - a )} ) + {P}^{{2}^{i} b} = {P}^{{2}^{i} \cdot b}$$

$$and {ϕ}^{- 1} = {P}^{- {2}^{i} b} \cdot {ϕ}^{{2}^{i} - 1} . Here , as {ϕ}^{{2}^{i} - 1} becomes$$

$${ϕ}^{{2}^{i} - 1} = {ϕ}^{{2}^{i - 1}} \cdot {ϕ}^{{2}^{i - 2}} \cdot … \cdot {ϕ}^{2} \cdot ϕ = ( {P}^{{2}^{( i - 1 )} a} + {P}^{{2}^{( i - 1 )} b} + {P}^{{2}^{( i - 1 )} c} ) ( {P}^{{2}^{( i - 2 )} a} + {P}^{{2}^{( i - 2 )} b} + {P}^{{2}^{( i - 2 )} c} ) \cdot … \cdot ( {P}^{2 a} + {P}^{2 b} + {P}^{2 c} ) \cdot ( {P}^{a} + {P}^{b} + {P}^{c} )$$

it may be seen that φ⁻¹ can be determined relatively simply, but the computational complexity due to φ⁻¹ increases as the value of i increases. Hence, the value of i may be appropriately restricted for utilization based on the system's acceptable complexity. Usually, the value of i is preferably within the range 0≤i≤4, but larger values may be utilized depending on the system's acceptable range.

For reference, operation P^{x}·v^{T}, which multiplies a specific bit sequence v^{T} of length Z by a circulant permutation matrix P^{X} of size Z×Z, is not a true matrix multiplication, but rather a circular shift of the bit sequence V^{T} by x bits. That is, the above operation represents a calculation or operation with very low complexity because it can be implemented with a bit-shift operation rather than a matrix multiplication. Further, when calculating φ²ⁱ⁻¹·v^{t}, computational complexity may be minimized by performing stepwise calculations such as φ²ⁱ⁻¹·v^{t}=φ²ⁱ⁻¹( . . . (φ²(φ·v^{T}))), rather than expanding each term of φ²ⁱ⁻¹. As a simple example, the calculation may be performed as follows:

$$( {P}^{2 a} + {P}^{2 b} + {P}^{2 c} ) \cdot ( {P}^{a} + {P}^{b} + {P}^{c} ) \cdot {\underline{v}}^{T} = {P}^{3 a} ( I + {P}^{2 ( b - a )} + {P}^{2 ( c - a )} ) \cdot ( I + {P}^{b - a} + {P}^{c - a} ) \cdot {\underline{v}}^{T} = {P}^{3 a} ( I + {P}^{2 ( b - a )} + {P}^{2 ( c - a )} ) \cdot ( {\underline{v}}^{T} + {P}^{b - a} \cdot {\underline{v}}^{T} + {P}^{c - a} \cdot {\underline{v}}^{T} ) = {P}^{3 a} ( I + {P}^{2 ( b - a )} + {P}^{2 ( c - a )} ) \cdot {\underline{v}}_{1}^{T} = {P}^{3 a} ( {\underline{v}}_{1}^{T} + {P}^{2 ( b - a )} \cdot {\underline{v}}_{1}^{T} + {P}^{2 ( c - a )} \cdot {\underline{v}}_{1}^{T} ) = {P}^{3 a} \cdot {\underline{v}}_{2}^{T} .$$

Also for the case of

$$\vert a - b \vert = \frac{Z}{{2}^{i}} or \vert b - c \vert = \frac{Z}{{2}^{i}}$$

in exponent condition 2a, encoding can be performed by determining φ⁻¹ in the same manner. However, if all the differences between two exponents are of the form

$$\frac{Z}{{2}^{i}} ,$$

the cycle characteristics are likely to deteriorate. Hence, for efficient encoding and good cycle characteristics, a method can be considered in which at least one of the differences between two exponents satisfies the property

$$\frac{Z}{{2}^{i}} ( 0 \leq i \leq L ) ,$$

and the remaining exponent differences satisfy either exponent condition 1a or exponent condition 1b. Additionally, exponents the difference between the two exponents is Z/2\hat{ }i, and exponents satisfying at least one of exponent condition 1a or exponent condition 1b can be selected. Additionally, specific exponents may be selected if the difference between two exponents is

$$\frac{Z}{{2}^{i}}$$

and at least one of exponent conditions 1a or 1b is satisfied.

Exponent condition 2b further restricts the exponent condition compared to exponent condition 2a, enabling efficient encoding while further improving cycle characteristics. When exponent condition 2b is satisfied, encoding complexity increases slightly compared to existing 5G LDPC codes, but cycle characteristics are improved. Definitely, if there are no cases where exponent condition 2b is satisfied, the exponents may be determined in consideration of exponent condition 2a. For reference, it may be seen that, except for the case where

$$\frac{Z}{{2}^{i}} = 1$$

in exponent condition 2a, the difference between two exponents is always non-coprime to Z. That is, the difference between Z and the two exponents has a common divisor greater than 1. The existence of i satisfying

$$\frac{Z}{{2}^{i}} = 1$$

means that Z=2^{L}, so that exponent condition 2b is to be satisfied, and the difference between Z and the two exponents is not relatively prime according to condition 1≤i<L and has 2^{L-i} as a common divisor.

As an embodiment of the disclosure, a description will be given of more specific examples of constructing submatrix B 1020 in FIG. 10 using the above exponent conditions.

First, a communication or broadcasting system such as 5G is considered where lifting size sets are defined as shown in Tables 3 to 8, and only lifting sizes included in a lifting size set can be applied. Additionally, a parity check matrix or exponent matrix can be separately defined for each lifting size set. That is, in the cases of Tables 3 to 8, a parity check matrix or exponent matrix can be defined for each of the eight set indices.

In Equation 15 and an extended form of submatrix B based on Equation 15, let a, b, c be determined as follows. In general, since exponents a, b and c for submatrix B of the parity check matrix corresponding to i_{LS}=k (k=0, 1, 2, . . . ) may all be different, they are represented as aₖ, bₖ, cₖ for convenience.

### Example 1 of Exponent Selection (i_{LS}=k)

aₖ is any integer
bₖ is given by bₖ−aₖ+sₖ, where sₖ is an integer satisfying gcd(sₖ, Zₖ)=1. That is, among the exponents corresponding to submatrix B, aₖ and bₖ are integers satisfying gcd(|aₖ−bₖ|, Zₖ)=1. Here, gcd(x, y) may indicate the greatest common divisor of x and y, and Zₖ may indicate a specific lifting size belonging to the lifting size set corresponding to i_{LS}=k.
cₖ is given by cₖ=aₖ+tₖ, where tₖ is one of the lifting sizes less than the largest lifting size Z_{k,max} among the lifting size values belonging to the lifting size set corresponding to i_{LS}=k.

If calculating the difference between exponents for submatrix B determined according to example 1 of exponent selection, for lifting size Zₖ, as |aₖ−bₖ|=|sₖ|, so exponent condition 1a is satisfied; and in |bₖ−cₖ|=|sₖ−tₖ|, tₖ is one of the Zₖ values, Zₖ values are multiples one another (multiples of 2ⁱ), and according to the definition of sₖ, 1=gcd(sₖ,Zₖ)=gcd(sₖ−Zₖ, Zₖ)=gcd(sₖ−tₖ, Zₖ) is established, so that exponent condition 1b is also satisfied. However, as

$$\vert {c}_{k} - {a}_{k} \vert = {t}_{k} = \frac{{Z}_{max}}{{2}^{i}} = p \cdot {2}^{( L - i )} ,$$

the satisfaction of exponent conditions 2a and 2b varies depending on the lifting size Zₖ. For example, when Zₖ>tₖ, exponent conditions 2a and 2b are always satisfied. However, when Zₖ≤tₖ, cₖ≡aₖ+tₖ≡aₖ (mod Zₖ) holds, and circulant permutation matrices P^{ak} and P^{ck} of size Zₖ×Zₖ are effectively equal, so exponent conditions 2a and 2b may be not satisfied. In other words, if Zₖ≤tₖ, the structure as shown in Equation 16 is generated, indicating that cycle characteristics are not improved. In conclusion, to improve the cycle characteristics for lifting sizes of various lengths, it is desirable that the tₖ value be determined as small as possible.

However, when the lifting size Zₖ for LDPC encoding is relatively large compared to tₖ (e.g., when the value of i is large for

$$\frac{{Z}_{k}}{{t}_{k}} = {2}^{i} ) .$$

the coding complexity is likely to increase significantly due to the φ⁻¹ matrix relate operations. Hence, the tₖ value may be selected in consideration of the cycle characteristics and encoding complexity. When considering only improvement of the cycle characteristics, the smallest lifting size among lifting size values belonging to the lifting size set corresponding to i_{LS}=k may be selected as tₖ. Additionally, when considering a limited increase in encoding complexity, among lifting size values belonging to the lifting size set corresponding to i_{LS}=k, a lifting size that is greater than the smallest lifting size and less than the largest lifting size may be selected as tₖ. Typically, when lifting sizes included in the lifting size set are Z₁=p·2^{j1}, Z₂=p·2^{j2}, . . . , Zₘₐₓ=p·2^{jmax} (j₁<j₂< . . . <jₘₐₓ), the tₖ value may be set as tₖ−p 2′ (j₁≤i<jₘₐₓ). In general, if the values j₁, j₂, . . . , jₘₐₓ are not consecutive integers, the value of i may be selected as an integer other than j₂,j₃, . . . . In addition to the above embodiment, for other embodiments, tₖ may be selected based on various conditions as described above, but a detailed description thereof may be omitted for convenience.

As a specific example of exponent selection, an example of exponent selection is shown below when a=1, e.g., P^{a}=P¹ for convenience.

### Example 2 of exponent selection (i_{LS}=k)

$${a}_{k} = 1 ( \to {P}^{a} = P )$$

$${b}_{k} = 0 ( if {s}_{k} = - 1 , gcd ( \vert {a}_{k} - {b}_{k} \vert , {Z}_{k} ) = 1 , {P}^{b} = I )$$

cₖ is given by cₖ=1+tₖ (or cₖ=1−tₖ). Here, among the lifting size values belonging to the lifting size set corresponding to i_{LS}=k, tₖ is one of the lifting sizes less than the largest lifting size Z_{k,max}.

When calculating the difference between exponents for submatrix B determined according to example 2 of exponent selection, as |aₖ−bₖ|=1, gcd(|aₖ−bₖ|, Zₖ)=1 always holds for any lifting size Zₖ; and as |bₖ−cₖ|=1+tₖ, 1=gcd(1,Zₖ)=gcd(1+Zₖ, Zₖ)=gcd(1+tₖ, Zₖ) holds, so that exponent conditions 1a and 1b can be satisfied. As in example 2 of exponent selection, when bₖ=0, exponent conditions 1a and 1b can be satisfied not only for aₖ=1 but also for any aₖ generally satisfying gcd(aₖ,Zₖ)=1. That is, submatrix B in which aₖ=a, bₖ=0, cₖ=a+tₖ for integer a satisfying gcd(a,Zₖ)=1 satisfies exponent conditions 1a and 1b. Additionally, since

$$\vert {c}_{k} - {a}_{k} \vert = {t}_{k} = \frac{{Z}_{max}}{{2}^{i}} = p \cdot {2}^{( L - i )} ,$$

the satisfaction of exponent conditions 2a and 2b varies depending on the lifting size Zₖ. As described above, tₖ(or cₖ) may be selected based on various conditions, taking into account improvement of cycle characteristics and encoding complexity.

A description will be given of a specific embodiment in relation to example 2 of exponent selection.

Given a lifting size set as shown in Table 8, a specific example of submatrix B is shown in Equation 18 below. Equation 18 illustrates an example of submatrix B in the parity check matrix for i_{LS}=0 in Table 8. (an example of setting (P^{a}, P^{b}, P^{c}) of the matrices in Equation 15.) Submatrix B may be determined based on at least one of the matrices included in Equation 18 below. However, the embodiments of the disclosure are not limited thereto. That is, the following embodiment illustrates a case where 32 is selected from among lifting sizes, but any of the lifting sizes listed in Table 8 above may be selected. Hence, various matrices may be considered based on c determined according to the lifting size.

$$a = 1 , b = 0 , c = 1 + 32 = 33 ( selecting 32 among lifting size values ) \qquad [ Equation 18 ]$$

$${B}_{1} = [ \begin{matrix}{P}^{1} & I & O \\ I & I & I \\ {P}^{33} & O & I\end{matrix} ] , {B}_{2 , 1} = [ \begin{matrix}{P}^{1} & I & O & O \\ I & I & I & O \\ O & O & I & I \\ {P}^{33} & O & O & I\end{matrix} ] , {B}_{2 , 2} = [ \begin{matrix}{P}^{1} & I & O & O \\ O & I & I & O \\ I & O & I & I \\ {P}^{33} & O & O & I\end{matrix} ] ,$$

$${B}_{3} = [ \begin{matrix}{P}^{1} & I & O & O & O \\ O & I & I & O & O \\ I & O & I & I & O \\ O & O & O & I & I \\ {P}^{33} & O & O & O & I\end{matrix} ] , {B}_{4 , 1} = [ \begin{matrix}{P}^{1} & I & O & O & O & O \\ O & I & I & O & O & O \\ O & O & I & I & O & O \\ I & O & O & I & I & O \\ O & O & O & O & I & I \\ {P}^{33} & O & O & O & O & I\end{matrix} ] ,$$

$${B}_{4 , 2} = [ \begin{matrix}{P}^{1} & I & O & O & O & O \\ O & I & I & O & O & O \\ O & O & I & I & O & O \\ I & O & O & I & I & O \\ O & O & O & O & I & I \\ {P}^{33} & O & O & O & O & I\end{matrix} ] .$$

For Equation 18, in the 0^{th} lifting size set, if the lifting size Z value is selected to be 32 or less, such as 8, 16, or 32, then P³³ P1 due to 33=1 (mod Z), effectively making the φ matrix the identity matrix I. Hence, φ⁻¹ also becomes the identity matrix I. This simplifies the encoding process but fails to improve the cycle characteristics. If considering a limited increase in encoding complexity while improving the cycle characteristics, the following combinations are possible for exponent tuple (a, b, c) corresponding to (P^{a}, P^{b}, P^{c}) in the submatrix having the structure illustrated in Equation 18.

TABLE 10

| Set index (i_{LS}) | (a, b) | c |
|---|---|---|
| 0 | (a, b) = (1, 0) | 17 or 33 or 65 (or 129) |
| 1 | | 25 or 49 or 97 (or 193) |
| 2 | | 21 or 41 or 81 (or 161) |
| 3 | | 15 or 29 or 57 (or 113) |
| 4 | | 19 or 37 or 73 (or 145) |
| 5 | | 23 or 45 or 89 (or 177) |
| 6 | | 27 or 53 (or 105) |
| 7 | | 31 or 61 (or 121) |

Table 10 above is only an example, and generally, t may be selected from among the lifting size values less than Zₘₐₓ, determining c=t+1.

As an embodiment of the disclosure, the c value may be determined based on the largest lifting size among lifting sizes less than a specific reference value. More specifically, if the reference value is set to 96, in a system using lifting size sets as shown in Tables 3 to 8, the numbers less than or equal to 96 in lifting size sets are, in order, 64, 96, 80, 56, 72, 88, 52, and 60. Hence, if the c value corresponding to the parity check matrix defined for each lifting size set index is determined based on the given reference value for each lifting size set, the c value may be defined as 65, 97, 81, 57, 73, 89, 53, and 61, in order, based on each lifting size set index. If the reference value is set to 48, the c value may be defined in the same way as 33, 49, 41, 29, 37, 45, 27, and 31, in order, according to each lifting size set index. For reference, in the case of using lifting size sets excluding those numbers in parentheses in Table 3 or Table 8, if the i^{th} largest lifting size among the lifting size values included in the lifting size set with i_{LS}=1 is determined as the reference value, the c value corresponding to the parity check matrix defined according to each lifting size set index has the characteristic that it is determined to be an integer obtained by adding 1 to the i^{th} largest lifting size in each set.

In addition, to ensure uniformity in the encoding method, the i^{th} largest lifting size in each lifting size set may be selected (i=2, 3, 4, . . . ). For example, in a system using lifting size sets as shown in Table 3, the fifth largest numbers in individual lifting size sets are 16, 24, 20, 14, 18, 22, 13, and 15. Hence, if the c value corresponding to the parity check matrix defined for each lifting size set index is determined based on the fifth largest number in each lifting size set (i=5), the c value may be defined as 17, 25, 21, 15, 19, 23, 14, and 16, in order, based on each lifting size set index. Similarly, if the c value corresponding to the parity check matrix defined for each lifting size set index is determined based on the fourth largest number in each lifting size set (i=4), the c value may be defined as 33, 49, 41, 29, 37, 45, 27, and 31, in order, based on the lifting size set index. Similarly, if the c value corresponding to the parity check matrix defined for each lifting size set index is determined based on the third largest number in each lifting size set (i=3), the c value may be defined as 65, 97, 81, 57, 73, 89, 53, and 61, in order, based on the lifting size set index. Similarly, if the c value corresponding to the parity check matrix defined for each lifting size set index is determined based on the second largest number in each lifting size set (i=2), the c value may be defined as 129, 193, 161, 113, 145, 177, 105, and 121, in order, based on the lifting size set index.

In a system using lifting size sets excluding those values in parentheses in Table 8, the fifth largest number in each lifting size set is 32, 48, 40, 28, 36, 44, 26, and 30. Hence, if the c value corresponding to the parity check matrix defined for each lifting size set index is determined based on the fifth largest number in each lifting size set (i=5), the c value may be defined as 33, 49, 41, 29, 37, 45, 27, and 31, in order, based on the lifting size set index. Similarly, if the c value corresponding to the parity check matrix defined for each lifting size set index is determined based on the fourth largest number in each lifting size set (i=4), the c value may be defined as 65, 97, 81, 57, 73, 89, 53, and 61, in order, based on the lifting size set index. Similarly, if the c value corresponding to the parity check matrix defined for each lifting size set index is determined based on the third largest number in each lifting size set (i=3), the c value may be defined as 129, 193, 161, 113, 145, 177, 105, and 121, in order, based on the lifting size set index. Similarly, if the c value corresponding to the parity check matrix defined for each lifting size set index is determined based on the second largest number in each lifting size set (i=2), the c value may be defined as 257, 385, 321, 225, 289, 353, 209, and 241, in order, based on the lifting size set index.

In addition, according to tuple (P^{a}, P^{b}, P^{c})=(P, I, P^{c}) shown in Equation 18, Table 10 and corresponding embodiments, the φ matrix becomes φ=P+I+P^{c}, and when the lifting size Zₖ value is less than or equal to (c−1) according to example 2 of exponent selection, c≡1 (mod Zₖ) holds, leading to P^{a}=P=P^{c}, so that the cycle characteristics are not improved, but efficient LDPC encoding is possible by utilizing φ=I+P+P^{c}=I=φ⁻¹. When the lifting size Zₖ value is greater than (c−1), there is i that satisfies (P)²ⁱ=(P^{c})²ⁱ(i≥1), and φ²ⁱ=I holds, so that by utilizing the property that φ⁻¹=φ²ⁱ⁻¹φ²ⁱ⁻¹. φ²ⁱ⁻² . . . φ²·φ, efficient LDPC encoding is possible, albeit with increased encoding complexity. Here, the cycle length determined by P^{a} and P^{c} increases from the existing value of 2m_{b1} to 2m_{b1}−Z/D=2m_{b1}·2ⁱ=2ⁱ⁻¹·m_{b1}. The cycle length determined by P^{a} and P^{b} or P^{b} and P^{c} increases significantly in proportion to the Z value because it satisfies exponent condition 1a and exponent condition 1b.

As a specific example of exponent selection, when a=0, e.g., P^{a}=I for convenience, an example of exponent selection is shown below.

### Example 3 of Exponent Selection (i_{LS}=k)

$${a}_{k} = 0 ( \to {P}^{a} = I )$$

$${b}_{k} = 1 ( if {s}_{k} = 1 , gcd ( \vert {a}_{k} - {b}_{k} \vert , {Z}_{k} ) = 1 , {P}^{b} = P )$$

cₖ is given by cₖ=tₖ (or cₖ=−tₖ), where tₖ is one of lifting sizes less than the largest lifting size Z_{k,max} among the lifting size values belonging to the lifting size set corresponding to i_{LS}=k.

When calculating the difference between exponents for submatrix B determined according to example 3 of exponent selection, |aₖ−bₖ|=1, so gcd(|aₖ−bₖ|, Zₖ)=1 is always true for any lifting size Zₖ, and |bₖ−cₖ|=tₖ−1, so

$$1 = gc d ( 1 , {Z}_{k} ) = g c d ( {Z}_{k} - 1 , {Z}_{k} ) = g c d ( {t}_{k} - 1 , {Z}_{k} )$$

holds, so that exponent conditions 1a and 1b may be satisfied. As in example 3 of exponent selection, when aₖ=0, exponent conditions 1a and 1b can be satisfied for not only bₖ=1 but also any bₖ that generally satisfies gcd(bₖ,Zₖ)=1. That is, for integer b such that gcd(b,Zₖ)=1, submatrix B with aₖ=0, bₖ=b, cₖ−tₖ satisfies both exponent condition 1a and exponent condition 1b. Additionally, since

$$\vert {c}_{k} - {a}_{k} \vert = {t}_{k} = \frac{{Z}_{max}}{{2}^{i}} = p \cdot {2}^{( L - i )} ,$$

the satisfaction of exponent conditions 2a and 2b varies depending on the lifting size Zₖ. As previously described, tₖ (or cₖ) may be selected based on various conditions, taking into account cycle characteristics and encoding complexity.

Next, a description will be given of specific embodiments in relation to example 3 of exponent selection.

Given lifting size sets as shown in Table 8, a specific example of submatrix B is shown in Equation 19 below. Equation 19 illustrates an example of submatrix B in the parity check matrix for i_{LS}=0 in Table 8. (This is an example of setting (P^{a}, P^{b}, P^{c}) of the matrices in Equation 15.) Submatrix B may be determined based on at least one of the matrices included in Equation 19 below. However, embodiments of the disclosure are not limited thereto. That is, the following example illustrates a case where 32 is selected from among lifting size values, but anyone of the lifting size values listed in Table 8 may be selected. Hence, various matrices may be considered based on the c value determined according to the lifting size.

$$a = 0 , b = 1 , c = 32 ( selecting 32 among lifting size values ) \qquad [ Equation 19 ]$$

$${B}_{1} = [ \begin{matrix}I & I & O \\ P & I & I \\ {P}^{32} & O & I\end{matrix} ] , {B}_{2 , 1} = [ \begin{matrix}I & I & O & O \\ P & I & I & O \\ O & O & I & I \\ {P}^{32} & O & O & I\end{matrix} ] , {B}_{2 , 2} = [ \begin{matrix}I & I & O & O \\ O & I & I & O \\ P & O & I & I \\ {P}^{32} & O & O & I\end{matrix} ] ,$$

$${B}_{3} = [ \begin{matrix}I & I & O & O & O \\ O & I & I & O & O \\ P & O & I & I & O \\ O & O & O & I & I \\ {P}^{32} & O & O & O & I\end{matrix} ] , {B}_{4 , 1} = [ \begin{matrix}I & I & O & O & O & O \\ O & I & I & O & O & O \\ O & O & I & I & O & O \\ P & O & O & I & I & O \\ O & O & O & O & I & I \\ {P}^{32} & O & O & O & O & I\end{matrix} ]$$

$${B}_{4 , 2} = [ \begin{matrix}I & I & O & O & O & O \\ O & I & I & O & O & O \\ P & O & I & I & O & O \\ O & O & O & I & I & O \\ O & O & O & O & I & I \\ {P}^{32} & O & O & O & O & I\end{matrix} ] .$$

For Equation 19, if the lifting size Z value is selected as 32 or less, such as 8, 16, or 32, in the 0^{th} lifting size set, then P³² P⁰=I from 32-0 (mod Z), effectively making the φ matrix a circulant permutation matrix P, and φ⁻¹ becomes a circulant permutation matrix P⁻¹. This simplifies the encoding process, but without improving the cycle characteristics. If considering a limited increase in encoding complexity while improving the cycle characteristics, the following combinations are possible for index tuples (a, b, c) corresponding to (P^{a}, P^{b}, P^{c}) in the submatrix having the structure shown in Equation 18 above.

TABLE 11

| Set index (i_{LS}) | (a, b) | c |
|---|---|---|
| 0 | (a, b) = (0, 1) | 16 or 32 or 64 (or 128) |
| 1 | | 24 or 48 or 96 (or 192) |
| 2 | | 20 or 40 or 80 (or 160) |
| 3 | | 14 or 28 or 56 (or 112) |
| 4 | | 18 or 36 or 72 (or 144) |
| 5 | | 22 or 44 or 88 (or 176) |
| 6 | | 26 or 52 (or 104) |
| 7 | | 30 or 60 (or 120) |

Table 11 above is only an example, and generally, one value may be selected as t from among lifting size values less than Zₘₐₓ and determined as c=t.

As an embodiment of the disclosure, the c value may be determined based on the largest lifting size value among lifting size values less than a specific reference value. Specifically, if the reference value is set to 96, then in a system using lifting size sets as shown in Table 3 to Table 8, the number less than or equal to 96 in each lifting size set is 64, 96, 80, 56, 72, 88, 52, and 60, in order. Hence, if the c value corresponding to the parity check matrix defined for each lifting size set index is determined based on the given reference value for each lifting size set, the c value can be defined as 64, 96, 80, 56, 72, 88, 52, and 60, in order, according to each lifting size set index. Similarly, if the reference value is set to 48, the c value may be defined as 32, 48, 40, 28, 36, 44, 26, and 30, in order, according to each lifting size set index. In the case of using lifting size sets excluding those numbers in parentheses in Table 3 or Table 8, if the i^{th} largest lifting size among the lifting sizes included in the lifting size set with i_{LS}=1 is determined as the reference value, the c value corresponding to the parity check matrix defined according to each lifting size set index has the characteristic that it is determined as the i^{th} largest lifting size in each set.

In addition, to ensure uniformity in the encoding method, the i^{th} largest lifting size in each lifting size set may be selected (i=2, 3, 4, 5, 6, . . . ). For example, in a system using lifting size sets as shown in Table 3, the 5^{th} largest number in each lifting size set is 16, 24, 20, 14, 18, 22, 13, and 15. Hence, if the c value corresponding to the parity check matrix defined for each lifting size set index is determined based on the 5^{th} largest number in each lifting size set (i=5), the c value may be defined as 16, 24, 20, 14, 18, 22, 13, and 15, in order, according to the lifting size set index. Similarly, if the c value corresponding to the parity check matrix defined for each lifting size set index is determined based on the fourth largest number in each lifting size set (i=4), the c value may be defined as 32, 48, 40, 28, 36, 44, 26, and 30, in order, according to the lifting size set index. Similarly, if the c value corresponding to the parity check matrix defined for each lifting size set index is determined based on the third largest number in each lifting size set (i=3), the c value may be defined as 64, 96, 80, 56, 72, 88, 52, and 60, in order, according to the lifting size set index. Similarly, if the c value corresponding to the parity check matrix defined for each lifting size set index is determined based on the second largest number in each lifting size set (i=2), the c value may be defined as 128, 192, 160, 112, 144, 176, 104, and 120, in order, according to the lifting size set index.

In a system utilizing lifting size sets of values excluding those values in parentheses in Table 8, the fifth largest number in each lifting size set is 32, 48, 40, 28, 36, 44, 26, and 30. Hence, if the c value corresponding to the parity check matrix defined for each lifting size set index is determined based on the fifth largest number in each lifting size set (i=5), the c value may be defined as 32, 48, 40, 28, 36, 44, 26, and 30, in order, according to the lifting size set index. Similarly, if the c value corresponding to the parity check matrix defined for each lifting size set index is determined based on the fourth largest number in each lifting size set (i=4), the c value may be defined as 64, 96, 80, 56, 72, 88, 52, and 60, in order, according to the lifting size set index. Similarly, if the c value corresponding to the parity check matrix defined for each lifting size set index is determined based on the third largest number in each lifting size set (i=3), the c value may be defined as 128, 192, 160, 112, 144, 176, 104, and 120, in order, according to the lifting size set index. Similarly, if the c value corresponding to the parity check matrix defined for each lifting size set index is determined based on the second largest number in each lifting size set (i=2), the c value may be defined as 256, 384, 320, 224, 288, 353, 208, and 240, in order, according to the lifting size set index.

In addition, according to tuple (P^{a}, P^{b}, P^{c}) (I, P, P^{c}) shown in Equation 19, Table 11 and associated embodiments, the φ matrix becomes φ=I+P+P^{c}. In the case where the lifting size Zₖ value is less than or equal to c according to example 3 of exponent selection, c≡0 (mod Zₖ) holds, and thus P^{a}=I=P^{c}, so that the cycle characteristics are not improved, but efficient LDPC encoding is possible by utilizing φ=P and φ⁻¹=P⁻¹. When the lifting size Zₖ value is greater than c, there is an i such that (P^{c})²ⁱ=I(i≥1), so φ²ⁱ=I. Hence, efficient LDPC encoding is possible by utilizing the property of φ⁻¹=φ²ⁱ⁻¹=φ²ⁱ⁻¹φ²ⁱ⁻¹ . . . φ²·φ, although the encoding complexity increases. Here, the cycle length determined by P^{a} and P^{c} increases from the existing value of 2m_{b1} to 2m_{b1}−Z/D=²m_{b1}·2ⁱ=2ⁱ⁻¹·m_{b1}. The cycle length determined by P^{a} and P^{b} or P^{b} and P^{c} increases significantly in proportion to the Z value because exponent condition 1a and exponent condition 1b are satisfied.

Examples 1, 2, and 3 of exponent selection above are methods for selecting exponents for some circulant permutation matrices constituting submatrix B 1020 in the parity check matrix of FIG. 10 in simultaneous consideration of cycle characteristic improvement and coding complexity. The above examples of exponent selection suggest a method that does not improve cycle characteristics but offers very low coding complexity when the lifting size is small and the code length is short, and improves cycle characteristics with a slight increase in coding complexity as the lifting size increases. In general, LDPC codes are more susceptible to the error floor phenomenon due to cycle characteristics as the length becomes longer. Hence, the above methods, which further improve the cycle characteristics as the length of the code increases along with the increasing lifting size, can be said to be methods that can improve the error floor phenomenon in accordance with the length of the LDPC code.

When the lifting size is small and the code length is short, the cycle characteristics do not significantly affect the error floor phenomenon. However, it is definitely possible to apply a method for improving the cycle characteristics even when the lifting size is small.

As an embodiment of the disclosure, a description will be given of a method for improving cycle characteristics when the code length is short.

### Example 4 of Exponent Selection (i_{LS}=k)

aₖ is any integer
bₖ is given by bₖ=aₖ+sₖ, where skis an integer satisfying gcd(sₖ, Zₖ)=1. That is, among the exponents corresponding to submatrix B, aₖ and bₖ are integers satisfying gcd(|aₖ−bₖ|,Zₖ)=1. Here, gcd(x,y) denotes the greatest common divisor of x and y, and Zₖ denotes a specific lifting size belonging to the lifting size set corresponding to i_{LS}=k. (Zₖ=pₖ·2^{Lk}, pₖ is odd, Lₖ≥0)

$${c}_{k} is given by {c}_{k} = {a}_{k} + \frac{{Z}_{k}}{{2}^{min ( J , {L}_{k} )}} = {a}_{k} + {p}_{k} \cdot {2}^{{L}_{k} - {2}^{min ( J , {L}_{k} )}}$$

$$or , {c}_{k} = \{ \begin{matrix}{a}_{k} + {p}_{k} , & {L}_{k} < J \\ {a}_{k} + \frac{{Z}_{k}}{{2}^{J}} , & {L}_{k} \geq J\end{matrix} ( = \{ \begin{matrix}{a}_{k} + {p}_{k} , & {L}_{k} < J \\ {a}_{k} + {p}_{k} \cdot {2}^{{L}_{k} - J} , & {L}_{k} \geq J\end{matrix} ) .$$

If the Zₖ value supported by the system is always greater than or equal to pₖ·2^{J}, it may be simply expressed as

$${c}_{k} = {a}_{k} + \frac{{Z}_{k}}{{2}^{J}} ( = {a}_{k} + {p}_{k} \cdot {2}^{{L}_{k} - J} ) .$$

Example 4 of exponent selection illustrates a method in which exponents of circulant permutation matrices (P^{a}, P^{b}, P^{c}) are not fixed but rather variably determined based on at least one lifting size Z. Hence, the method proposed in the disclosure may be applied even when other various lifting size sets are defined in addition to the lifting size sets in Tables 3 to 8.

For

$${Z}_{k} = {p}_{k} \cdot {2}^{{L}_{k}} , if {L}_{k} < J , \frac{{Z}_{k}}{{2}^{J}}$$

is not an integer, so cₖ=aₖ+pₖ can be set in the above example. That is, the cₖ value may be determined variably depending on the Zₖ values supported by the system and the given J value. If the Zₖ value supported by the system is greater than or equal to Pₖ·2^{J}, then

$$\frac{{Z}_{k}}{{2}^{J}}$$

is always an integer, so one expression such as

$${c}_{k} = {a}_{k} + \frac{{Z}_{k}}{{2}^{J}}$$

is possible.

The method of example 4 of exponent selection above satisfies exponent conditions 1a and 1b, but varies in whether exponent conditions 2a and 2 are satisfied depending on the lifting size Zₖ. For example, exponent condition 2a and exponent condition 2b are satisfied if the range of supported Zₖ values is greater than or equal to Pₖ·2^{J}, and are not satisfied if it is less than Pₖ·2^{j}.

According to the embodiment for example 4 of exponent selection, the cycle length determined by P^{a} and P^{c} increases from the existing value of 2m_{b1} to 2^{J+1} m_{b1} when Zₖ≥Pₖ·2^{J}(or Lₖ≥J), and increases to 2^{Lk+1}·m_{b1} when Zₖ<pₖ·2^{J} (or Lₖ<J). (It does not increase when Lₖ=0.) The cycle length determined by P^{a} and P^{b} or P^{b} and P^{c} increases significantly in proportion to the value of Z because exponent condition 1a and exponent condition 1b are satisfied.

In addition, if Zₖ≥Pₖ·2^{J} (or Lₖ≥J), then the φ matrix is given by

$$ϕ = {p}^{{a}_{k}} + {p}^{{a}_{k} + {s}_{k}} + {P}^{{a}_{k} + \frac{Z}{{2}^{J}}} = {p}^{{a}_{k}} ( l + {p}^{{s}_{k}} + {P}^{\frac{Z}{{2}^{J}}} )$$

$$So ,$$

$${ϕ}^{{2}^{J}} = {P}^{{a}_{k} \cdot {2}^{J}} \cdot ( I + {P}^{{s}_{k} \cdot {2}^{J}} + {P}^{Z} ) = {P}^{( {a}_{k} + {s}_{k} ) \cdot {2}^{J}}$$

$${ϕ}^{- 1} = {p}^{- ( {a}_{k} + {s}_{k} ) \cdot {2}^{J}} \cdot {ϕ}^{{2}^{J} - 1} = {p}^{- ( {a}_{k} + {s}_{k} ) \cdot {2}^{J}} \cdot {ϕ}^{{2}^{J - 1}} \cdot {ϕ}^{{2}^{J - 2}} \cdot … \cdot {ϕ}^{2} \cdot ϕ$$

using this expression, it is possible to perform LDPC encoding. If Zₖ<Pₖ·2^{J} (or Lₖ<J), then the φ matrix is given by

$$ϕ = {p}^{{a}_{k}} + {p}^{{a}_{k} + {s}_{k}} + {p}^{{a}_{k} + {p}_{k =}} {p}^{{a}_{k}} ( l + {p}^{{s}_{k}} + {p}^{{p}_{k}} )$$

$$So ,$$

$${ϕ}^{{2}^{j}} = {P}^{{a}_{k} \cdot {2}^{j}} ( I + {P}^{{s}_{k} \cdot {2}^{j}} + {P}^{Z} ) = {P}^{( {a}_{k} + {s}_{k} ) \cdot {2}^{j}}$$

As there is an integer j (j<J) that satisfies the above expression, LDPC encoding is possible in a similar manner.

The method of example 4 of exponent selection above has the disadvantage that the maximum cycle length that can be improved based on the J value is fixed regardless of the lifting size Z, but has the advantage of improving cycle characteristics even when the lifting size Z is small. In other words, the cycle characteristics may be improved for various lifting sizes by allowing at least one of the exponents of the circulant permutation matrices (P^{a}, P^{b}, P^{c}) to be variably determined based on the lifting size Z rather than by setting all the exponents of the circulant permutation matrices to a fixed integer value.

As a specific example for example 4 of exponent selection, a description is given of exponent selection when a=1, e.g., P^{a}=p¹ for convenience.

### Example 5 of Exponent Selection (i_{LS}=k)

$${a}_{k} = 1 ( {P}^{a} = P )$$

$${b}_{k} = 0 ( {P}^{b} = I )$$

$${c}_{k} is given by {c}_{k} = {a}_{k} + \frac{{Z}_{k}}{{2}^{min ( J , {L}_{k} )}} = {a}_{k} + {p}_{k} \cdot {2}^{{L}_{k} - {2}^{min ( J , {L}_{k} )}}$$

$$or , {c}_{k} = \{ \begin{matrix}{a}_{k} + {p}_{k} , & {L}_{k} < J \\ {a}_{k} + \frac{{Z}_{k}}{{2}^{J}} , & {L}_{k} \geq J\end{matrix} ( = \{ \begin{matrix}{a}_{k} + {p}_{k} , & {L}_{k} < J \\ {a}_{k} + {p}_{k} \cdot {2}^{{L}_{k} - J} , & {L}_{k} \geq J\end{matrix} ) .$$

If the Zₖ value supported by the system is always greater than or equal to Pₖ·2^{J}, it may be simply expressed as

$${c}_{k} = {a}_{k} + \frac{{Z}_{k}}{{2}^{J}} ( = 1 + {p}_{k} \cdot {2}^{{L}_{k} - J} ) .$$

When bₖ=0 as in example 5 of exponent selection, exponent conditions 1a and 1b are satisfied for not only aₖ=1 but also any aₖ such that gcd(aₖ, Zₖ)=1. That is, submatrix B, for which a setting is made such as for integer a such that

$$gcd ( a , {Z}_{k} ) = 1 , {a}_{k} = a , {b}_{k} = 0 , {c}_{k} = 1 + {p}_{k} \cdot {2}^{max ( {L}_{k} - J , 0 )}$$

$$( or {c}_{k} = \{ \begin{matrix}a + {p}_{k} , & {L}_{k} < J \\ a + \frac{{Z}_{k}}{{2}^{J}} , & {L}_{k} \geq J\end{matrix} ) ,$$

exponent condition 1a and exponent condition 1b.

According to the method as in example 5 of exponent selection,

$${ϕ}^{{2}^{J}} = {P}^{a \cdot {2}^{J}} + I + {P}^{a \cdot {2}^{J} + z} = I$$

holds, so efficient encoding is possible by using φ⁻¹=φ^{2J-1}·φ^{2J-2} . . . φ²·φ.

As a more specific example for example 4 of exponent selection, a description is given of exponent selection when a=0, e.g., P^{a}=I for convenience.

### Example 6 of Exponent Selection (i_{LS}=k)

$${a}_{k} = 0 ( {P}^{a} = I )$$

$${b}_{k} = 1 ( {P}^{b} = P )$$

$${c}_{k} is given by {c}_{k} = \frac{{z}_{k}}{{2}^{min ( J , {L}_{k} )}} = {p}_{k} \cdot {2}^{{L}_{k} - {2}^{min ( J , {L}_{k} )}}$$

$$or , {c}_{k} = \{ \begin{matrix}{p}_{k} , & {L}_{k} < J \\ \frac{{z}_{k}}{{2}^{J}} , & {L}_{k} \geq J\end{matrix} = \{ \begin{matrix}{p}_{k} , & {L}_{k} < J \\ {p}_{k} \cdot {2}^{{L}_{k} - J} , & {L}_{k} \geq J\end{matrix} )$$

If the Zₖ value supported by the system is always greater than or equal to Pₖ·2^{J}, it may be simply expressed as

$${c}_{k} = \frac{{z}_{k}}{{2}^{J}} ( = {p}_{k} \cdot {2}^{{L}_{k} - J} ) .$$

When aₖ=0 as in example 6 of exponent selection, exponent conditions 1a and 1b are satisfied for not only bₖ=1 but also any bₖ such that gcd(bₖ,Zₖ)=1. That is, submatrix B, for which a setting is made such as for integer b such as gcd

$$( b , {Z}_{k} ) = 1 , {a}_{k} = 0 , {b}_{k} = b , {c}_{k} = {p}_{k} \cdot {2}^{max ( {L}_{k} - J , 0 )} ( or {c}_{k} = \{ \begin{matrix}{p}_{k} , & {L}_{k} < J \\ \frac{{z}_{k}}{{2}^{J}} , & {L}_{k} \geq J\end{matrix} ) ,$$

satisfies exponent condition 1a and exponent condition 1b.

According to the method as in example 6 of exponent selection,

$${ϕ}^{{2}^{J}} = I + {P}^{b \cdot {2}^{J}} + {P}^{z} = {P}^{b \cdot {2}^{J}}$$

$${ϕ}^{- 1} = {P}^{- b \cdot {2}^{J}} \cdot {ϕ}^{{2}^{J} - 1} = {P}^{- b \cdot {2}^{J}} \cdot {ϕ}^{{2}^{J - 1}} \cdot {ϕ}^{{2}^{J - 2}} \cdot … \cdot {ϕ}^{2} \cdot ϕ ,$$

efficient encoding is possible based on the above expressions.

The exponent selection method according to examples 4, 5, and 6 of exponent selection enables cycle length improvement of up to 2^{J+1}·m_{b1} when considering efficient encoding. If the m_{b1} value is relatively large, cycle characteristics may be sufficiently improved even without a large J value. Typically, the J value may be determined in consideration of parameter m_{b}i, which indicates the number of rows in the core matrix part of the parity check matrix given by the system, and the target BLER value. For example, if the target BLER is relatively high or the m_{b1} value of the core matrix is large, J=1, 2 may be sufficient, but if the target BLER is relatively low or the m_{b1} value of the core matrix is small, it is desirable to set J=2, 3, 4, . . . ,.

Since the degree to which code's performance is affected by its cycle characteristics varies in general depending on the code length, it is also possible to set the J value differently depending on the lifting size. That is, while at least one of the exponents is determined based on the lifting size, when the lifting size is relatively small, the J₁ value may be set to a smaller value, and when the lifting size is relatively large, the J₂ value may be set to a larger value (J₁≤J₂). When setting different J values depending on the lifting size, a reference lifting size and appropriate J₁ and J₂ values should be determined.

Various possible exponent selection methods including examples 1 to 6 for exponent selection may be variably applied depending on the target BLER and/or lifting size of the system. For example, if the target BLER of the system is high, encoding may be performed using existing methods with the highest encoding efficiency albeit without improving the cycle characteristics, as the cycle characteristics do not significantly affect the code's decoding performance. However, if the target BLER is low, the exponent selection methods proposed in this disclosure may be applied. Here, being high or low of the target BLER may be relatively determined when multiple target BLERs are applicable in the system. For example, if a first target BLER is 10⁻¹ and a second target BLER is 10⁻⁵, the first target BLER may be said to be higher than the second target BLER. If a first target BLER is 10⁻¹, a second target BLER is 10⁻⁵, and a third target BLER is 10⁻⁶ (or 10⁻⁷), the first target BLER may be determined to be higher than the second BLER and third target BLER, and the first BLER and second target BLER may be determined to be higher than the third target BLER. In this way, when there are multiple target BLERs applicable to the system, being high or low of the BLER may be determined with respect to a specific BLER value, and then the exponent selection method proposed in the disclosure may be variably applied based on this determination.

However, this is only an embodiment of the disclosure, and the exponent selection method proposed in this disclosure may be applied when the target BLER is high or regardless of the target BLER, and may be applied variably based on other factors. Additionally, since the exponent selection method described throughout this disclosure refers to a method for selecting the exponents of circulant permutation matrices included in a submatrix (specifically, submatrix B) of the parity check matrix, the exponent selection method of this disclosure may be described as a method for determining a parity check matrix or a method for determining a submatrix included in a parity check matrix. In addition, since the lifting size is closely related to the code length or TBS, in the embodiments disclosed in the disclosure, all processes determined based on the lifting size may be described as a process based on the code length or TBS. Further, in examples 1 to 6 of exponent selection, the lifting size Zₖ is expressed as “Zₖ=Pₖ·2^{Lk}, Lₖ≥0, Pₖ is an odd number” for convenience, but in general, even when Pₖ is not restricted to an odd number, such as “Zₖ=Pₖ·2^{Lk}, Lₖ≥0, Pₖ is the smallest lifting size in the k^{th} lifting size set” as in Table 7-1 or Table 7-2, the exponent selection methods may be applied in the same way.

As a specific example for application of the J value in examples 4 to 6 of exponent selection, if the system target BLER is determined to be high, the J value may be set to a small value J₁, and if the system target BLER is determined to be low, the J value may be set to a relatively large value J₂ (J₁<J₂). Additionally, this method for selecting exponents or determining the J value may be considered in conjunction with the lifting size. Generally, A reference BLERs and/or lifting sizes may be set, and these may be distinguished by a total of (A+1) different J values. For example, if there are a first reference, a second reference, . . . , then the J value may be subdivided into J₁<J₂, J₁<J₂<J₃, . . . . In general, J may also be set to 0, in which case P^{a}=p^{c} holds, which may indicate the existing method that allows the simplest encoding process without improvement of the cycle characteristics.

For reference, the method for determining the target BLER at the terminal or base station may vary depending on the system. For example, the system target BLER may be indicated directly from higher layer signaling such as configured RRC (radio resource control) information, the target BLER may be indicated indirectly according to a configured CQI table or MCS table, or the target BLER may be indicated indirectly according to the configured service scenario.

As an embodiment of the disclosure, a method for improving the error floor performance of an LDPC code is proposed. In the disclosure, in the first part of a parity check matrix composed of submatrices A 1010 and B 1020 as in FIG. 10, when submatrix B 1020 corresponding to the first parity bits is in the following form,

$$[ \begin{matrix}I & I \\ {P}^{a} + {P}^{b} & I\end{matrix} ] \qquad [ Equation 20 ]$$

algebraic properties to be satisfied are proposed.

Submatrix B 1020 of Equation 20 has a size of M₁×M₁ (or, 2Z X 2Z) and corresponds to a base matrix or weight matrix of size 2×2. Additionally, the first column block of submatrix B 1020 is composed of a Z×Z circulant matrix including overlapping one Z×Z circulant permutation matrix and two Z×Z circulant permutation matrices, and the second column block is composed of two Z×Z identity matrices (or circulant permutation matrices). For convenience, this disclosure only represents a case where the second column block is composed of identity matrices, but this limitation is not generally necessary. In addition, matrices that can be transformed into submatrix B 1020 in the above form through an appropriate invertible transform process may be considered as algebraically equivalent matrices.

In the case of submatrix B 1020 of Equation 20, the <φ matrix of size Z×Z used in the encoding process becomes I+P^{a}+P^{b}, which enables efficient encoding according to exponent selection as in the previous embodiments. However, to remove cycles of length 4 from the structure of Equation 20, conditions such as a, b(mod Z)>0,

$$a ≢ b ( mod \frac{z}{2} ) ( or a - b ≢ \frac{z}{2} ( mod Z ) )$$

should be satisfied. Cycles of length 4 are preferably removed because they reduce the decoding performance of the code. Next, a description will be given of an exponent selection method that enables efficient encoding by improving the cycle characteristics of the submatrix of Equation 20 while reasonably increasing the computational complexity associated with the φ⁻¹ matrix required for LDPC encoding. In the embodiment of the disclosure, it is assumed that the above condition for removing a cycle of length 4 is basically satisfied.

If the lifting size Z for the parity check matrix of a QC LDPC code is Z=p·2^{L} (p is odd, L is an integer greater than or equal to 0), then exponents (or circular shift values) 0, a, b of the circulant permutation matrices constituting the first column block of submatrix B 1020 are different integers and satisfy at least some or all of the following conditions:

Exponent condition 3: a has a greatest common divisor of 1 with lifting size Z or is the smallest number among the divisors of Z greater than 1. (That is, a is relatively prime to Z or has the least divisor of Z greater than 1 as its greatest common divisor.)

Exponent condition 4: For an integer i such that

$$2 \leq i < {l}_{1} , \vert a - b \vert ≢ \frac{z}{i} ( mod Z )$$

Exponent condition 5: For an integer i such that 0≤i<l₂,

i·a (i+1)b(mod Z) and (i+1)a i·b (mod Z)

Exponent condition 6:

$$b = \frac{q \cdot Z}{{2}^{J}} ( 0 < J \leq L , q is odd )$$

According to exponent condition 3 above, if a is relatively prime to Z, the length of the cycle on the Tanner graph determined by

$$[ \begin{matrix}I & I \\ {P}^{a} & I\end{matrix} ]$$

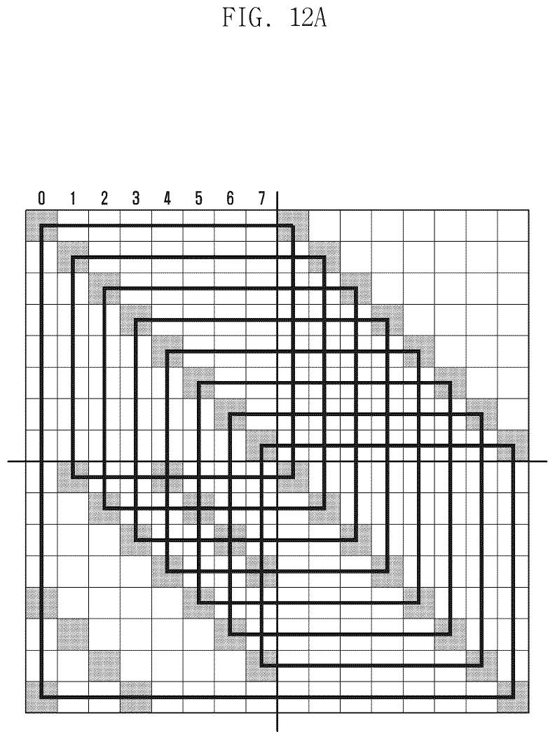

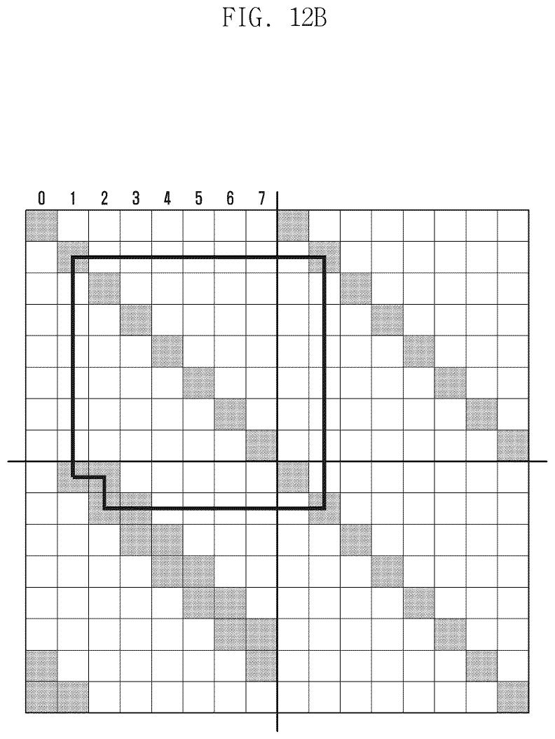

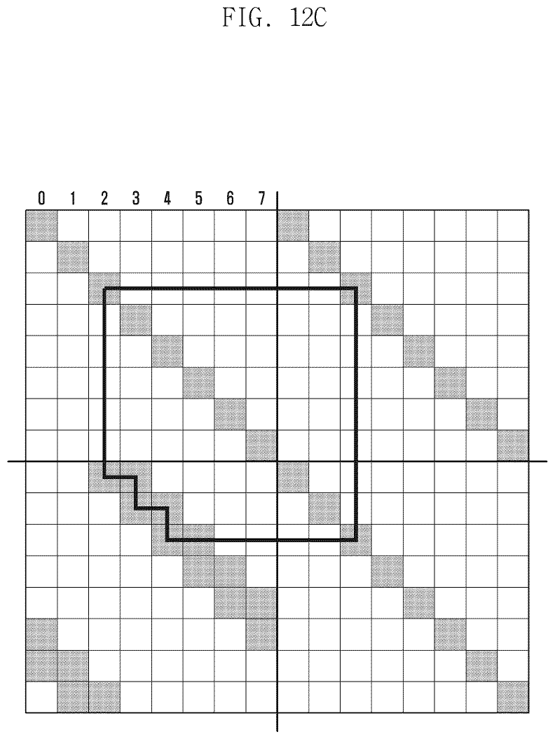

in the matrix of Equation 20 becomes 4Z. A simple example for the cycle characteristics according to exponent condition 3 is shown in FIG. 12A.

FIG. 12A is a diagram illustrating cycle characteristics in a submatrix of the parity check matrix for an LDPC code satisfying the characteristics proposed in the disclosure.

FIG. 12A illustrates the cycle characteristics derived by

$$[ \begin{matrix}I & I \\ {P}^{1} & I\end{matrix} ] in [ \begin{matrix}I & I \\ {P}^{1} + {P}^{4} & I\end{matrix} ]$$

when Z=8, and depicts a cycle of length 32. In general, if the greatest common divisor of a and Z is D, the cycle length is 4Z/D. Consequently, as the value of Z increases, the cycle length increases. Considering only the cycle characteristics, it is desirable for a to be coprime to Z. However, depending on the situation, the exponent may be chosen so that the greatest common divisor D is small (e.g., the smallest divisor of Z greater than 1) based on other conditions. For example, if a cannot satisfy the property of being coprime to Z, it is desirable to select an exponent that makes the greatest common divisor D small.

Exponent condition 4 is a condition for improving the characteristics of cycles on the Tanner graph determined by

$$[ \begin{matrix}* & * \\ {P}^{a} + {P}^{b} & *\end{matrix} ]$$

in the matrix of Equation 20. When exponent condition 4 is satisfied, all cycles with a length of 2(l₁−1) or less are removed from the above structure, so only cycles with a length of 2l₁ or more are present.

Exponent condition 5 is a condition for improving the characteristics of cycles on the Tanner graph determined by

$$[ \begin{matrix}I & I \\ {P}^{a} + {P}^{b} & I\end{matrix} ]$$

in the matrix of Equation 20. When exponent condition 5 is satisfied, all cycles with a length of (4+2i) or less for integer i such that 0≤i<l₂ are removed from the above structure, so only cycles with a length of (4+2l₂) or more are present. A simple example for the cycle characteristics according to exponent condition 5 is shown in FIGS. 12B and 12C.

FIG. 12B is a diagram illustrating cycle characteristics in a submatrix of the parity check matrix for an LDPC code satisfying the characteristics proposed in the disclosure.

Specifically, FIG. 12B illustrates the cycle characteristics derived by

$$[ \begin{matrix}I & I \\ {P}^{1} + {P}^{2} & I\end{matrix} ]$$

when Z=8.

0·1 1·2 (mod 8) and 1·1 0·2 (mod 8)

Although the above expression is satisfied for i=0, as 2-1−1-2 (mod 8) holds for i=1, so a cycle of length 4 is eliminated, but a cycle of length 6 may be present.

FIG. 12C is a diagram illustrating cycle characteristics in a submatrix of the parity check matrix for an LDPC code satisfying the characteristics proposed in the disclosure.

Specifically, FIG. 12C illustrates the cycle characteristics derived by

$$[ \begin{matrix}I & I \\ {P}^{2} + {P}^{3} & I\end{matrix} ]$$

when Z=8.

1·(mod 8) and 1·2 0·3 (mod 8),

1·2—3 (mod8) and 2·2 1·3 (mod8)

Although the above expressions are satisfied for i=0, as 3·2=2·3 (mod 8) holds for i=2, so a cycle of length 4 or 6 is eliminated, but a cycle of length 8 may be present.

Exponent condition 6 is a condition for simplifying the φ⁻¹ matrix as much as possible for efficient LDPC encoding. The φ matrix required in the process of performing LDPC encoding based on the parity check matrix including submatrix B of Equation 20 may be defined as φ=I+P^{a}+P^{b}. Here, if

$$b = \frac{Z}{{2}^{J}} , ϕ = I + {P}^{a} + {P}^{\frac{q Z}{{2}^{J}}} ,$$

so φ^{2J}=I+P^{2Ja}+P^{q·Z}=P^{2Ja}, which becomes φ⁻¹=p^{-2Ja}·φ^{2J-1}. Hence, relatively efficient encoding is possible using the φ⁻¹ matrix. In exponent condition 6, if the lifting size Z is odd, the value of b cannot be an integer, so this embodiment is applicable only when all lifting sizes are even. That is, in Z=p·2^{L}, L is applicable only when it is an integer greater than or equal to 1. For example, as shown in Table 9, the minimum lifting size in each lifting size set should be even.

TABLE 9

| Set index (i_{LS}) | Set of lifting sizes (Z) |
|---|---|
| 0 | {(8,) 16, 32, 64, 128, 256(, 512)} |
| 1 | {(12,) 24, 48, 96, 192, 384(, 768)} |
| 2 | {20, 40, 80, 160, 320(, 640}} |
| 3 | {28, 56, 112, 224, 448(, 896)} |
| 4 | {(18,) 36, 72, 144, 288(, 576)} |
| 5 | {(22,) 44, 88, 176, 352(, 704}} |
| 6 | {(26,} 52, 104, 208, 416(, 832)} |
| 7 | {(30,) 60, 120, 240, 480(, 960)} |

As an embodiment of the disclosure, a description will be given of a more specific example for constructing submatrix B 1020 of FIG. 10 using the above exponent conditions.

First, a communication system or broadcasting system is considered, such as 5G, where lifting size sets are defined as shown in Tables 3 to 9, and only lifting sizes included in the sets can be applied. Additionally, the parity check matrix or exponent matrix may be defined separately for each lifting size set. That is, in the cases of Tables 3 to 9, a parity check matrix or exponent matrix may be defined for each of a total of eight set indices.

In submatrix B based on Equation 20, let a and b be determined as follows. This disclosure only describes the case where a=1 for convenience, but the value of a may be selected from values that are relatively prime to Z or have a smaller greatest common divisor. Generally, since the exponent b for submatrix B of the parity check matrix corresponding to i_{LS}=k (k=0, 1, 2, . . . ) may all be different, it is represented as bₖ. In addition, Zₖ may indicate a lifting size belonging to the lifting size set corresponding to i_{LS}=k, and may be expressed in the form of Zₖ=pₖ 2^{Lk} (Pₖ is odd or minimum lifting size, Lₖ≥1).

### Example 7 of Exponent Selection (i_{LS}=k)

$$[ \begin{matrix}I & I \\ {P}^{1} + {P}^{{b}_{k}} & I\end{matrix} ] \\ {b}_{k} = \frac{{Z}_{k}}{{2}^{min ( J , {L}_{k} )}} = {p}_{k} \cdot {2}^{{L}_{k} - min ( J , {L}_{k} )} \\ ( where \frac{{Z}_{k}}{{2}^{min ( J , {L}_{k} )}} > 1 , that is , {Z}_{k} > {2}^{min ( J , {L}_{k} )} should be satisfied . )$$

In example 7 of exponent selection, if all Zₖ values supported by the system are multiples of 2^{J}, it may be simply expressed as

$${b}_{k} = \frac{{Z}_{k}}{{2}^{J}} = {p}_{k} \cdot {2}^{{L}_{k} - J}$$

(where Zₖ>2^{J}). This may indicate that the minimum lifting size in each lifting size set as in Table 9 is a multiple of 2^{J}. For example, when J=2, this may indicate that each minimum lifting size is a multiple of 4, and when J=3, this may indicate that each minimum lifting size is a multiple of 8. In Tables 3 to 9, for the lifting size set with i_{LS}=0, when Zₖ=2^{Lk}, the minimum lifting size satisfying the condition Zₖ>2^{J} is 2^{J+1}. For example, when J=2 and 3, the minimum lifting sizes are 8 and 16, respectively. For convenience, this disclosure only describes cases where the minimum lifting size in each lifting size set is a multiple of 2^{J}. In general, the exponent selection method described in the disclosure may also be applied to cases where the minimum lifting size in each lifting size set is a multiple of 2 but not a multiple of 2^{J}.

According to example 7 of exponent selection, exponent conditions 3 and 6 are satisfied.

Also, since

$$\vert a - b \vert = \frac{{Z}_{k}}{{2}^{J}} - 1 ,$$

according to exponent condition 4, there is no cycle of length 4 derived by

$$[ \begin{matrix}* & * \\ {P}^{a} + {P}^{b} & *\end{matrix} ] .$$

If Zₖ does not have a prime factor of 3 (e.g., Pₖ is not an odd multiple of 3), as

$$\frac{Z}{3}$$

cannot be an integer, there is no cycle of length 6. If Zₖ has a prime factor of 3, this may indicate that Zₖ=3·2^{Lk}, so the following expression holds

$$\frac{Z}{3} - \vert a - b \vert = {2}^{{L}_{k}} - ( 3 \cdot {2}^{{L}_{k} - J} - 1 ) = {2}^{{L}_{k} - J} ( {2}^{J} - 3 ) + 1$$

If J=2 and Lₖ≥2, then

$$\frac{Z}{3} - \vert a - b \vert = {2}^{{L}_{k} - 2} + 1 ,$$

and the following expression holds

$${2}^{{L}_{k} - 2} + 1 ≢ 0 ( mod 3 \cdot {2}^{{L}_{k}} )$$

Hence, there is no cycle of length 6 for all lifting sizes. Further, if J=2, since

$$\vert a - b \vert = \frac{{Z}_{k}}{4} - 1$$

satisfies

$$\vert a - b \vert ≢ \frac{{Z}_{k}}{4} ( mod {Z}_{k} ) ,$$

there is no cycle of length 8 derived by

$$[ \begin{matrix}* & * \\ {P}^{a} + {P}^{b} & *\end{matrix} ]$$

either. Therefore, when J is chosen as an integer greater than or equal to 2, the cycle length derived by

$$[ \begin{matrix}* & * \\ {P}^{a} + {P}^{b} & *\end{matrix} ]$$

is at least 10. As the J value increases, the cycle characteristics can be further improved, but because the encoding complexity increases and the constraints on the lifting size increase, it is desirable to select an appropriate J value according to the system requirements.

According to example 7 of exponent selection,

$$i ≢ ( i + 1 ) \frac{{Z}_{k}}{{2}^{J}} ( mod {Z}_{k} )$$

is satisfied from i=0 to a relatively large integer, but when i=1 and

$${Z}_{k} = {2}^{J + 1} , ( i + 1 ) ≡ i \cdot \frac{{Z}_{k}}{{2}^{J}} ( mod {Z}_{k} )$$

is satisfied. Hence, according to exponent condition 5, only cycles with length 4 are removed from among the cycles derived by

$$[ \begin{matrix}I & I \\ {P}^{1} + {P}^{{b}_{k}} & I\end{matrix} ]$$

as in FIGS. 12B and 12C. Therefore, to remove longer cycles, it is desirable to set J to an integer greater than or equal to 2 and apply the above exponent selection method for lifting sizes satisfying Lₖ>J+2. For example, if J=2 and Lₖ=J+2, the following expression may hold.

$$i \cdot {b}_{k} - ( i + 1 ) = i \cdot \frac{{Z}_{k}}{{2}^{2}} - ( i + 1 ) = i \cdot {p}_{k} \cdot {2}^{2} - ( i + 1 ) = ( 4 {p}_{k} - 1 ) i - 1$$

$$i = 1 ; ( 4 {p}_{k} - 1 ) i - 1 = 4 {p}_{k} - 2 ≢ 0 ( mod {p}_{k} {2}^{4} )$$

$$i = 2 ; ( 4 {p}_{k} - 1 ) i - 1 = {2}^{3} {p}_{k} - 3 ≢ 0 ( mod {p}_{k} {2}^{4} )$$

$$i = 3 ; ( 4 {p}_{k} - 1 ) i - 1 = 12 {p}_{k} - 4 ≢ 0 ( mod {p}_{k} {2}^{4} )$$

$$i = 4 ; ( 4 {p}_{k} - 1 ) i - 1 = {2}^{4} {p}_{k} - 5 ≢ 0 ( mod {p}_{k} {2}^{4} )$$

Hence, according to exponent condition 5, it can be seen that all cycles with a length of 12 or less among the cycles that can be derived by

$$[ \begin{matrix}I & I \\ {P}^{1} + {P}^{{b}_{k}} & I\end{matrix} ]$$

as in FIGS. 12B and 12C are removed.

Considering exponent conditions 3 to 6 and features of example 7 of exponent selection, a method for selecting exponents based on the minimum lifting size of a given lifting size set can also be applied as follows.

### Example 8 of Exponent Selection (i_{LS}=k)

$$[ \begin{matrix}I & I \\ {P}^{1} + {P}^{{b}_{k}} & I\end{matrix} ]$$

The lifting size set corresponding to i_{LS}=k is {pₖ2^{L1}, pₖ2^{L2}, . . . pₖ2^{Lmax}}, where Lₘᵢₙ=L₁<L₂< . . . <Lₘₐₓ and Pₖ does not necessarily have to be odd.

$${b}_{k} = {p}_{k} \cdot {2}^{{L}_{1} - J} , J \geq 2$$

Example 8 of exponent selection describes a method for selecting exponents based on the minimum lifting size Zₘ in included in each lifting size set when lifting size sets are given. According to example 8 of exponent selection, it may be represented as

$${b}_{k} = \frac{{Z}_{min}}{{2}^{J}} ( = {p}_{k} \cdot {2}^{{L}_{min} - J} ) .$$

As a specific example, in a system that applies lifting size sets excluding those numbers in parentheses in Table 9, if J=2, the bₖ value for each set index is 4, 6, 5, 7, 9, 11, 13, and 15, in order. If J=3 and the minimum lifting size of each lifting size set is 32, 48, 40, 56, 72, 88, 104, and 120, in order, then the bₖ value for each set index is 4, 6, 5, 7, 9, 11, 13, and 15, in order.

As an embodiment of the disclosure, the bₖ value may be determined based on lifting sizes greater than a specific reference value. Specifically, it is assumed that J=2 and the reference value is set to 64. If example 8 of exponent selection is applied only when the bₖ value is greater than or equal to the reference value, the bₖ value for each set index is 16, 24, 20, 28, 36, 44, 52, and 60, in order. As another example, it is assumed that J=3 and the reference value is set to 64. If example 8 of exponent selection is applied only when the bₖ value is greater than or equal to the reference value, the bₖ value for each set index is 8, 12, 10, 14, 18, 22, 26, 30, in order.

As an embodiment of the disclosure, there is proposed an exponent selection method for improving the decoding efficiency of LDPC codes. In this disclosure, an LDPC encoding and decoding system using a parity check matrix in the form of Equation 21 is assumed.

$$H = [ ( {\sum }_{j = 1}^{{w}_{1}} {P}^{{e}_{1 j}} ) … ( {\sum }_{j = 1}^{{w}_{k}} {P}^{{e}_{kj}} ) ( {\sum }_{j = 1}^{{w}_{k + 1}} {P}^{{e}_{( k + 1 ) j}} ) ] , \qquad [ Equation 21 ]$$

$$M ( H ) = [ 1 … 11 ] ,$$

$$W ( H ) = [ {w}_{1} … {w}_{k} {w}_{k + 1} ] , {w}_{i} \geq 3 , ( i = 1 , 2 , … , k ) , {w}_{k + 1} \geq 2$$

$$V ( H ) = [ ( {e}_{11} , {e}_{12} , … , {e}_{1 {w}_{1}} ) … ( {e}_{k 1} , {e}_{k 2} , … , {e}_{{kw}_{k}} ) ( {e}_{( k + 1 ) 1} , … , {e}_{( k + 1 ) {w}_{1}} ) ]$$

The parity check matrix of Equation 21 above has a size of Z×(k+1)Z, and the base matrix or weight matrix has a size of 1×(k+1). The parity check matrix of Equation 21 may correspond to a core matrix in which the size of submatrix A 1010 in FIG. 10 is Z×kZ and the size of submatrix B 1020 is Z×Z. (In FIG. 10, when M₂=0, Equation 21 corresponds to the entire parity check matrix.)

Additionally, each i^{th} column block is composed of a Z×Z circulant matrix in which wᵢ circulant permutation matrices of size Z×Z overlap. For convenience, this disclosure illustrates the case where one of the circulant permutation matrices constituting each column block is an identity matrix (e₁₁=e₂₁= . . . =e₍ₖ₊₁₎₁=0), but this limitation is not generally necessary. In addition, matrices that can be transformed into a parity check matrix of the above form through an appropriate inverse transform process such as circular shift and permutation may be considered as algebraically equivalent matrices.

In the parity check matrix of Equation 21, the first k circulant matrices of size Z×Z, corresponding to the information word, are composed of three or more circulant permutation matrices, and are typically composed of four or more circulant permutation matrices to improve the minimum distance characteristics of the code. The last (k+1)^{th} circulant matrix corresponding to the parity bits is composed of two or more circulant permutation matrices; since a circulant matrix composed of two or four circulant permutation matrices does not have full rank, at least one column of the (k+1)^{th} circulant matrix corresponds to an information bit. Hence, to improve the minimum distance characteristics and apply existing efficient encoding methods, it is typically composed of three or more odd circulant permutation matrices. Additionally, to remove cycles of length 4, the differences between exponents (or circular shift values) corresponding to the circulant permutation matrices constituting one circulant matrix of size Z×Z are all different with respect to modulo-Z.

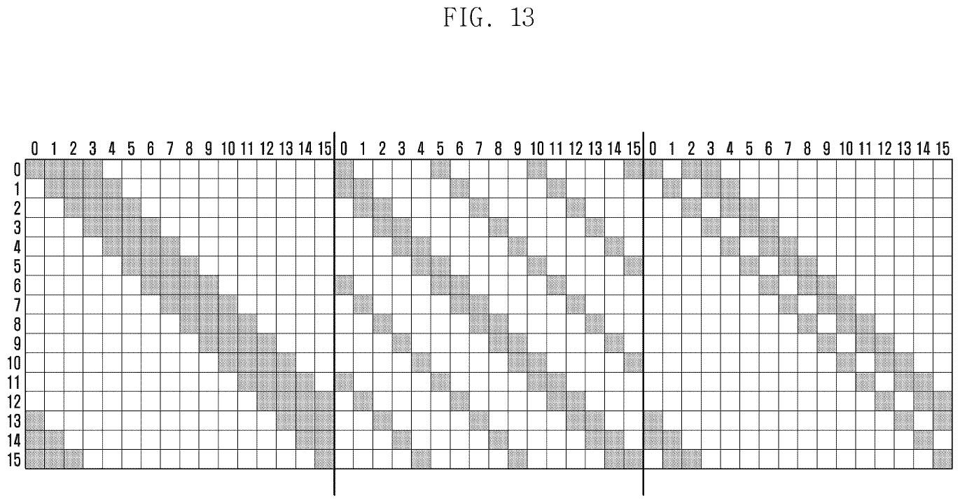

An example of the parity check matrix of Equation 21 is shown in FIG. 13. The parity check matrix of FIG. 13 has a size of Z×3Z for Z=16, and the circulant permutation matrices constituting three column blocks are as shown in Equation 22 below.

$$H = [ ( {P}^{0} + {P}^{1} + {P}^{2} + {P}^{3} ) ( {P}^{0} + {P}^{5} + {P}^{10} + {P}^{15} ) ( {P}^{0} + {P}^{2} + {P}^{3} ) ] . \qquad [ Equation 22 ]$$

In general, when there are three or more overlapping circulant permutation matrices in one Z×Z circulant matrix as in the parity check matrix of Equation 21 and FIG. 13, a cycle of length 6 can always be generated. In other words, if there is at least one case where wᵢ>3 in the parity check matrix of Equation 21, the girth (the minimum cycle length in the Tanner graph corresponding to the code) in the Tanner graph is 6. Hence, the parity check matrix of Equation 21 above cannot improve cycle characteristics, so it is preferable to use this parity check matrix in an environment that is not significantly affected by cycle characteristics. Communication systems that are not sensitive to cycle characteristics typically have short supported code lengths, high supported code rates, and/or high target BLERs.

According to the parity check matrix of Equation 21, the parity check matrix may be generated regardless of the Z value as long as only (w₁+w₂+ . . . +w₍ₖ₊₁₎) exponents are stored, thereby providing the advantage of high storage efficiency. For example, the parity check matrix of FIG. 13 may be generated or determined if only the Z value and information [(0, 1, 2, 3,) (0, 5, 10, 15) (0, 2, 3)] are stored in the terminal or base station.

In general, QC-LDPC codes are well-suited for parallel processing utilizing a layered decoding method with each row block being the basic unit. However, in the parity check matrix of Equation 21 or FIG. 13, since each row is a single row block, performing decoding using a Z-unit parallel processing processor may indicate processing all rows simultaneously. This decoder structure is not problematic when the Z value is small, but when supporting large code lengths, it may be burdensome to implement the decoder because the length of the row, e.g., the Z value, increases as the code length increases.

This disclosure proposes an appropriate exponent selection method for a parity check matrix having the structure of Equation 21, and explains that parallel processing less than Z is possible by applying the proposed exponent selection method.

First, a rule is define for applying column permutation and row permutation to a Z×Z circulant matrix as follows.

### [Permutation Rule]

$$Z = d \times {Z}_{d} , ( d : divisor of Z greater than 1 )$$

Apply the following permutation rule to each circulant matrix of size Z×Z.

$$For 0 \leq i < {Z}_{d} , 0 \leq j < \frac{{Z}_{d}}{d} ,$$

(a) Column permutation rule: shift (i×d+j)^{th} column to (j×Z_{d}+i)^{th} column.

(b) Row permutation rule: shift (i×d+j)^{th} row to (j×Z_{d}+i)^{th} row.

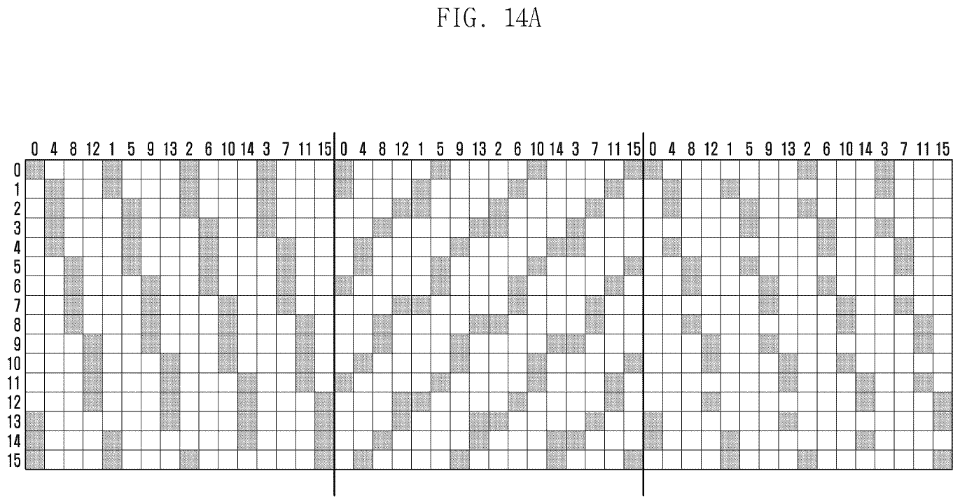

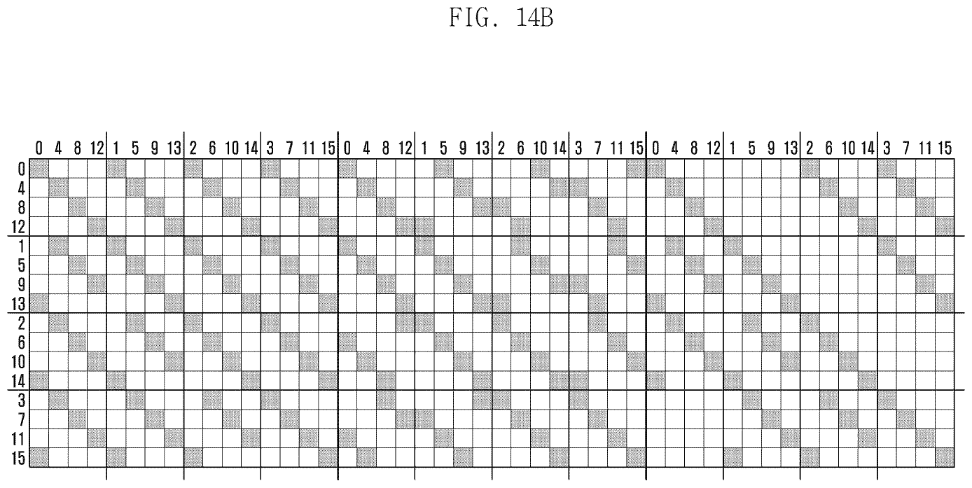

A specific example of applying the above permutation rule to the parity check matrix in FIG. 13 is shown in FIGS. 14A and 14B. In FIGS. 14A and 14B, the permutation rule is applied based on Z=d×Z_{d}=16, d=4, and Z_{d}=4.

FIGS. 14A and 14B are a diagram illustrating application of a permutation rule to the parity check matrix according to an embodiment of the disclosure.

FIG. 14A is a diagram illustrating application of column permutation to the parity check matrix in FIG. 13, and FIG. 14B is a diagram illustrating additional application of row permutation to the parity check matrix in FIG. 14A. With reference to FIG. 14B, the parity check matrix of Equation 22, which is composed of a circulant matrix of size Z×Z, can be expressed as a parity check matrix composed of a circulant permutation matrix of size Z_{d}×Z_{d} as in Equation 23 below by rearranging the rows and columns with application of the permutation rule.

$${H}_{perm} = [ \begin{matrix}I & I & I & I & I & P & {P}^{2} & {P}^{2} & {P}^{3} & I & O & I & I \\ P & I & I & I & I & I & P & P & {P}^{2} & P & I & O & I \\ P & P & I & I & {P}^{3} & I & I & I & P & P & P & I & O \\ P & P & P & I & {P}^{2} & {P}^{3} & I & I & I & O & P & P & I\end{matrix} ] . \qquad [ Equation 23 ]$$

In general, simple permutations of rows and columns do not affect the characteristics or performance of a code. In particular, row permutation has no effect on the characteristics of the code, and column permutation only affects the order of bits without affecting the code's characteristics or performance. Therefore, it can be seen that it is possible to convert the structure into one that is easy to apply a Z_{d}-unit layered decoding method by rearranging the parity check matrix only.

It can be seen that when the above permutation rule is applied to a circulant matrix of size Z×Z, the circulant matrix is divided into d² circulant permutation matrices of size Z_{d}×Z_{d} for divisor d of Z as in Equation 24 below.

$$0 \leq {e}_{i} < {Z}_{d ,} \qquad [ Equation 24 ]$$

$${[ {P}^{2 {e}_{1}} + {P}^{2 {e}_{2} + 1} ]}_{Z \times Z} \to {[ \begin{matrix}{P}^{{e}_{1}} & {P}^{{e}_{2}} \\ {P}^{{e}_{2} + 1} & {P}^{{e}_{1}}\end{matrix} ]}_{2 {Z}_{d} \times 2 {Z}_{d}}$$

$${[ {P}^{3 {e}_{1}} + {P}^{3 {e}_{2} + 1} + {P}^{3 {e}_{3} + 2} ]}_{Z \times Z} \to {[ \begin{matrix}{P}^{{e}_{1}} & {P}^{{e}_{2}} & {P}^{{e}_{3}} \\ {P}^{{e}_{3} + 1} & {P}^{{e}_{1}} & {P}^{{e}_{2}} \\ {P}^{{e}_{2} + 1} & {P}^{{e}_{3} + 1} & {P}^{{e}_{1}}\end{matrix} ]}_{3 {Z}_{d} \times 3 {Z}_{d}}$$

$${[ {P}^{4 {e}_{1}} + {P}^{4 {e}_{2} + 1} + {P}^{4 {e}_{3} + 2} + {P}^{4 {e}_{4} + 3} ]}_{Z \times Z} \to {[ \begin{matrix}{P}^{{e}_{1}} & {P}^{{e}_{2}} & {P}^{{e}_{3}} & {P}^{{e}_{4}} \\ {P}^{{e}_{4} + 1} & {P}^{{e}_{1}} & {P}^{{e}_{2}} & {P}^{{e}_{3}} \\ {P}^{{e}_{3} + 1} & {P}^{{e}_{4} + 1} & {P}^{{e}_{1}} & {P}^{{e}_{2}} \\ {P}^{{e}_{2} + 1} & {P}^{{e}_{3} + 1} & {P}^{{e}_{4} + 1} & {P}^{{e}_{1}}\end{matrix} ]}_{4 {Z}_{d} \times 4 {Z}_{d}}$$

Equation 24 above illustrates a case where, when a circulant matrix of size Z×Z is divided, no overlapping circulant matrices are present in a circulant permutation matrix. However, in general, circulant matrices may be present even after rearrangement as in Equation 25 below.

$$0 \leq {e}_{i} < {Z}_{d ,} \qquad [ Equation 25 ]$$

$${[ {P}^{3 {e}_{1}} + {P}^{3 {e}_{2} + 1} + {P}^{3 {e}_{3} + 2} ]}_{Z \times Z} \to {[ \begin{matrix}{P}^{{e}_{1}} & {P}^{{e}_{2}} + {P}^{{e}_{3}} & O \\ O & {P}^{{e}_{1}} & {P}^{{e}_{2}} + {P}^{{e}_{3}} \\ {P}^{{e}_{2} + 1} + {P}^{{e}_{3} + 1} & O & {P}^{{e}_{1}}\end{matrix} ]}_{3 {Z}_{d} \times 3 {Z}_{d}}$$

$${[ {P}^{4 {e}_{1}} + {P}^{4 {e}_{2} + 1} + {P}^{4 {e}_{3} + 2} + {P}^{4 {e}_{4} + 3} ]}_{Z \times Z} \to {[ \begin{matrix}{P}^{2 {e}_{1}} + {P}^{2 {e}_{3} + 1} & {P}^{2 {e}_{2}} + {P}^{2 {e}_{4} + 1} \\ {P}^{2 {e}_{2} + 1} + {P}^{2 {e}_{4} + 2} & {P}^{2 {e}_{1}} + {P}^{2 {e}_{3} + 1}\end{matrix} ]}_{2 {Z}_{d} \times 2 {Z}_{d}}$$

As described above, various rearrangements are possible depending on the exponents of the circulant permutation matrices constituting the parity check matrix of Equation 21. However, since a circulant matrix composed of three or more overlapping circulant permutation matrices typically significantly increases the decoder implementation complexity, it is advantageous in terms of decoder implementation to ensure that circulant permutation matrices do not overlap as much as possible or do overlap at most two.

According to Equations 24 and 26, the remainder of dividing the column index and row index of each circulant permutation matrix by a divisor d of the size of the circulant permutation matrix (Z) can affect the position after rearrangement. That is, the entries corresponding to columns and rows with the same remainder for divisor d are included in the same circulant matrix of size Z_{d}×Z_{d} after rearrangement

$$( {Z}_{d} = \frac{z}{d} ) .$$

As a specific example, for a divisor d, those

$${Z}_{d}^{2}$$

elements corresponding to rows with remainders i and columns with remainders j are included in a circulant matrix of size Z_{d}×Z_{d} corresponding to the j^{th} column block of the i^{th} row block (0≤i,j<d). Therefore, in order to prevent two or more circulant permutation matrices from being corresponding to a circulant matrix of size Z_{d}×Z_{d} after rearranging the parity check matrix by applying the permutation rule proposed in this disclosure, the exponents (or circular shift values) corresponding to the circulant permutation matrices constituting a single Z×Z circulant matrix in the initially given parity check matrix can be set such that all the remainders are different with respect to d, which is a divisor of Z, or there is at most one case where they are the same. In other words, there must exist a d such that the exponents (or circular shift values) corresponding to the circulant permutation matrices have either all different values with respect to modulo-d or at most one identical value (so that there is no more than one identical case), so that no more than two circulant permutation matrices correspond to a circulant matrix of size Z_{d}×Z_{d} after rearrangement. When the largest number among the weights of column blocks is wₘₐₓ, if relation 2d<Wₘₐₓ holds, this may indicate that three circulant permutation matrices overlap in at least one Z_{d}×Z_{d} circulant matrix. So, the above rearrangement is possible when 2d>Wₘₐₓ is satisfied.

To ensure that at most one circulant permutation matrix corresponds to a Z_{d}×Z_{d} circulant matrix after rearranging the parity check matrix, the exponents (or circular shift values) must all have different remainders with respect to a divisor d of Z. Also, if relation d<Wₘₐₓ holds, this may indicate that two circulant permutation matrices overlap in at least one Z_{d}×Z_{d} circulant matrix, so the above rearrangement is possible only when d>wₘₐₓ is satisfied.

To determine the exponents of the circulant permutation matrices constituting the circulant matrix corresponding to the last column block, both the remainder for d and efficient encoding should be considered. In a parity check matrix, the closer the submatrix corresponding to the parity is to a lower triangular matrix, the lower the encoding complexity. Hence, among the exponents satisfying the above conditions, it is desirable to select exponents closer to a lower triangular matrix. In this disclosure, considering the case where the Wₘₐₓ value is 4 or more, the circulant matrix of the last column block may be applied as I+P¹+P³ or I+P²+P³. This is because considering condition d>wₘₐₓ, if d is considered to be 4 or more, exponent tuple (0, 1, 3) or (0, 2, 3) always has different remainders with respect to d. Definitely, this is just an example, and the exponent values of the circulant permutation matrices may be appropriately selected based on at least one of the lifting size Z, the size Z×(k+1)Z of the parity check matrix, the divisor d value for rearrangement into a form divided into sizes Z_{d}×Z_{d}, and/or the weight distribution of the circulant matrix constituting each column block. Meanwhile, since the exponent selection method described throughout the disclosure refers to a method for selecting exponents of circulant permutation matrices included in a submatrix of the parity check matrix, the exponent selection method of the disclosure may be described as a method for determining a parity check matrix or a method for determining a submatrix included in the parity check matrix.

Meanwhile, electronic devices according to various embodiments disclosed in this document may take various forms. Such an electronic device may include, for example, at least one of portable communication device (e.g., smartphone), TV, computer device, portable multimedia device, portable medical instrument, camera, wearable device, or home appliance. The electronic device according to embodiments of this document is not limited to the aforementioned devices. Additionally, the operation of transmitting frames may not only imply transmission over a radio channel, but may also imply that an interface for outputting frames is included for transmission to various electronic devices. For example, a certain processor may output frames to an RF front end for transmission over a bus interface. Likewise, the operation of receiving frames from another device may imply that various electronic devices have interfaces for obtaining frames received from other devices. For example, it may indicate that a certain processor may receive or obtain frames from the RF front end via a bus interface.

Various embodiments of this document and terms used therein are not intended to limit the technical features described in this document to specific embodiments, and should be understood as including various modifications, equivalents, or substitutes of a corresponding embodiment.

With regard to the description of the drawings, similar reference numerals may be used to refer to similar or related elements. A singular expression may include a plural expression unless the context clearly indicates otherwise. In this document, each of phrases such as “A or B”, “at least one of A and/or B”, “A, B or C”, and “at least one of A, B and/or C”, may include all possible combinations of the items enumerated together. Terms such as “1st” and “2nd”, or “first” and “second” may be used to simply distinguish a corresponding component from another, and does not limit the components in other aspect such as importance or order. When an element (e.g., first element) is referred to, with or without the term “operably” or “communicatively”, as “coupled to/with” or “connected to/with” another element (e.g., second element), this may indicate that the element may be connected or coupled to the other element directly or via a third element(s).

In addition, the word “determining” may have many different meanings, such as identifying, calculating or computing, processing, deriving, investigating, estimating, looking up (e.g., from a database or other data structure), and ascertaining, depending on the context.

Meanwhile, in the drawings explaining the method of the present disclosure, the order of description does not necessarily correspond to the order of execution, and operations may be changed in their order or executed in parallel.

Alternatively, in the drawings illustrating the method of the disclosure, some components may be omitted and only some components may be included without harming the subject matter of the disclosure.

In addition, the method of the disclosure may be implemented by combining some or all of the contents included in individual embodiments within a range that does not harm the subject matter of the invention.

While the disclosure has been described with preferred embodiments, various changes and modifications may occur to those skilled in the art. These changes and modifications are intended to be encompassed by the appended claims. In addition, it is clear that operations expressed as different blocks for convenience of explanation in the operational flow diagram of the disclosure may be implemented by separately assigning them to multiple processors in an actual system, but may also be implemented by integrally assigning them to a single processor.

1. A method performed by a transmitter in a communication system, the method comprising:
determining a number of input bits;
determining a base matrix based on the number of input bits;
determining a lifting size (Z) based on at least one of the number of input bits or the base matrix;
determining a parity check matrix based on at least one of the base matrix or the lifting size (Z); and
performing encoding based on the parity check matrix and the input bits,
wherein a size of the parity check matrix is Z×(k+1)Z, a last column block of the parity check matrix corresponds to parity bits, and Z×kZ column blocks of the parity check matrix correspond to information bits,
wherein modulo-Z values of differences between circular shift values corresponding to circulant permutation matrices constituting a circulant matrix of size Z×Z are all different,
wherein each of circulant matrices corresponding to the information bits includes at least three circulant permutation matrices.

2. The method of claim 1, wherein modulo values of each of the circular shift values for at least one divisor (d) of divisors of Z are all different, or include at most one identical values.

3. The method of claim 2, wherein the divisor of Z satisfies 2d>wₘₐₓ for a maximum column weight (wₘₐₓ) of the parity check matrix.

4. The method of claim 2, wherein the divisor of Z satisfies d>wₘₐₓ for a maximum column weight (wₘₐₓ) of the parity check matrix, and
wherein a circulant matrix of the last column block is I+P¹+P³ or I+P²+P³.

5. A method performed by a receiver in a communication system, the method comprising:
receiving a signal;
determining a number of input bits based on the signal;
determining a base matrix based on the number of input bits;
determining a lifting size (Z) based on at least one of the number of input bits or the base matrix;
determining a parity check matrix based on at least one of the base matrix or the lifting size (Z); and
performing decoding of the signal based on the parity check matrix,
wherein a size of the parity check matrix is Z×(k+1)Z, a last column block of the parity check matrix corresponds to parity bits, and Z×kZ column blocks of the parity check matrix correspond to information bits,
wherein modulo-Z values of differences between circular shift values corresponding to circulant permutation matrices constituting a circulant matrix of size Z×Z are all different,
wherein each of circulant matrices corresponding to the information bits includes at least three circulant permutation matrices.

6. The method of claim 5, wherein modulo values of each of the circular shift values for at least one divisor (d) of divisors of Z are all different, or include at most one identical values.

7. The method of claim 6, wherein the divisor of Z satisfies 2d>wₘₐₓ for a maximum column weight (wₘₐₓ) of the parity check matrix.

8. The method of claim 6, wherein the divisor of Z satisfies d>wₘₐₓ for a maximum column weight (wₘₐₓ) of the parity check matrix, and
wherein a circulant matrix of the last column block is I+P¹+P³ or I+P²+P³.

9. A transmitter in a communication system, comprising:
a transceiver comprising circuitry; and
a controller, comprising processing circuitry, coupled with the transceiver and configured to:
determine a number of input bits;
determine a base matrix based on the number of input bits;
determine a lifting size (Z) based on at least one of the number of input bits or the base matrix;
determine a parity check matrix based on at least one of the base matrix or the lifting size (Z); and
perform encoding based on the parity check matrix and the input bits,
wherein a size of the parity check matrix is Z×(k+1)Z, a last column block of the parity check matrix is related to to parity bits, and Z×kZ column blocks of the parity check matrix is/are related to information bits,
wherein modulo-Z values of differences between circular shift values corresponding to circulant permutation matrices constituting a circulant matrix of size Z×Z are all different,
wherein each of circulant matrices corresponding to the information bits includes three or more circulant permutation matrices.

10. The transmitter of claim 9, wherein modulo values of each of the circular shift values for at least one divisor (d) of divisors of Z are all different, or include at most one identical values.

11. The transmitter of claim 10, wherein the divisor of Z satisfies 2d>wₘₐₓ for a maximum column weight (wₘₐₓ) of the parity check matrix.

12. The transmitter of claim 10, wherein the divisor of Z satisfies d>wₘₐₓ for a maximum column weight (wₘₐₓ) of the parity check matrix, and
wherein a circulant matrix of the last column block is I+P¹+P³ or I+P²+P³.

13. A receiver in a communication system, comprising:
a transceiver comprising circuitry; and
a controller, comprising processing circuitry, coupled with the transceiver and configured to:
receive a signal;
determine a number of input bits based on the signal;
determine a base matrix based on the number of input bits;
determine a lifting size (Z) based on at least one of the number of input bits or the base matrix;
determine a parity check matrix based on at least one of the base matrix or the lifting size (Z); and
perform decoding of the signal based on the parity check matrix,
wherein a size of the parity check matrix is Z×(k+1)Z, a last column block of the parity check matrix corresponds to parity bits, and Z×kZ column blocks of the parity check matrix correspond to information bits,
wherein modulo-Z values of differences between circular shift values corresponding to circulant permutation matrices constituting a circulant matrix of size Z×Z are all different,
wherein each of circulant matrices corresponding to the information bits includes three or more circulant permutation matrices.

14. The receiver of claim 13, wherein modulo values of each of the circular shift values for at least one divisor (d) of divisors of Z are all different, or include at most one identical values, and
wherein the divisor (d) of Z satisfies 2d>wₘₐₓ for a maximum column weight (wₘₐₓ) of the parity check matrix.

15. The receiver of claim 13, wherein the divisor (d) of Z satisfies d>wₘₐₓ for a maximum column weight (wₘₐₓ) of the parity check matrix, and
wherein a circulant matrix of the last column block is or comprises I+P¹+P³ or I+P²+P³.
